(19) United States
(12) Patent Application Publication
(10) Pub. No.: US 2021/0399234 A1
(43) Pub. Date: Dec. 23, 2021

(54) ORGANIC LIGHT EMITTING DEVICE

(71) Applicant: LG CHEM, LTD., Seoul (KR)

(72) Inventors: Seong So KIM, Daejeon (KR); Minseung CHUN, Daejeon (KR); Jae Seung HA, Daejeon (KR); Sang Duk SUH, Daejeon (KR); Sung Kil HONG, Daejeon (KR)

(21) Appl. No.: 17/289,338

(22) PCT Filed: Nov. 26, 2019
(86) PCT No.: PCT/KR2019/016376

§ 371 Date: Apr. 28, 2021

(30) Foreign Application Priority Data
Nov. 30, 2018 (KR) 10-2018-0152920

(51) Int. Cl. H01L 51/00

(52) U.S. Cl. CPC H01L 51/0073; H01L 51/0058; H01L 51/0074; H01L 51/5024; H01L 51/0054; H01L 51/006; H01L 51/0056; H01L 51/0072

(57) ABSTRACT

Provided is an organic light emitting device having low driving voltage, high luminous efficiency, and long lifespan characteristics, the organic light emitting device, comprising:
an anode;
a hole transport layer;
a hole adjustment layer;
a light emitting layer;
an electron transport layer; and
a cathode,
wherein the light emitting layer includes a host and a dopant,
the host has a dipole moment value of 0.4 to 1.3, and
the hole adjustment layer includes a compound having a dipole moment value of 1.2 to 2.0.

### CROSS-REFERENCE TO RELATED APPLICATION(S)

This application is a National Stage Application of International Application No. PCT/KR2019/016376 filed on Nov. 26, 2019, which claims priority to and the benefit of Korean Patent Application No. 10-2018-0152920 filed on Nov. 30, 2018 with the Korean Intellectual Property Office, the disclosure of which is incorporated herein by reference in its entirety.

### TECHNICAL FIELD

The present disclosure relates to an organic light emitting device having low driving voltage, high luminous efficiency and long lifetime characteristics.

### BACKGROUND

In general, an organic light emitting phenomenon refers to a phenomenon where electric energy is converted into light energy by using an organic material. The organic light emitting device using the organic light emitting phenomenon has characteristics such as a wide viewing angle, an excellent contrast, a fast response time, an excellent luminance, driving voltage and response speed, and thus many studies have proceeded.

The organic light emitting device generally has a structure which comprises an anode, a cathode, and an organic material layer interposed between the anode and the cathode. The organic material layer frequently has a multilayered structure that comprises different materials in order to enhance efficiency and stability of the organic light emitting device, and for example, the organic material layer can be formed of a hole injection layer, a hole transport layer, a light emitting layer, an electron transport layer, an electron injection layer and the like. In the structure of the organic light emitting device, if a voltage is applied between two electrodes, the holes are injected from an anode into the organic material layer and the electrons are injected from the cathode into the organic material layer, and when the injected holes and electrons meet each other, an exciton is formed, and light is emitted when the exciton falls to a ground state again.

There is a continuing need for the development of new materials for the organic materials used in the organic light emitting devices as described above.

### PRIOR ART LITERATURE

### Patent Literature

(Patent Literature 1) Korean Unexamined Patent Publication No. 10-2000-0051826

### BRIEF DESCRIPTION

### Technical Problem

It is an object of the present disclosure to provide an organic light emitting device having low driving voltage, high luminous efficiency and long lifetime characteristics.

### Technical Solution

In order to achieve the above object, there is provided the following organic light emitting device:

An organic light emitting device including: an anode, a hole transport layer, a hole adjustment layer; a light emitting layer; an electron transport layer; and a cathode,

wherein the light emitting layer includes a host and a dopant,

the host has a dipole moment value of 0.4 to 1.3, and

the hole adjustment layer includes a compound having a dipole moment value of 1.2 to 2.0.

### Advantageous Effects

The organic light emitting device according to the present disclosure can have low driving voltage, high luminous efficiency and long lifetime characteristics by using materials of a host and a hole adjustment layer satisfying a specific dipole moment value.

### BRIEF DESCRIPTION OF THE DRAWINGS

FIG. 1 shows an example of an organic light emitting device comprising a substrate 1, an anode 2, a hole transport layer 3, a hole adjustment layer 4, a light emitting layer 5, an electron transport layer 6 and a cathode 7.

FIG. 2 shows an example of an organic light emitting device comprising a substrate 1, an anode 2, a hole injection layer 8, a hole transport layer 3, a hole adjustment layer 4, a light emitting layer 5, an electron adjustment layer 9, an electron transport layer 6, an electron injection layer 10 and a cathode 7.

### DETAILED DESCRIPTION

Hereinafter, embodiments of the present disclosure will be described in more detail to facilitate understanding of the invention.

### DEFINITION OF TERMS

As used herein, the notation [symbol] means a bond linked to another substituent group.

As used herein, the term “substituted or unsubstituted” means being unsubstituted or substituted with one or more substituents selected from the group consisting of deuterium, a halogen group, a nitrile group, a nitro group, a hydroxy group, a carbonyl group, an ester group, an imide group, an amino group, a phosphine oxide group, an alkoxy group, an aryloxy group, an alkylthioxy group, an arylthioxy group, an alkylsulfoxy group, an arylsulfoxy group, a silyl group, a boron group, an alkyl group, a cycloalkyl group, an alkenyl group, an aryl group, an aralkyl group, an aralkenyl group, an alkylaryl group, an alkylamine group, an aralkylamine group, a heteroarylamine group, an arylamine group, an arylphosphine group, and a heterocyclic group containing at least one of N, O and S atoms, or being unsubstituted or substituted with a substituent to which two or more substituents of the above-exemplified substituents are connected. For example, “a substituent in which two or more substituents are connected” can be a biphenyl group. Namely, a biphenyl group can be an aryl group, or it can be interpreted as a substituent in which two phenyl groups are connected.

In the present disclosure, the carbon number of a carbonyl group is not particularly limited, but is preferably 1 to 40. Specifically, the carbonyl group can be a compound having the following structural formulas, but is not limited thereto:

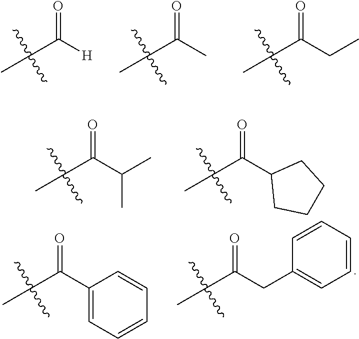

In the present disclosure, an ester group can have a structure in which oxygen of the ester group can be substituted by a straight-chain, branched-chain, or cyclic alkyl group having 1 to 25 carbon atoms, or an aryl group having 6 to 25 carbon atoms. Specifically, the ester group can be a compound having the following structural formulas, but is not limited thereto:

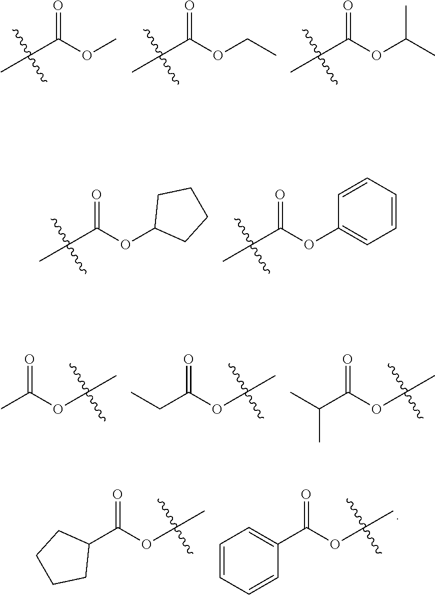

In the present disclosure, the carbon number of an imide group is not particularly limited, but is preferably 1 to 25. Specifically, the imide group can be a compound having the following structural formulas, but is not limited thereto:

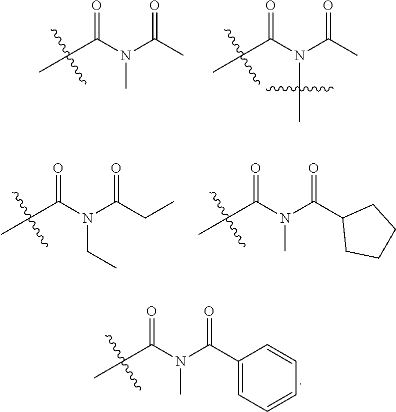

In the present disclosure, a silyl group specifically includes a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but is not limited thereto.

In the present disclosure, a boron group specifically includes a trimethylboron group, a triethylboron group, a t-butyldimethylboron group, a triphenylboron group, and a phenylboron group, but is not limited thereto.

In the present disclosure, examples of a halogen group include fluorine, chlorine, bromine, or iodine.

In the present disclosure, the alkyl group can be straight-chain or branched-chain, and the carbon number thereof is not particularly limited, but is preferably 1 to 40. According to one embodiment, the carbon number of the alkyl group is 1 to 20. According to another embodiment, the carbon number of the alkyl group is 1 to 10. According to another embodiment, the carbon number of the alkyl group is 1 to 6. Specific examples of the alkyl group include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohectylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, and the like, but are not limited thereto.

In the present disclosure, the alkenyl group can be straight-chain or branched-chain, and the carbon number thereof is not particularly limited, but is preferably 2 to 40. According to one embodiment, the carbon number of the alkenyl group is 2 to 20. According to another embodiment, the carbon number of the alkenyl group is 2 to 10. According to still another embodiment, the carbon number of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present disclosure, a cycloalkyl group is not particularly limited, but the carbon number thereof is preferably 3 to 60. According to one embodiment, the carbon number of the cycloalkyl group is 3 to 30. According to another embodiment, the carbon number of the cycloalkyl group is 3 to 20. According to still another embodiment, the carbon number of the cycloalkyl group is 3 to 6. Specific examples thereof include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

In the present disclosure, an aryl group is not particularly limited, but the carbon number thereof is preferably 6 to 60, and it can be a monocyclic aryl group or a polycyclic aryl group. According to one embodiment, the carbon number of the aryl group is 6 to 30. According to one embodiment, the carbon number of the aryl group is 6 to 20. The aryl group can be a phenyl group, a biphenyl group, a terphenyl group or the like as the monocyclic aryl group, but is not limited thereto. The polycyclic aryl group includes a naphthyl group, an anthracenyl group, a phenanthrenyl group, a pyrenyl group, a perylenyl group, a chrysenyl group, or the like, but is not limited thereto.

In the present disclosure, the fluorenyl group can be substituted, and two substituents can be linked with each other to form a spiro structure. In the case where the fluorenyl group is substituted,

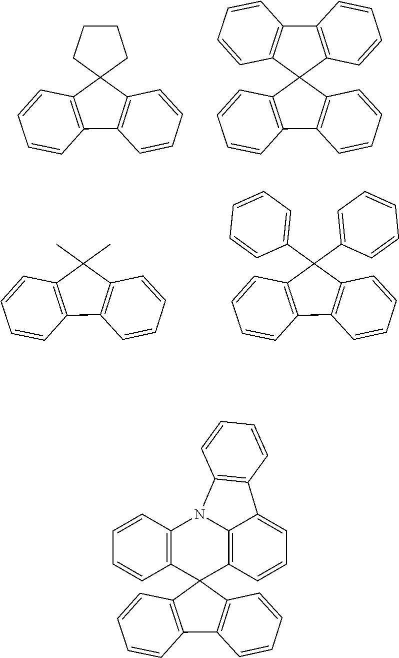

and the like can be formed. However, the structure is not limited thereto.

In the present disclosure, a heterocyclic group is a heterocyclic group containing one or more of O, N, Si and S as a heteroatom, and the carbon number thereof is not particularly limited, but is preferably 2 to 60. Examples of the heterocyclic group include a thiophene group, a furan group, a pyrrole group, an imidazole group, a thiazole group, an oxazol group, an oxadiazol group, a triazol group, a pyridyl group, a bipyridyl group, a pyrimidyl group, a triazine group, an acridyl group, a pyridazine group, a pyrazinyl group, a quinolinyl group, a quinazoline group, a quinoxalinyl group, a phthalazinyl group, a pyridopyrimidinyl group, a pyridopyrazinyl group, a pyrazinopyrazinyl group, an isoquinoline group, an indole group, a carbazole group, a benzoxazole group, a benzoimidazole group, a benzothiazol group, a benzocarbazole group, a benzothiophene group, a dibenzothiophene group, a benzofuranyl group, a phenanthroline group, an isoxazolyl group, a thiadiazolyl group, a phenothiazinyl group, a dibenzofuranyl group, and the like, but are not limited thereto.

In the present disclosure, the aryl group in the aralkyl group, the aralkenyl group, the alkylaryl group and the arylamine group is the same as the aforementioned examples of the aryl group. In the present disclosure, the alkyl group in the aralkyl group, the alkylaryl group and the alkylamine group is the same as the aforementioned examples of the alkyl group. In the present disclosure, the heteroaryl in the heteroarylamine can be applied to the aforementioned description of the heterocyclic group. In the present disclosure, the alkenyl group in the aralkenyl group is the same as the aforementioned examples of the alkenyl group. In the present disclosure, the aforementioned description of the aryl group can be applied except that the arylene is a divalent group. In the present disclosure, the aforementioned description of the heterocyclic group can be applied except that the heteroarylene is a divalent group. In the present disclosure, the aforementioned description of the aryl group or cycloalkyl group can be applied except that the hydrocarbon ring is not a monovalent group but formed by combining two substituent groups. In the present disclosure, the aforementioned description of the heterocyclic group can be applied, except that the heterocycle is not a monovalent group but formed by combining two substituent groups.

Light Emitting Layer and Hole Adjustment Layer

The present disclosure has the feature that the organic light emitting device includes an anode; a hole transport layer; a hole adjustment layer; a light emitting layer; an electron transport layer; and a cathode, the light emitting layer includes a host and a dopant, and the compound contained in the host and the hole adjustment layer has a specific dipole moment value.

The term “dipole moment” as used herein refers to a physical quantity indicating the degree of polarity, and can be calculated according to the following Equation 1:

$$p ( r ) = {\int }_{V} ρ ( {r}_{0} ) ( {r}_{0} - r ) {d}^{3} {r}_{0} \\ ρ ( {r}_{0} ) \text{:} molecular density \\ V \text{:} volume \\ r \text{:} the point of observation \\ {d}^{3} {r}_{0} \text{:} an elementary volume . \qquad \text{<} Equation 1 \text{>}$$

wherein in the Equation 1, the value of the dipole moment can be obtained by calculating the molecular density. For example, the molecular density can be obtained by calculating the charge and dipole of each atom using Hirshfeld Charge Analysis method, and then calculating it based on the following Equation. The dipole moment can be obtained by substituting the calculation result into the Equation 1.

$$\begin{matrix}{W}_{α} ( r ) = {{ρ}_{α} ( r - {R}_{α} ) [ {\sum }_{ρ} {ρ}_{β} ( r - {R}_{β} ) ]}^{- 1} \\ {ρ}_{α} ( r - {R}_{α} ) \text{:} spherically averaged ground \text{-} state amomic density \\ {\sum }_{ρ} {ρ}_{β} ( r - {R}_{β} ) \text{:} promolecule density & Weight Function \\ {ρ}_{d} ( r ) = ρ ( r ) - {\sum }_{α} {ρ}_{α} ( r - {R}_{α} ) \\ ρ ( r ) \text{:} molecular density \\ {ρ}_{α} ( r - {R}_{α} ) \text{:} density of the free atom α located at coordinates {R}_{α} & Deformation Density \\ q ( α ) = - \int {ρ}_{d} ( r ) {W}_{α} ( r ) {d}^{3} r \\ {W}_{α} ( r ) \text{:} weight function & Atomic Charge\end{matrix}$$

In order to optimize the light emission characteristics of an organic light emitting device, the dipole moment of the host compound of the light emitting layer must be considered. In the present disclosure, it was confirmed that when the compound contained in the host and the hole adjustment layer has a specific dipole moment value, it is possible to have a low driving voltage, high luminous efficiency, and long lifetime characteristics. Specifically, the organic light emitting device includes a compound in which a dipole moment value of the host is 0.4 to 1.3 and a dipole moment value of a compound used as the hole adjustment layer is 1.2 to 2.0. Preferably, the difference between the dipole moment value of the host and the dipole moment value of the compound contained in the hole adjustment layer is 0.15 to 1.25.

Preferably, the maximum emission peak wavelength of the light emitting layer is 400 nm to 470 nm.

Preferably, the triplet energy of the compound contained in the hole adjustment layer is greater than the triplet energy of the host.

Preferably, a compound of Chemical Formula 1 can be used as the host used above:

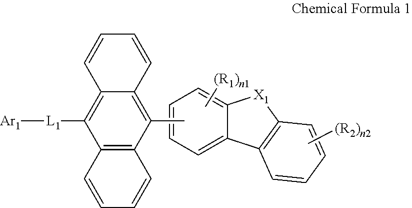

wherein in Chemical Formula 1:

X₁ is O or S;

L₁ is a single bond or a substituted or unsubstituted C₆₋₆₀ arylene;

Ar₁ is a substituted or unsubstituted C₆₋₆₀ aryl;

R₁ and R₂ are each independently hydrogen, deuterium, halogen, cyano, nitro, amino, a substituted or unsubstituted C₁₋₆₀ alkyl, a substituted or unsubstituted C₃₋₆₀ cycloalkyl, a substituted or unsubstituted C₂₋₆₀ alkenyl, a substituted or unsubstituted C₆₋₆₀ aryl, or a substituted or unsubstituted C₂₋₆₀ heteroaryl containing one or more heteroatoms selected from the group consisting of N, O and S, or two adjacent groups are bonded with each other to form a benzene ring;

n1 is an integer from 0 to 3; and

n2 is an integer from 0 to 4.

Preferably, L₁ is a single bond or phenylene.

Preferably, Ar₁ is phenyl, biphenylyl, terphenylyl, naphthyl, or naphthylphenyl.

Preferably, R₁ is hydrogen, deuterium, or phenyl.

Preferably, R₂ is hydrogen, deuterium, phenyl, biphenyl, or naphthyl.

Representative examples of the compound of Chemical Formula 1 are as follows:

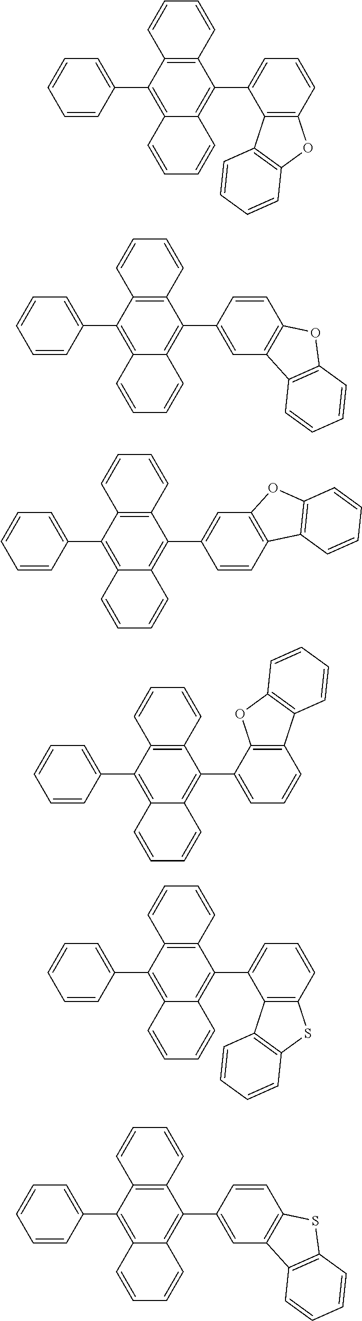

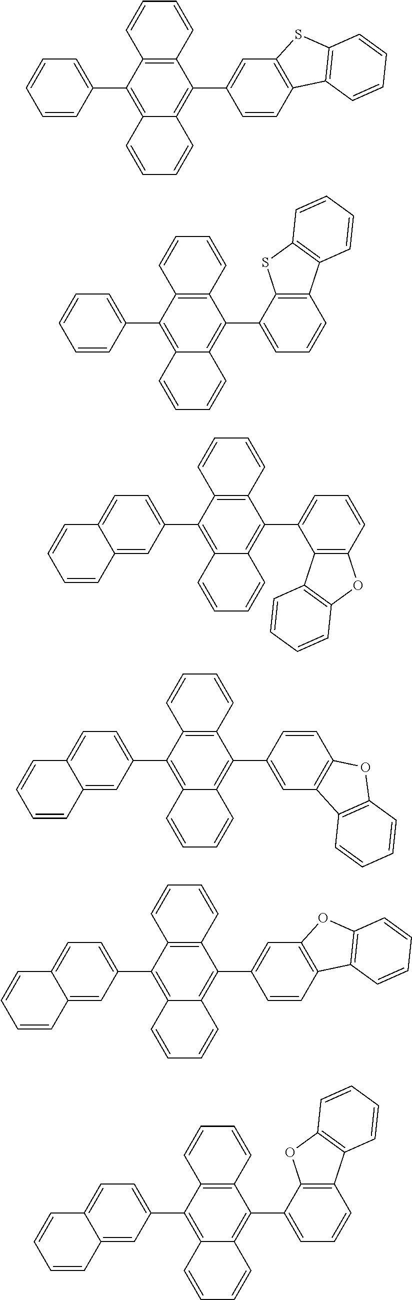

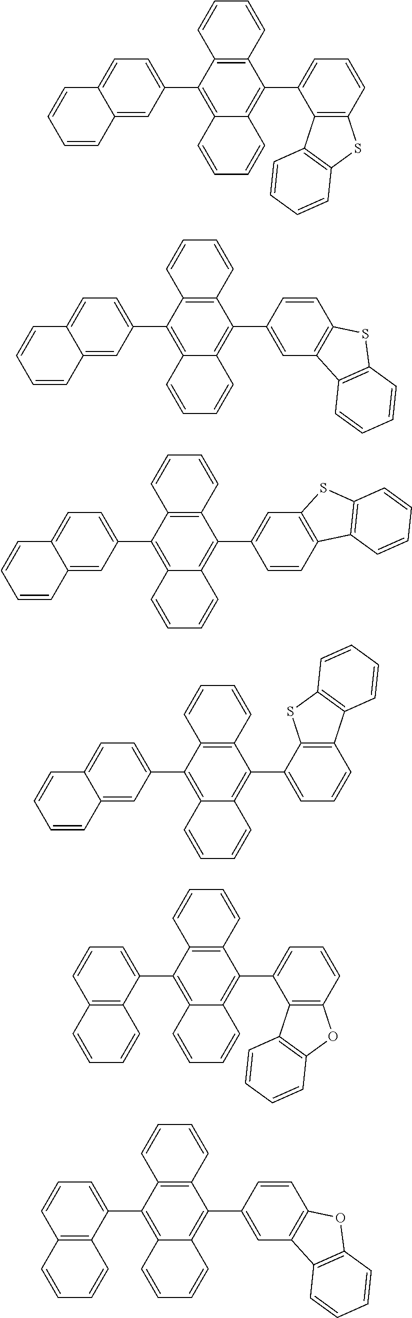

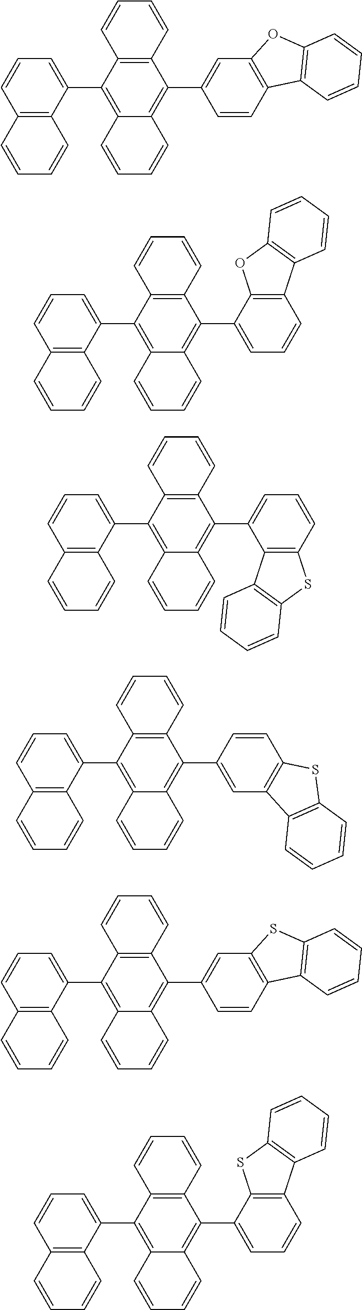

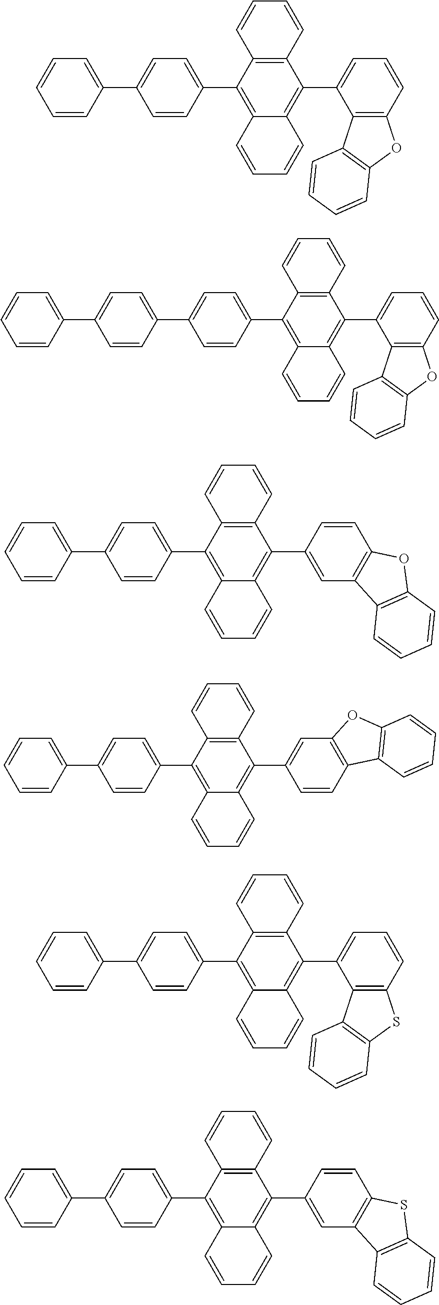

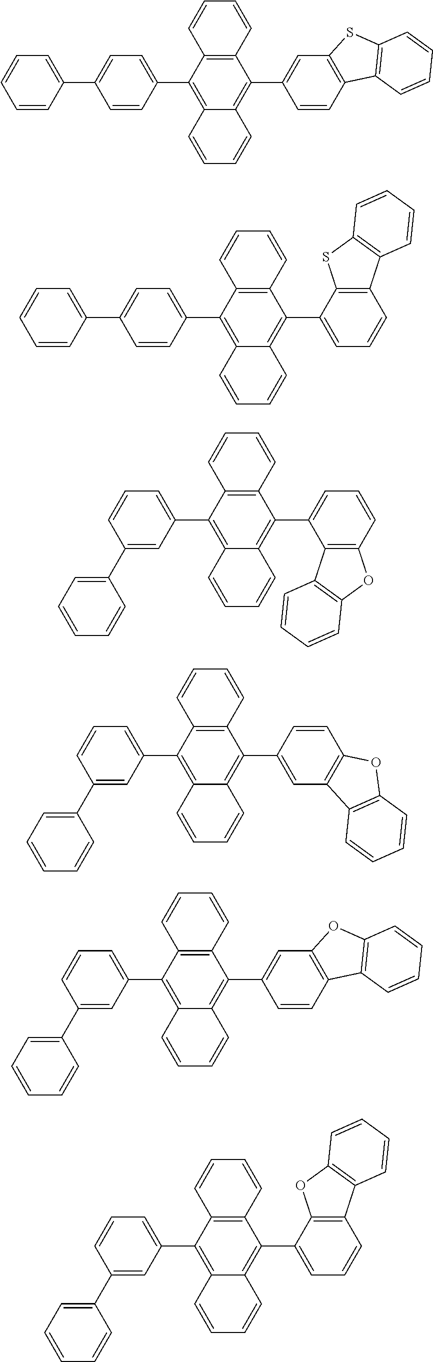

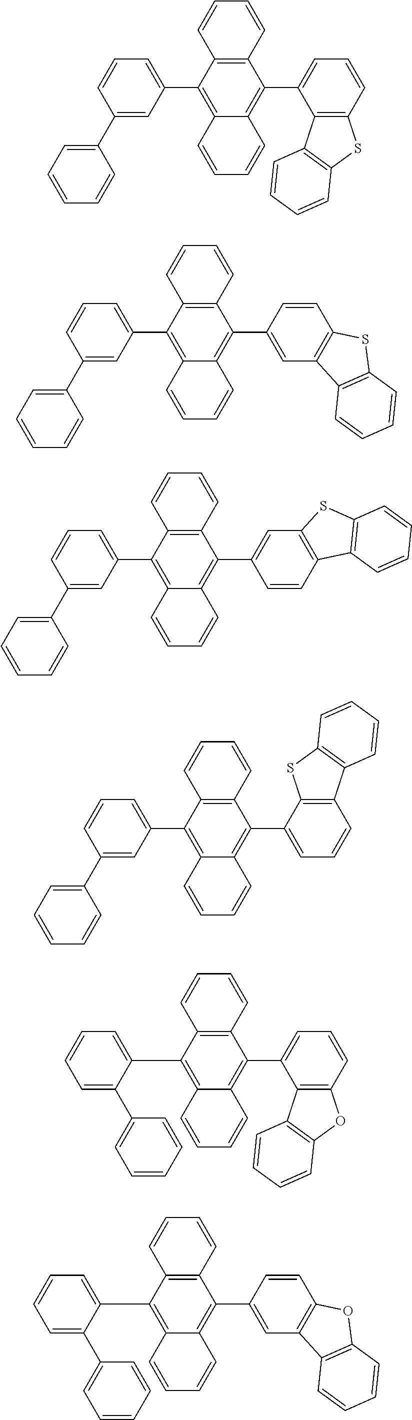

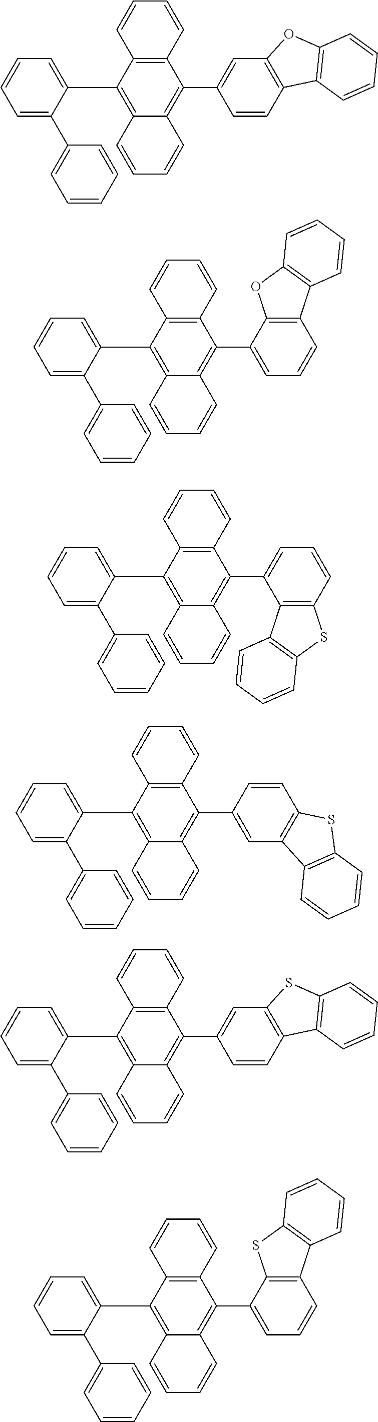

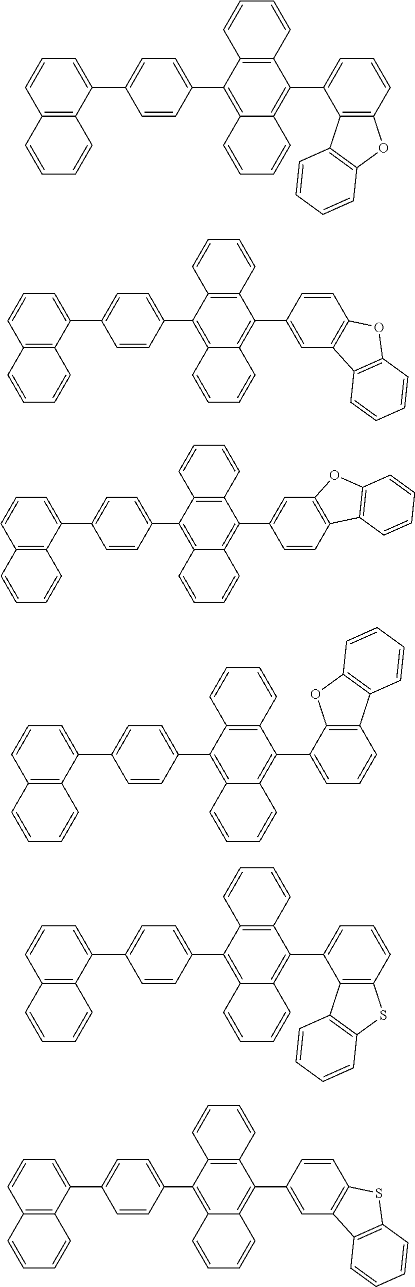

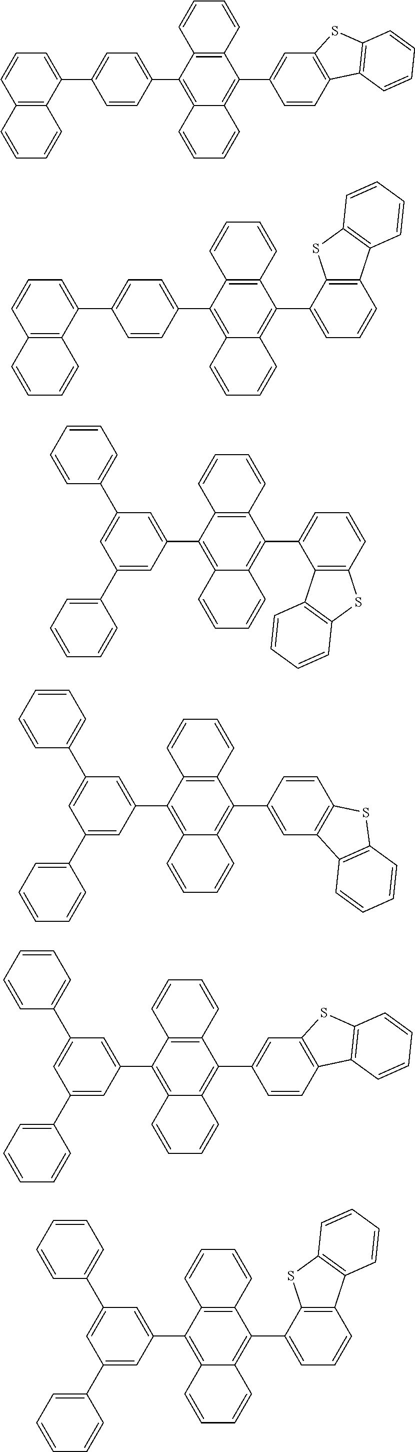

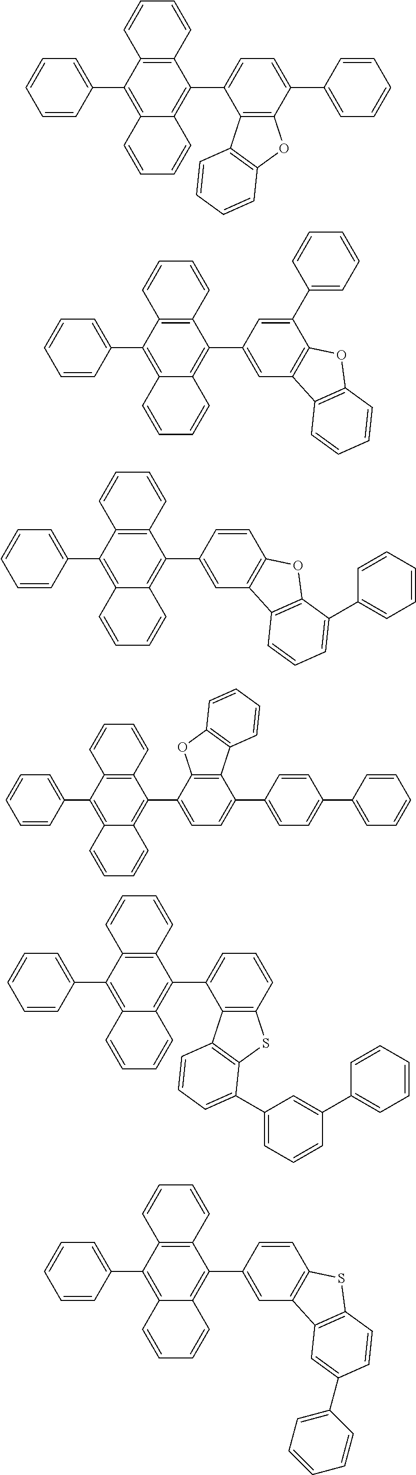

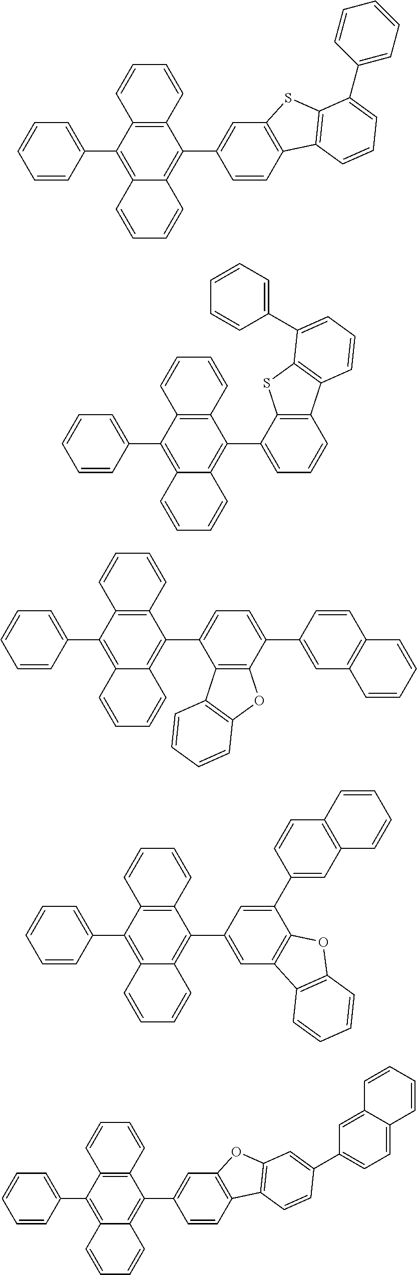

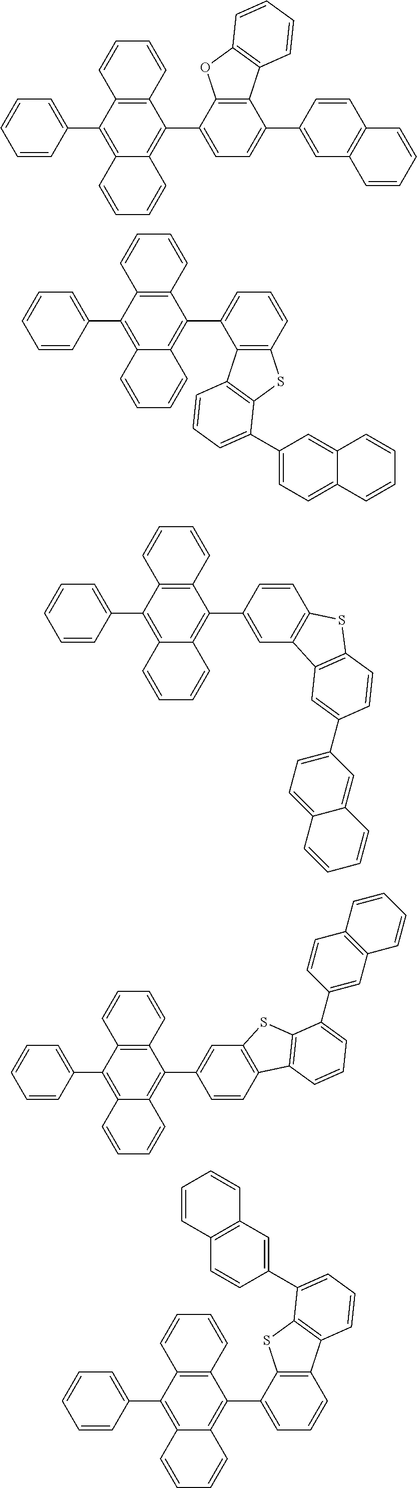

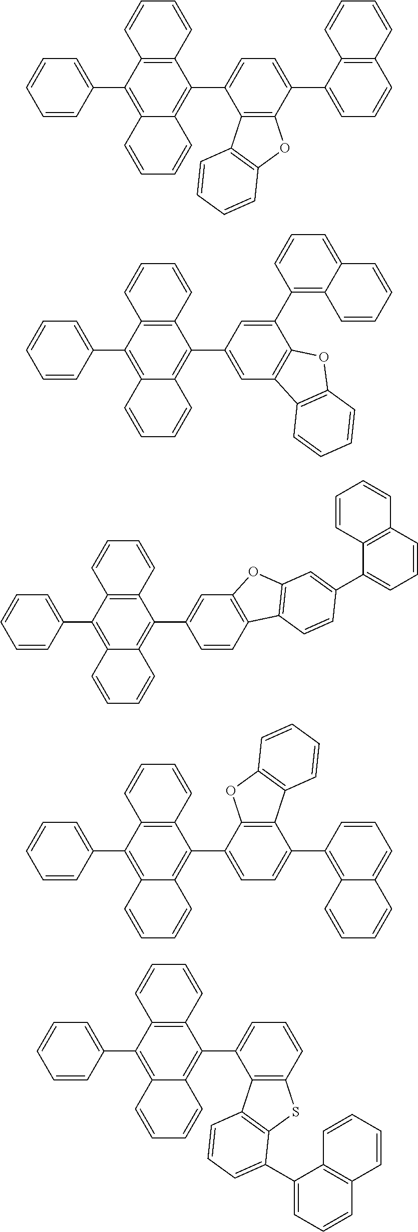

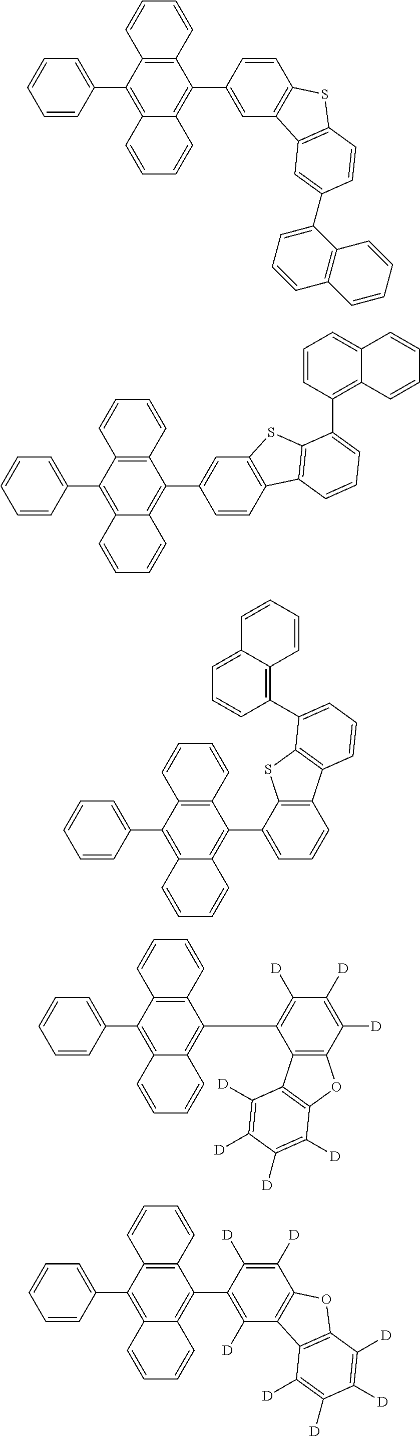

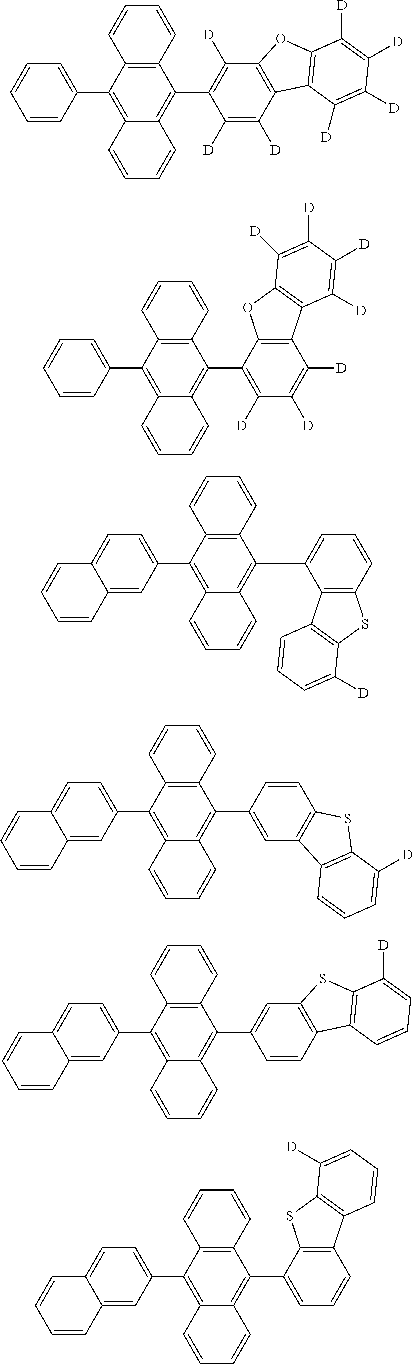

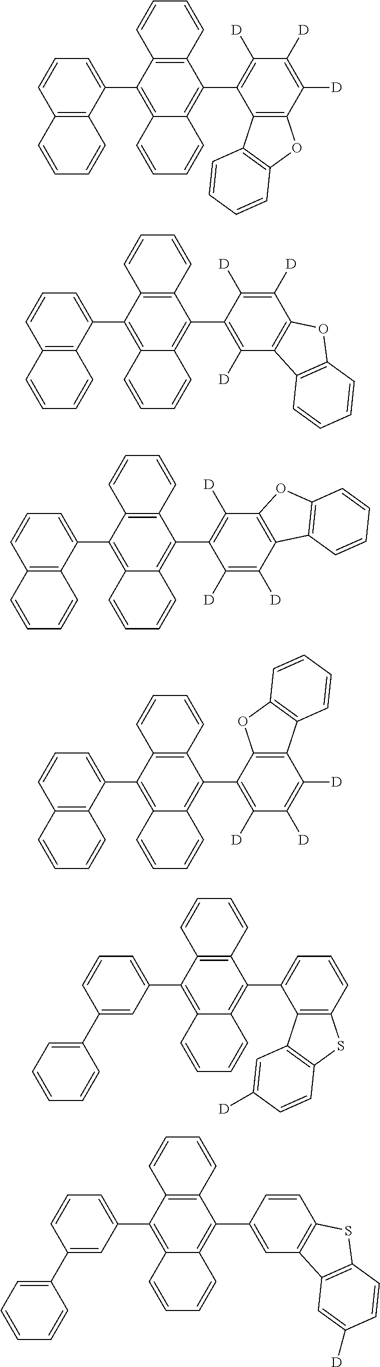

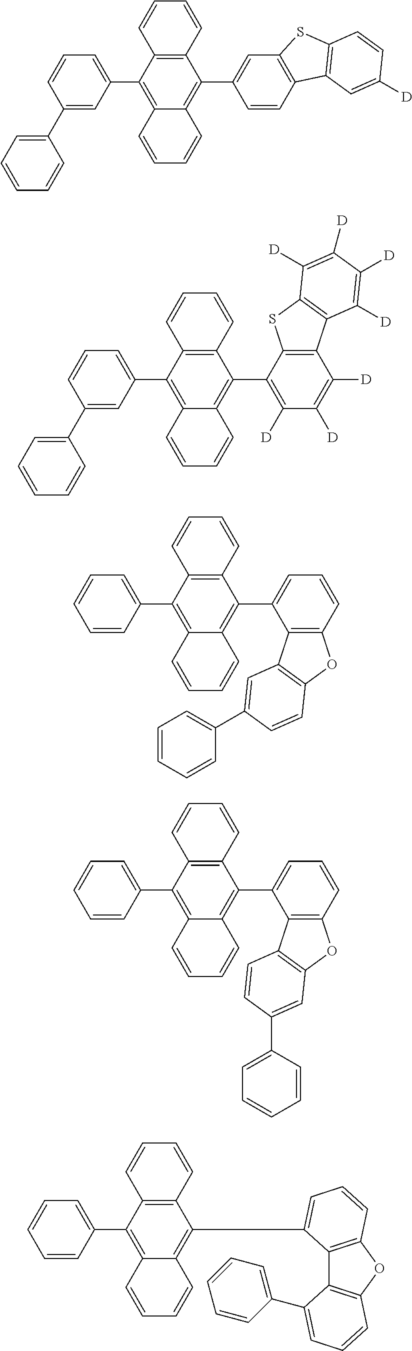

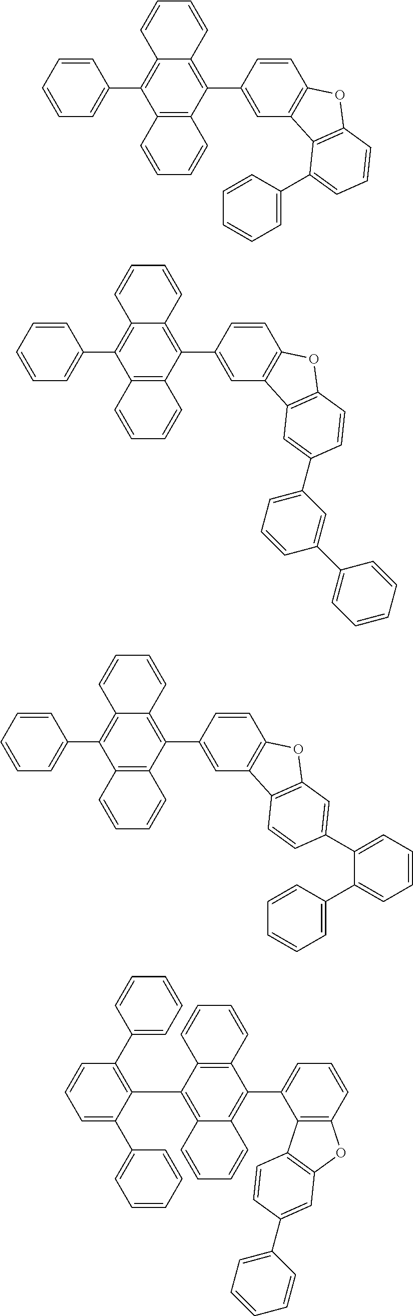 [SMILES: c1ccc(-c2c3ccccc3c(-c3ccc4oc5cccc(-c6ccccc6)c5c4c3)c3ccccc23)cc1 ; c1ccc(-c2cccc(-c3ccc4oc5ccc(-c6c7ccccc7c(-c7ccccc7)c7ccccc67)cc5c4c3)c2)cc1 ; c1ccc(-c2ccccc2-c2ccc3c(c2)oc2ccc(-c4c5ccccc5c(-c5ccccc5)c5ccccc45)cc23)cc1 ; c1ccc(-c2ccc3c(c2)oc2cccc(-c4c5ccccc5c(-c5c(-c6ccccc6)cccc5-c5ccccc5)c5ccccc45)c23)cc1]

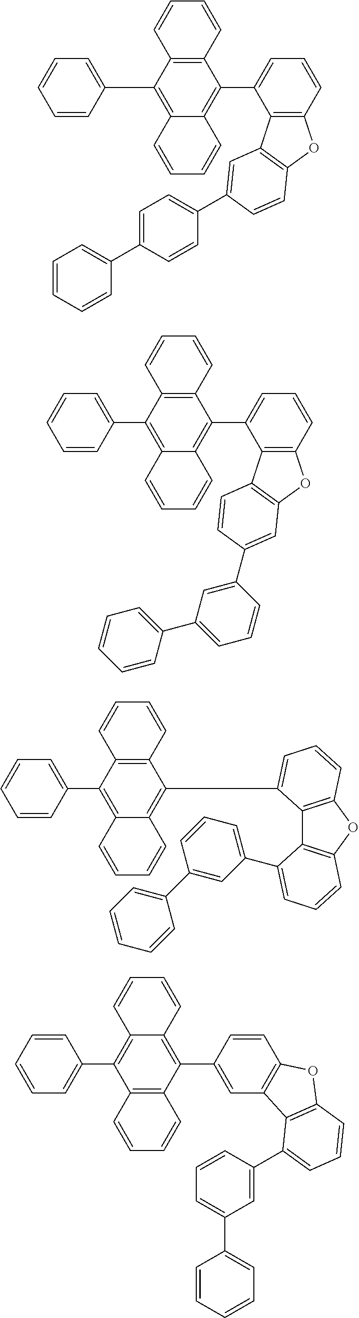

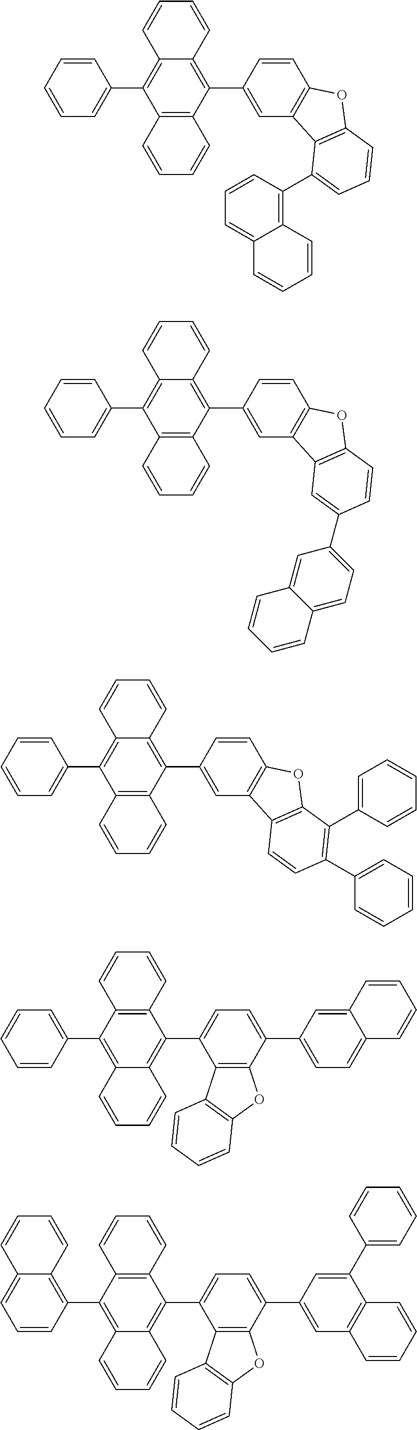 [SMILES: c1ccc(-c2c3ccccc3c(-c3ccc4oc5cccc(-c6cccc7ccccc67)c5c4c3)c3ccccc23)cc1 ; c1ccc(-c2c3ccccc3c(-c3ccc4oc5ccc(-c6ccc7ccccc7c6)cc5c4c3)c3ccccc23)cc1 ; c1ccc(-c2ccc3c(oc4ccc(-c5c6ccccc6c(-c6ccccc6)c6ccccc56)cc43)c2-c2ccccc2)cc1 ; c1ccc(-c2c3ccccc3c(-c3ccc(-c4ccc5ccccc5c4)c4oc5ccccc5c34)c3ccccc23)cc1 ; c1ccc(-c2cc(-c3ccc(-c4c5ccccc5c(-c5cccc6ccccc56)c5ccccc45)c4c3oc3ccccc34)cc3ccccc23)cc1]

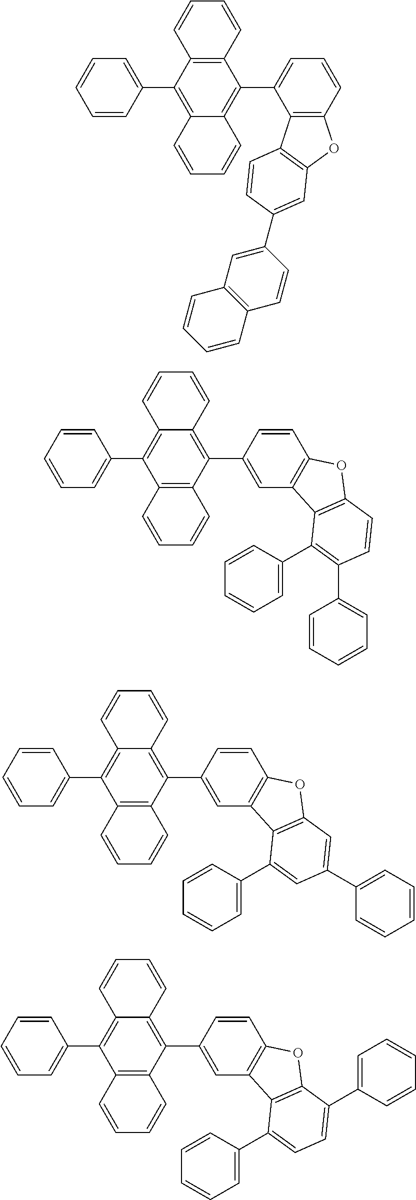

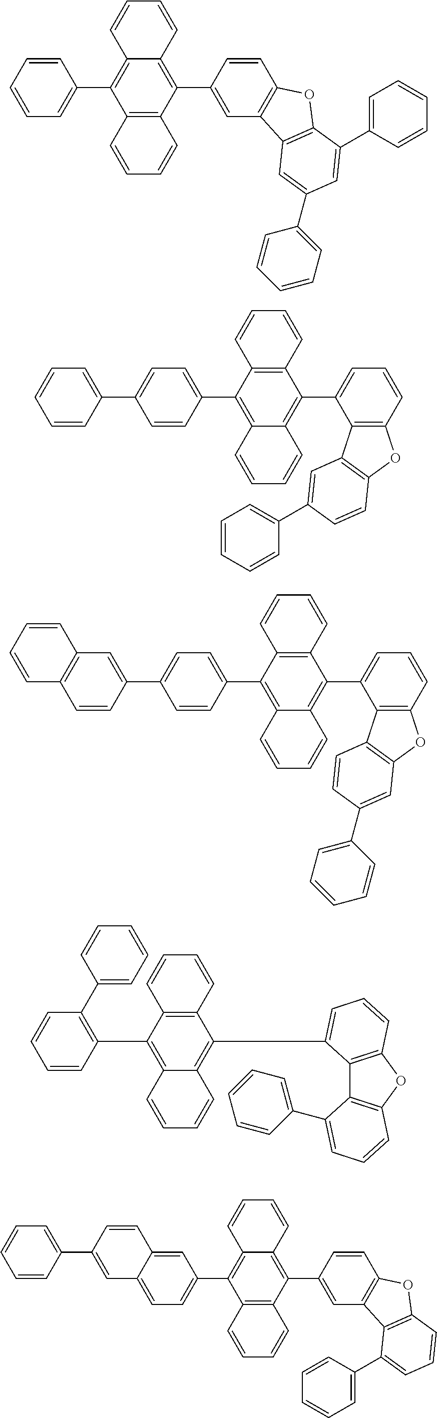

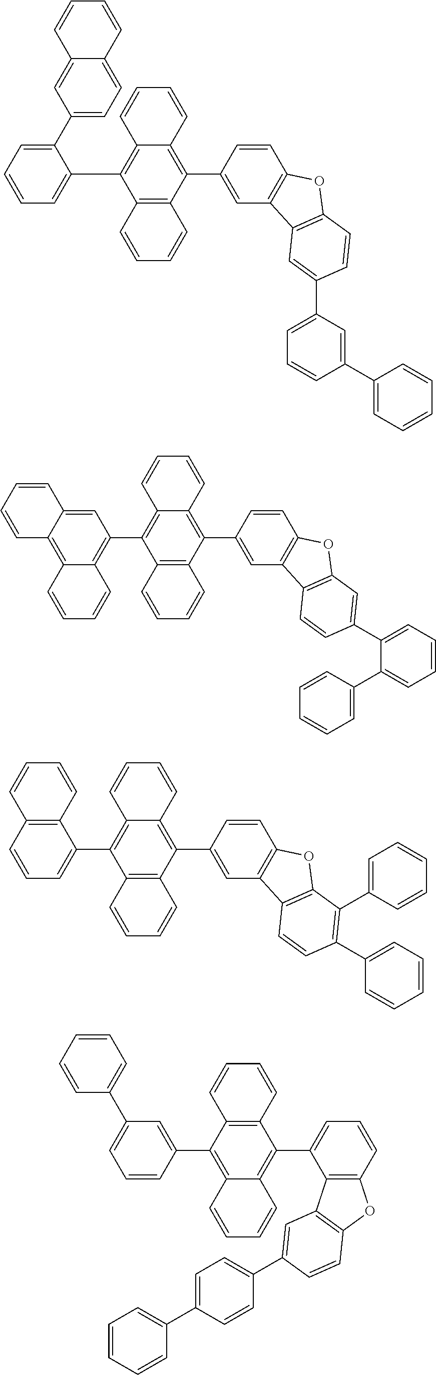 [SMILES: c1ccc(-c2cccc(-c3ccc4oc5ccc(-c6c7ccccc7c(-c7ccccc7-c7ccc8ccccc8c7)c7ccccc67)cc5c4c3)c2)cc1 ; c1ccc(-c2ccccc2-c2ccc3c(c2)oc2ccc(-c4c5ccccc5c(-c5cc6ccccc6c6ccccc56)c5ccccc45)cc23)cc1 ; c1ccc(-c2ccc3c(oc4ccc(-c5c6ccccc6c(-c6cccc7ccccc67)c6ccccc56)cc43)c2-c2ccccc2)cc1 ; c1ccc(-c2ccc(-c3ccc4oc5cccc(-c6c7ccccc7c(-c7cccc(-c8ccccc8)c7)c7ccccc67)c5c4c3)cc2)cc1]

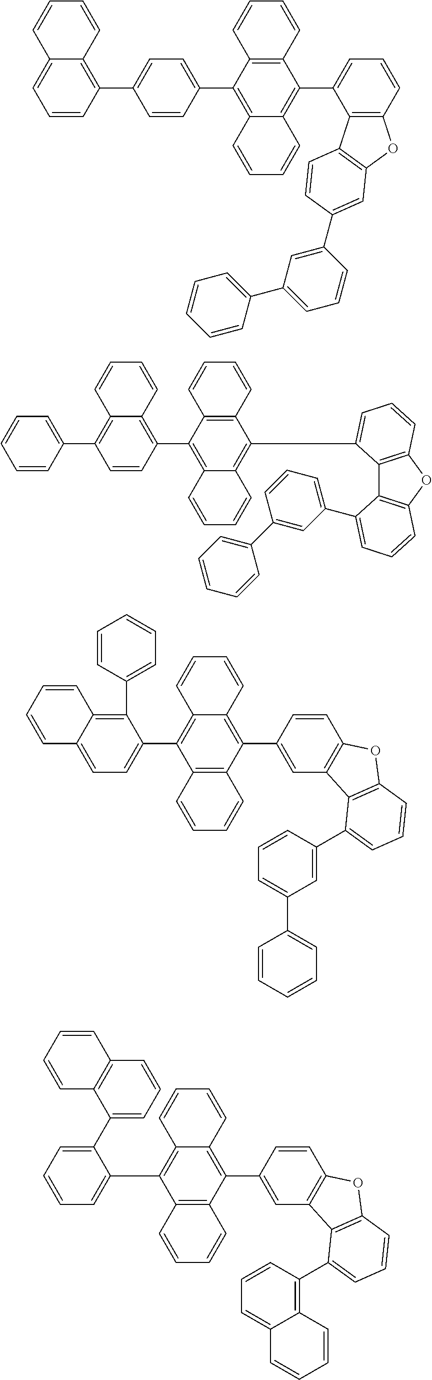

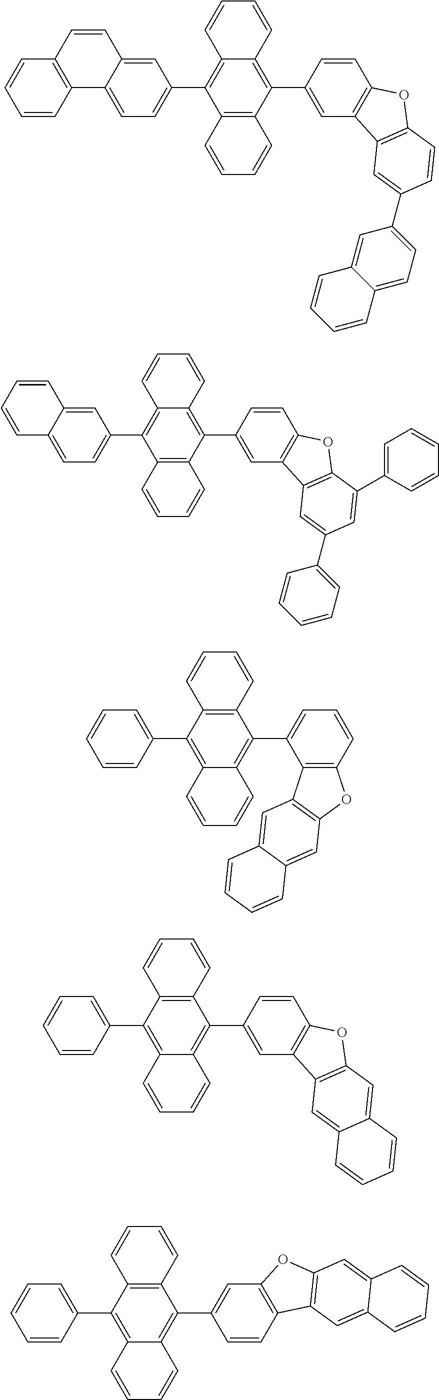 [SMILES: c1ccc2cc(-c3ccc4oc5ccc(-c6c7ccccc7c(-c7ccc8c(ccc9ccccc98)c7)c7ccccc67)cc5c4c3)ccc2c1 ; c1ccc(-c2cc(-c3ccccc3)c3oc4ccc(-c5c6ccccc6c(-c6ccc7ccccc7c6)c6ccccc56)cc4c3c2)cc1 ; c1ccc(-c2c3ccccc3c(-c3cccc4oc5cc6ccccc6cc5c34)c3ccccc23)cc1 ; c1ccc(-c2c3ccccc3c(-c3ccc4oc5cc6ccccc6cc5c4c3)c3ccccc23)cc1 ; c1ccc(-c2c3ccccc3c(-c3ccc4c(c3)oc3cc5ccccc5cc34)c3ccccc23)cc1]

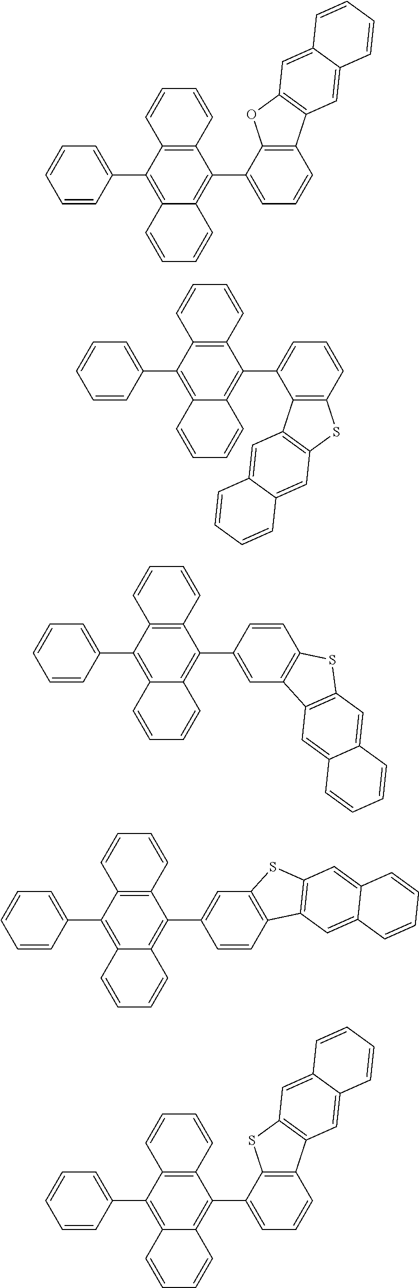

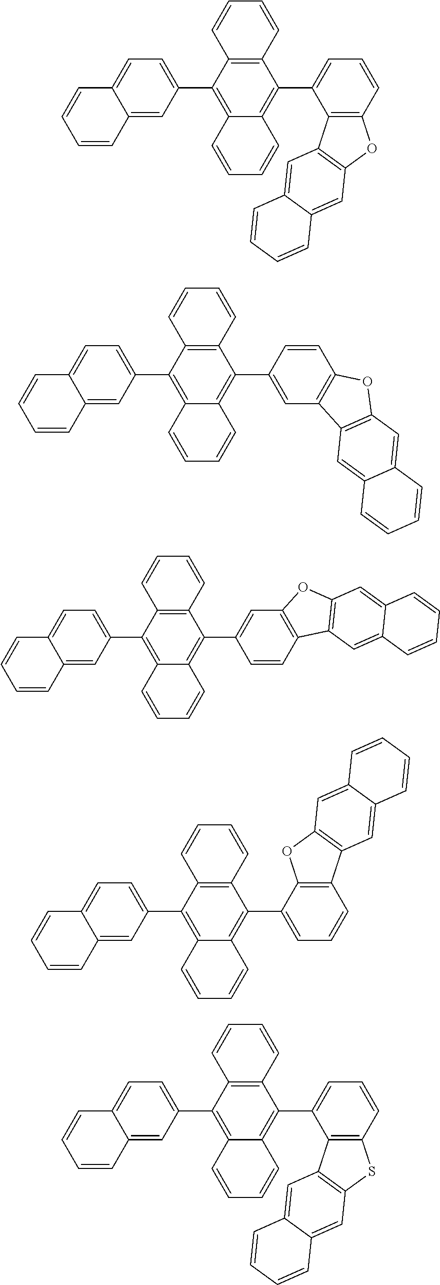

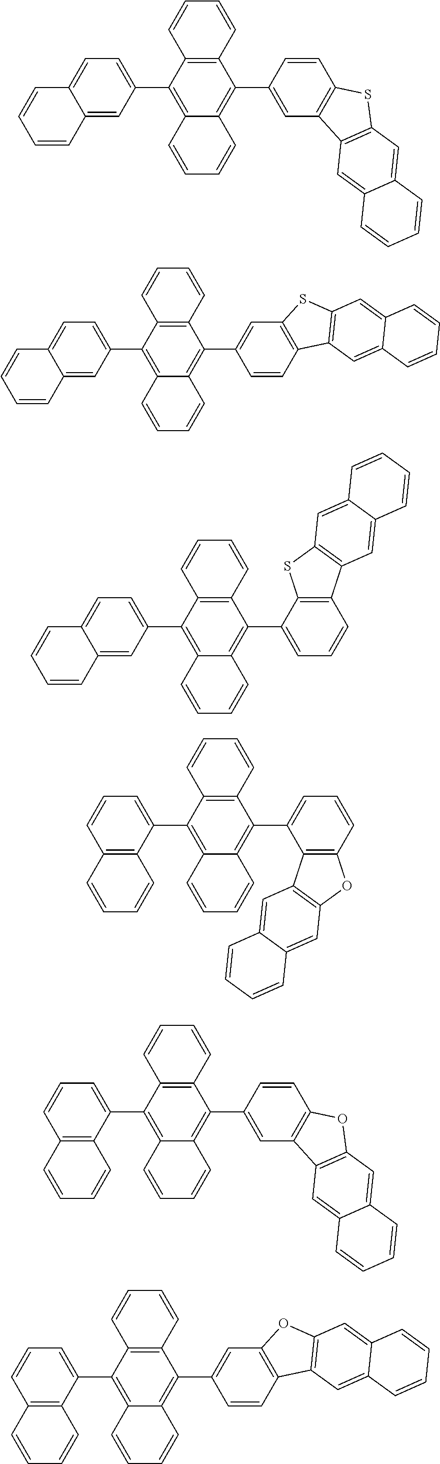

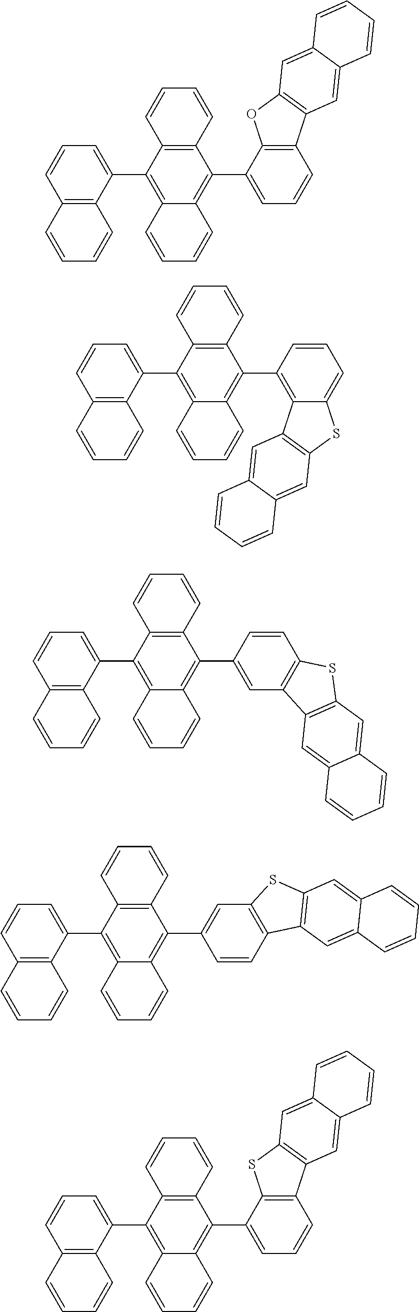

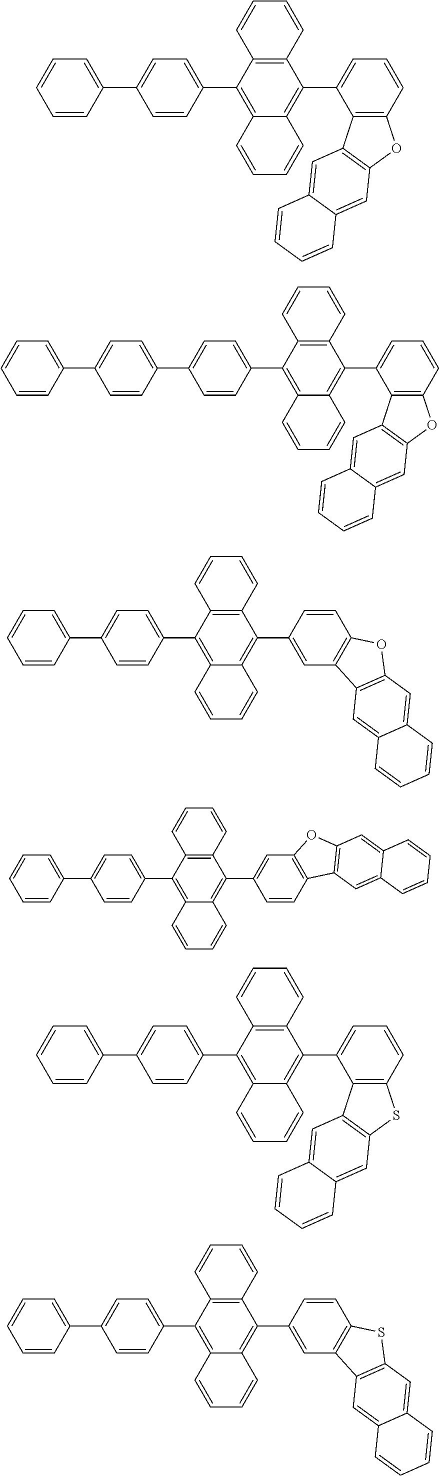

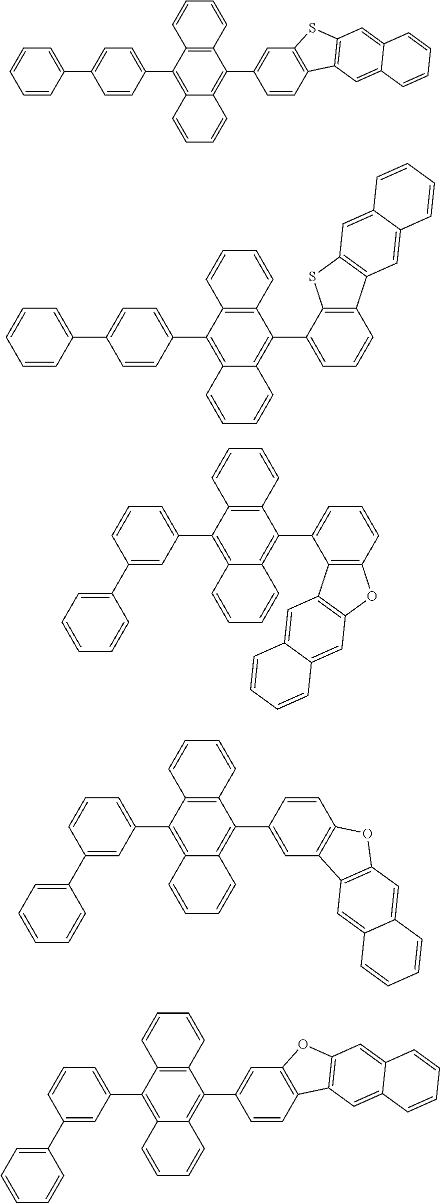

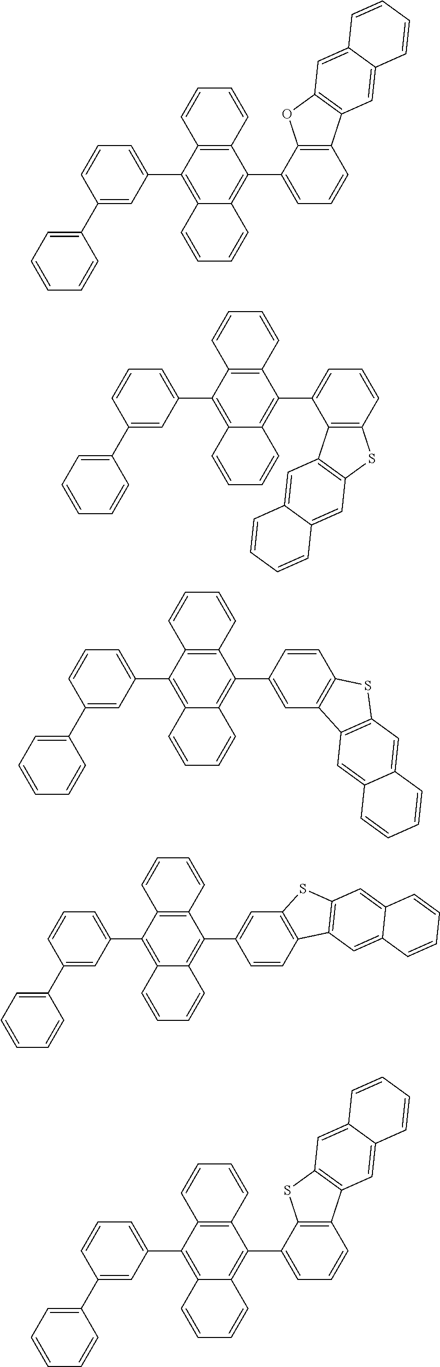 [SMILES: c1ccc(-c2cccc(-c3c4ccccc4c(-c4cccc5c4oc4cc6ccccc6cc45)c4ccccc34)c2)cc1 ; c1ccc(-c2cccc(-c3c4ccccc4c(-c4cccc5sc6cc7ccccc7cc6c45)c4ccccc34)c2)cc1 ; c1ccc(-c2cccc(-c3c4ccccc4c(-c4ccc5sc6cc7ccccc7cc6c5c4)c4ccccc34)c2)cc1 ; c1ccc(-c2cccc(-c3c4ccccc4c(-c4ccc5c(c4)sc4cc6ccccc6cc45)c4ccccc34)c2)cc1 ; c1ccc(-c2cccc(-c3c4ccccc4c(-c4cccc5c4sc4cc6ccccc6cc45)c4ccccc34)c2)cc1]

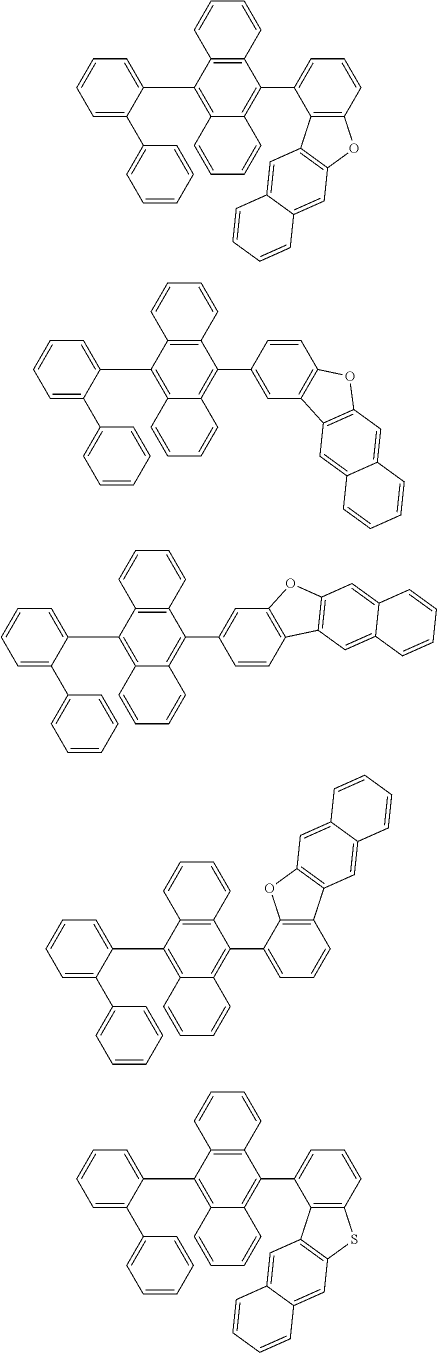 [SMILES: c1ccc(-c2ccccc2-c2c3ccccc3c(-c3cccc4oc5cc6ccccc6cc5c34)c3ccccc23)cc1 ; c1ccc(-c2ccccc2-c2c3ccccc3c(-c3ccc4oc5cc6ccccc6cc5c4c3)c3ccccc23)cc1 ; c1ccc(-c2ccccc2-c2c3ccccc3c(-c3ccc4c(c3)oc3cc5ccccc5cc34)c3ccccc23)cc1 ; c1ccc(-c2ccccc2-c2c3ccccc3c(-c3cccc4c3oc3cc5ccccc5cc34)c3ccccc23)cc1 ; c1ccc(-c2ccccc2-c2c3ccccc3c(-c3cccc4sc5cc6ccccc6cc5c34)c3ccccc23)cc1]

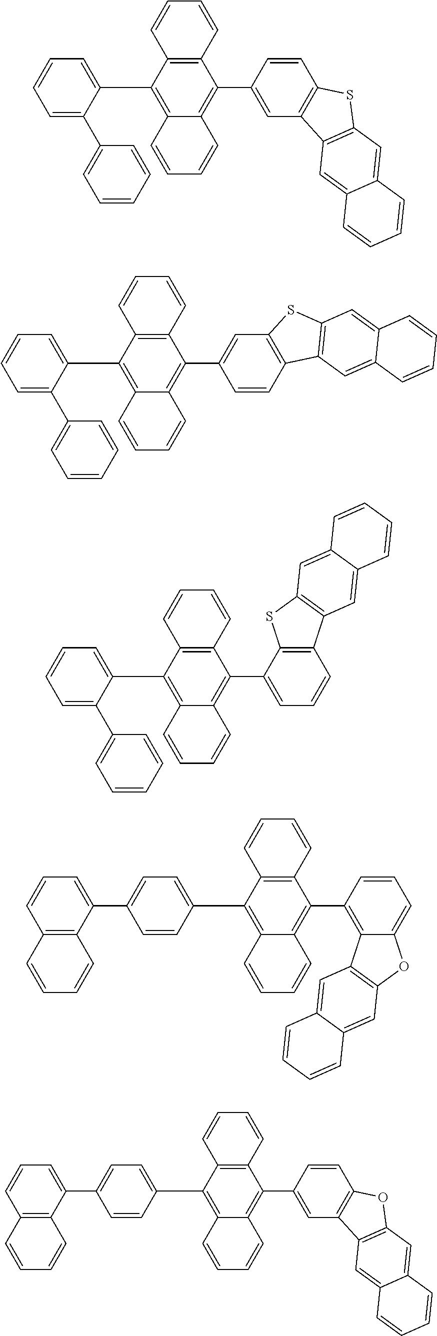 [SMILES: c1ccc(-c2ccccc2-c2c3ccccc3c(-c3ccc4sc5cc6ccccc6cc5c4c3)c3ccccc23)cc1 ; c1ccc(-c2ccccc2-c2c3ccccc3c(-c3ccc4c(c3)sc3cc5ccccc5cc34)c3ccccc23)cc1 ; c1ccc(-c2ccccc2-c2c3ccccc3c(-c3cccc4c3sc3cc5ccccc5cc34)c3ccccc23)cc1 ; c1ccc2cc3c(cc2c1)oc1cccc(-c2c4ccccc4c(-c4ccc(-c5cccc6ccccc56)cc4)c4ccccc24)c13 ; c1ccc2cc3c(cc2c1)oc1ccc(-c2c4ccccc4c(-c4ccc(-c5cccc6ccccc56)cc4)c4ccccc24)cc13]

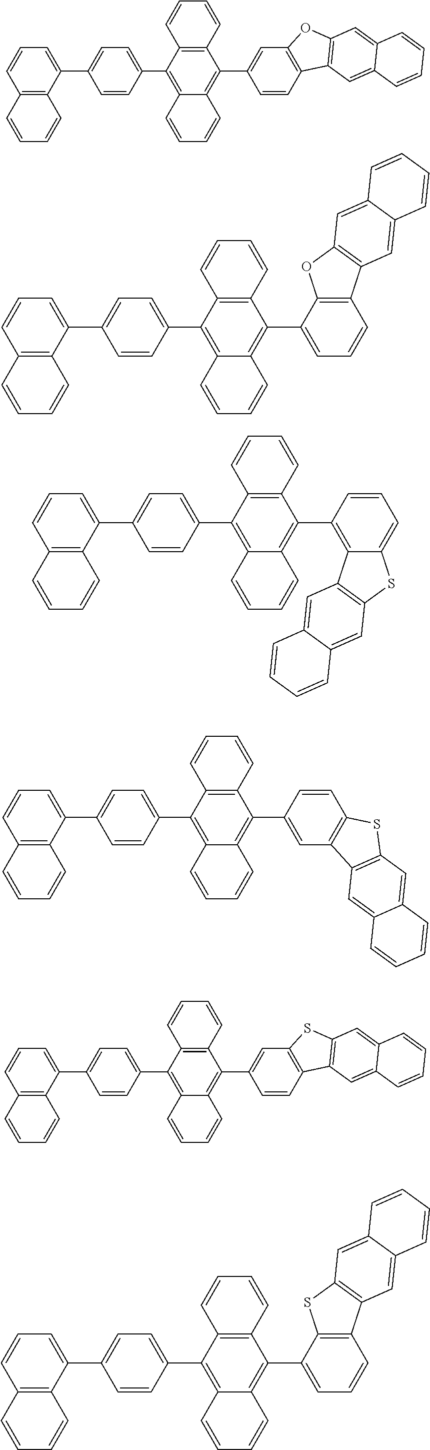

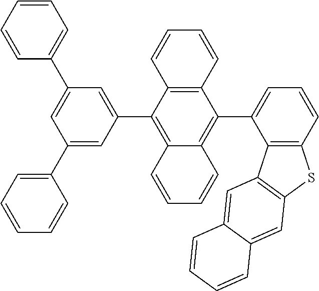 [SMILES: c1ccc(-c2cc(-c3ccccc3)cc(-c3c4ccccc4c(-c4cccc5sc6cc7ccccc7cc6c45)c4ccccc34)c2)cc1]

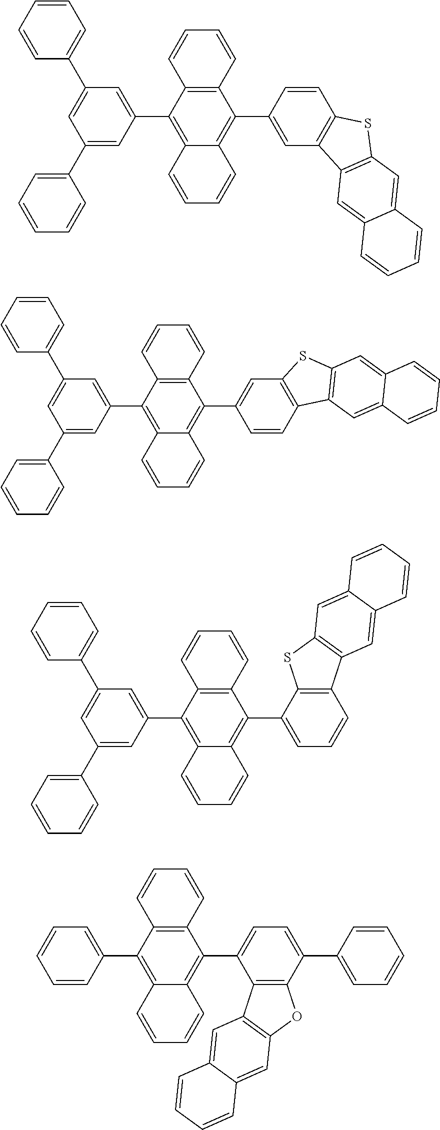 [SMILES: c1ccc(-c2cc(-c3ccccc3)cc(-c3c4ccccc4c(-c4ccc5sc6cc7ccccc7cc6c5c4)c4ccccc34)c2)cc1 ; c1ccc(-c2cc(-c3ccccc3)cc(-c3c4ccccc4c(-c4ccc5c(c4)sc4cc6ccccc6cc45)c4ccccc34)c2)cc1 ; c1ccc(-c2cc(-c3ccccc3)cc(-c3c4ccccc4c(-c4cccc5c4sc4cc6ccccc6cc45)c4ccccc34)c2)cc1 ; c1ccc(-c2c3ccccc3c(-c3ccc(-c4ccccc4)c4oc5cc6ccccc6cc5c34)c3ccccc23)cc1]

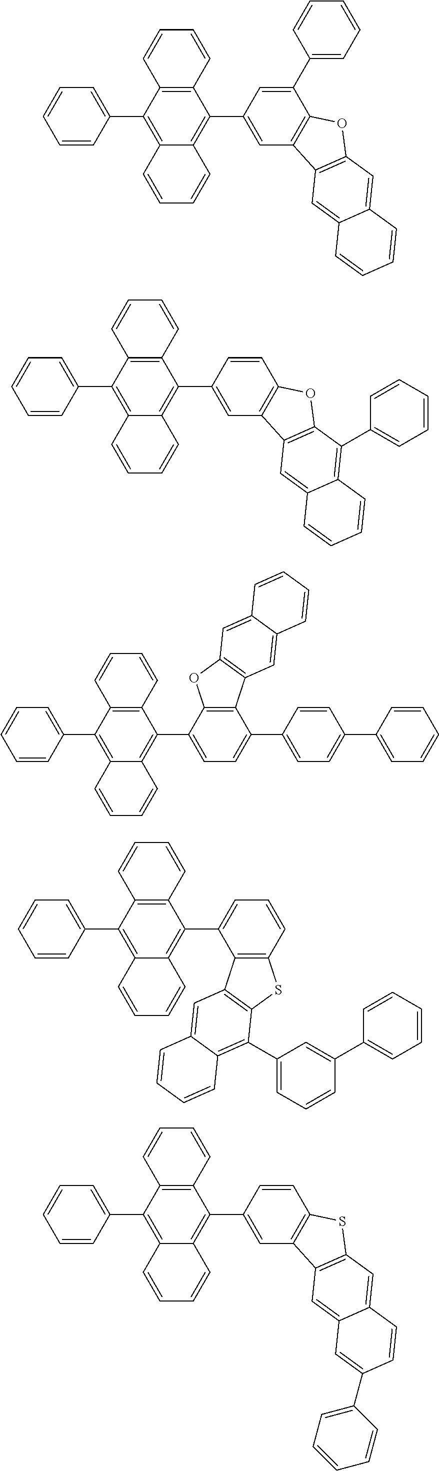

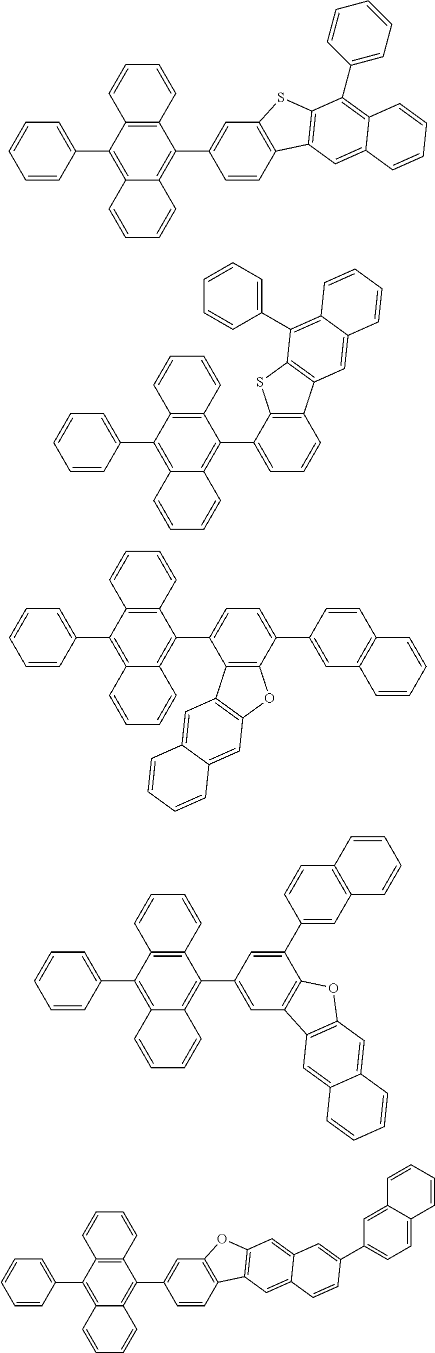

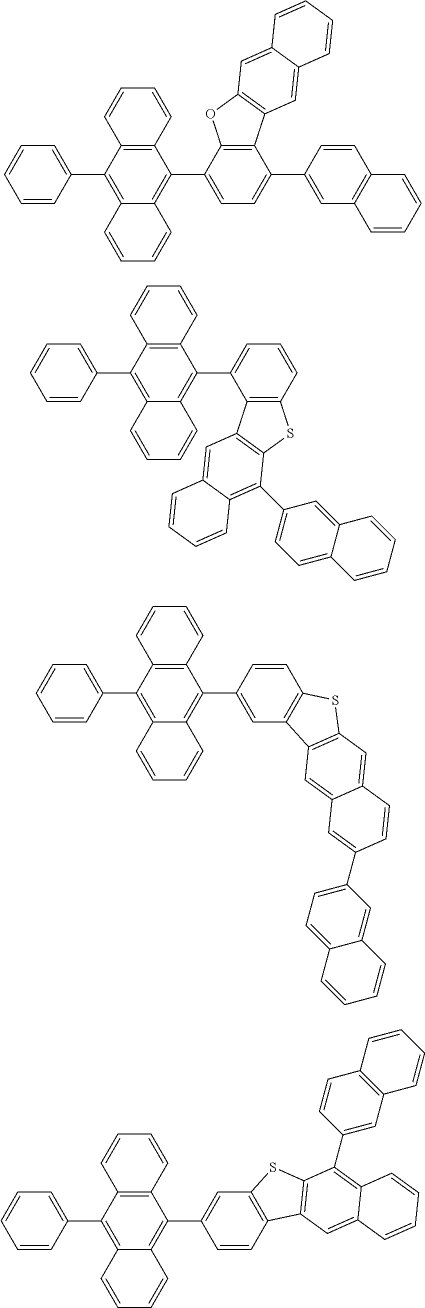

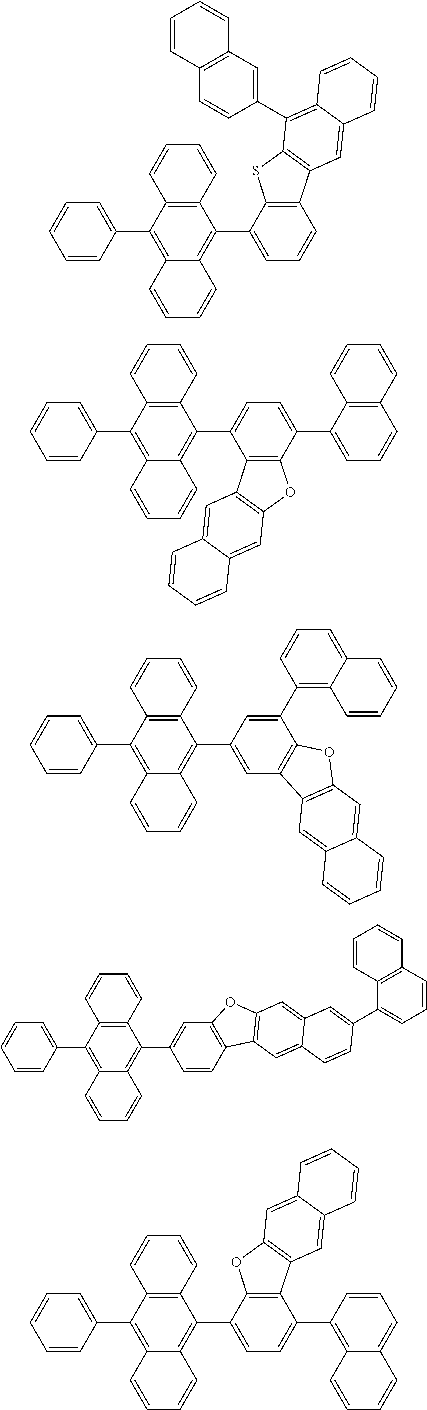

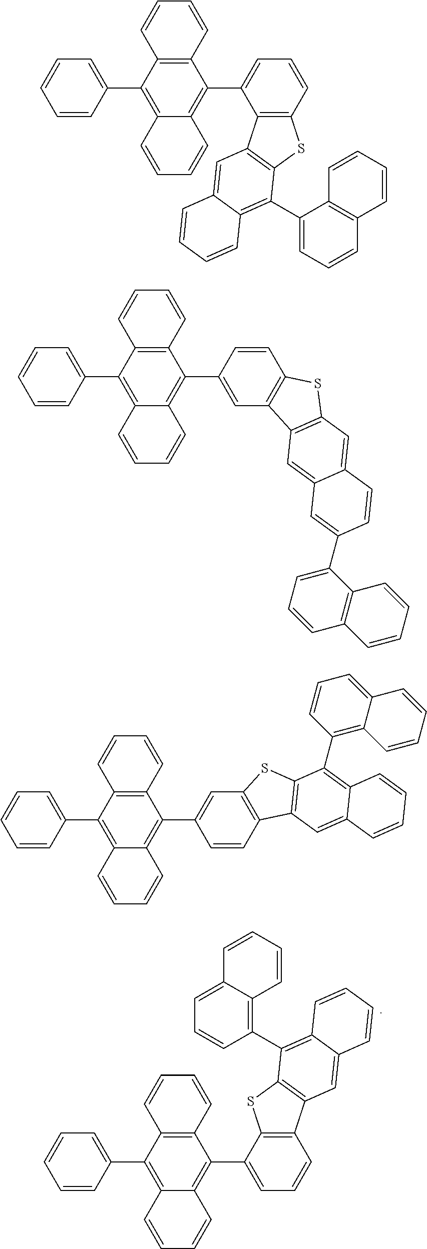

The compound of Chemical Formula 1 can be prepared by the preparation method as shown in the following Reaction Scheme 1:

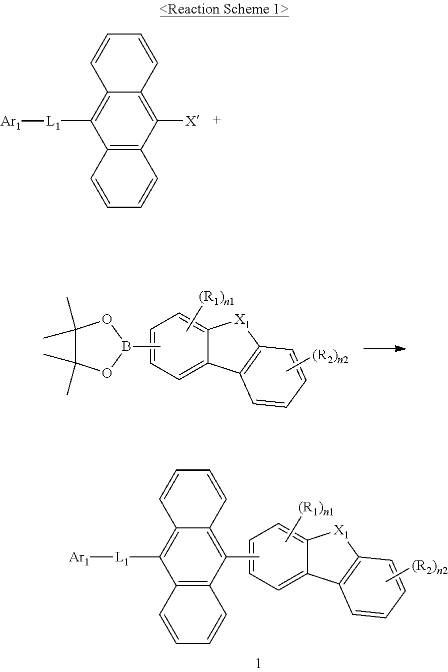

wherein in Reaction Scheme 1, the definition of the remaining substituents except for X′ are the same as defined above, and X′ is halogen, preferably bromo or chloro.

Reaction Scheme 1 is a Suzuki coupling reaction which is preferably carried out in the presence of a palladium catalyst and a base, and a reactive group for the Suzuki coupling reaction can be modified as known in the art. The above preparation method can be further embodied in the Preparation Examples described hereinafter.

Meanwhile, a dopant material used for the light emitting layer is not particularly limited as long as it is used for an organic light emitting device. For example, the dopant material includes an aromatic amine derivative, a strylamine compound, a boron complex, a fluoranthene compound, a metal complex, and the like. Specifically, the aromatic amine derivative is a condensation aromatic cycle derivative having a substituted or unsubstituted arylamino group, examples thereof include pyrene, anthracene, chrysene, and periflanthene having the arylamino group, and the like, the styrylamine compound is a compound where at least one arylvinyl group is substituted in substituted or unsubstituted arylamine, in which one or two or more substituent groups selected from the group consisting of an aryl group, a silyl group, an alkyl group, a cycloalkyl group, and an arylamino group are substituted or unsubstituted. Specific examples thereof include styrylamine, styryldiamine, styryltriamine, styryltetramine, and the like, but are not limited thereto. Further, examples of the metal complex include an iridium complex, a platinum complex, and the like, but are not limited thereto.

Preferably, the hole adjustment layer includes a compound of Chemical Formula 2:

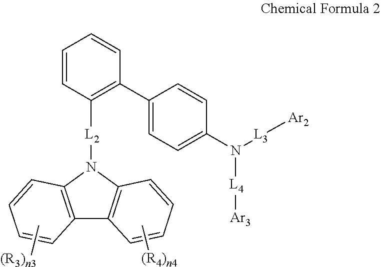

wherein in Chemical Formula 2:

L₂, L₃ and L₄ are each independently a single bond or a substituted or unsubstituted C₆₋₆₀ arylene;

Ar₂ and Ar₃ are each independently a substituted or unsubstituted C₆₋₆₀ aryl, or a substituted or unsubstituted C₂₋₆₀ heteroaryl containing one or more heteroatoms selected from the group consisting of N, O and S;

R₃ and R₄ are each independently hydrogen, deuterium, halogen, cyano, nitro, amino, a substituted or unsubstituted C₁₋₆₀ alkyl, a substituted or unsubstituted C₃₋₆₀ cycloalkyl, a substituted or unsubstituted C₂₋₆₀ alkenyl, a substituted or unsubstituted C₆₋₆₀ aryl, or a substituted or unsubstituted C₂₋₆₀ heteroaryl containing one or more heteroatoms selected from the group consisting of N, O and S, or two adjacent groups are bonded with each other to form a benzene ring;

n3 is an integer from 0 to 4; and

n4 is an integer from 0 to 4.

Preferably, L₂ is a single bond.

Preferably, L₃ and L₄ are each independently a single bond, phenylene, or dimethylfluorenediyl.

Preferably, Ar₂ and Ar₃ are each independently phenyl, biphenylyl, terphenylyl, naphthyl, phenanthrenyl, triphenylenyl, dimethylfluorenyl, or diphenylfluorenyl, and the Ar₂ and Ar₃ are each independently unsubstituted, or substituted with 1 to 5 substituent groups selected from the group consisting of deuterium, C₁₋₁₀ alkyl, tri(C₁₋₁₀ alkyl)silyl, halogen and cyano.

Preferably, R₃ is hydrogen, or n3 is 2, and two R₃s are bonded with each other to form a benzene ring.

Preferably, R₄ is hydrogen.

Representative examples of the compound of Chemical Formula 2 are as follows:

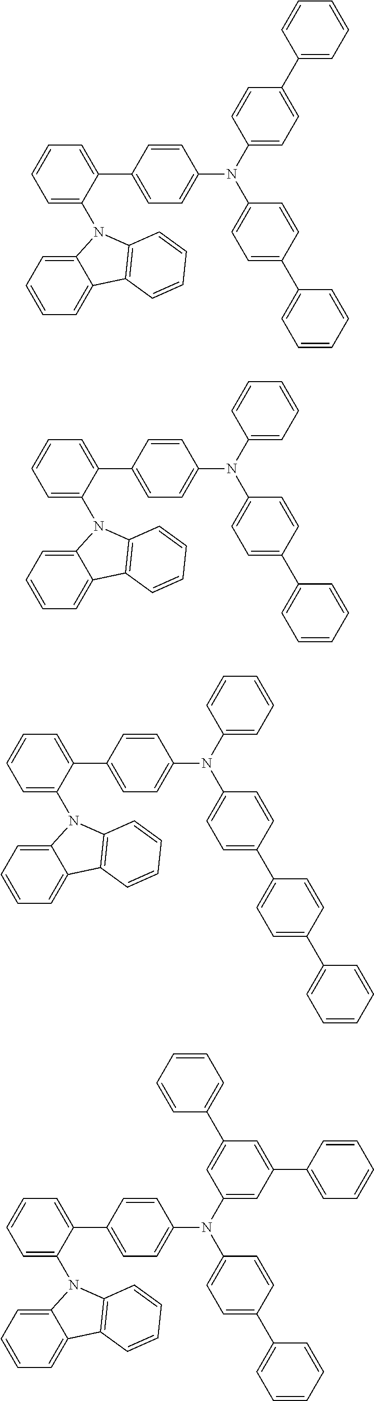

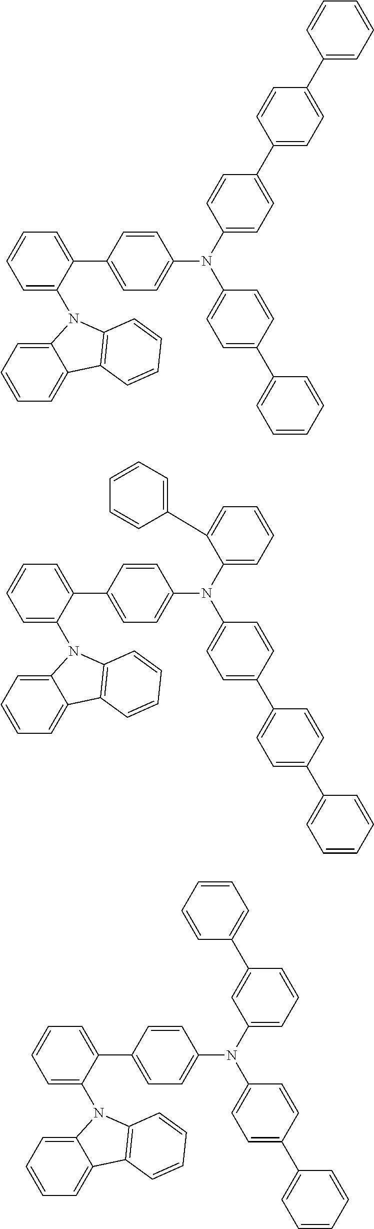 [SMILES: c1ccc(-c2ccc(-c3ccc(N(c4ccc(-c5ccccc5)cc4)c4ccc(-c5ccccc5-n5c6ccccc6c6ccccc65)cc4)cc3)cc2)cc1 ; c1ccc(-c2ccc(-c3ccc(N(c4ccc(-c5ccccc5-n5c6ccccc6c6ccccc65)cc4)c4ccccc4-c4ccccc4)cc3)cc2)cc1 ; c1ccc(-c2ccc(N(c3ccc(-c4ccccc4-n4c5ccccc5c5ccccc54)cc3)c3cccc(-c4ccccc4)c3)cc2)cc1]

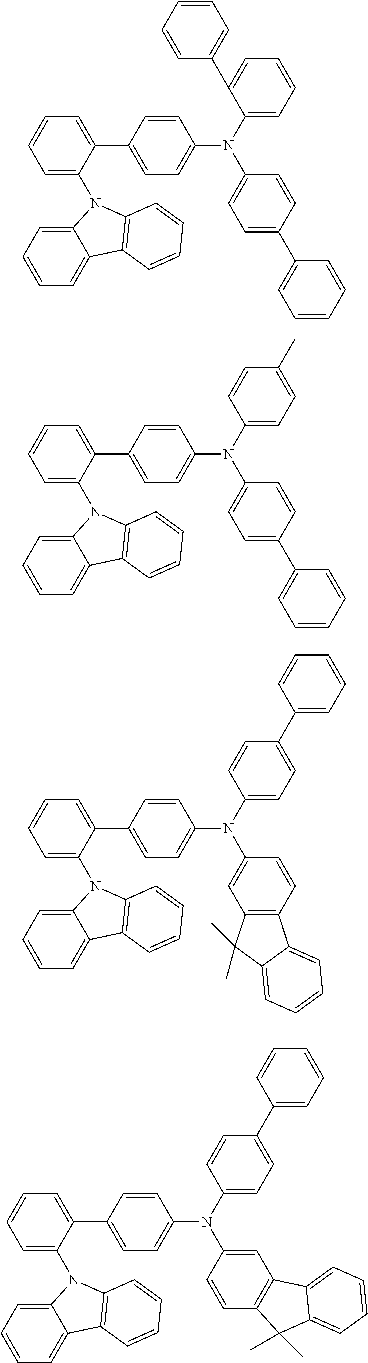

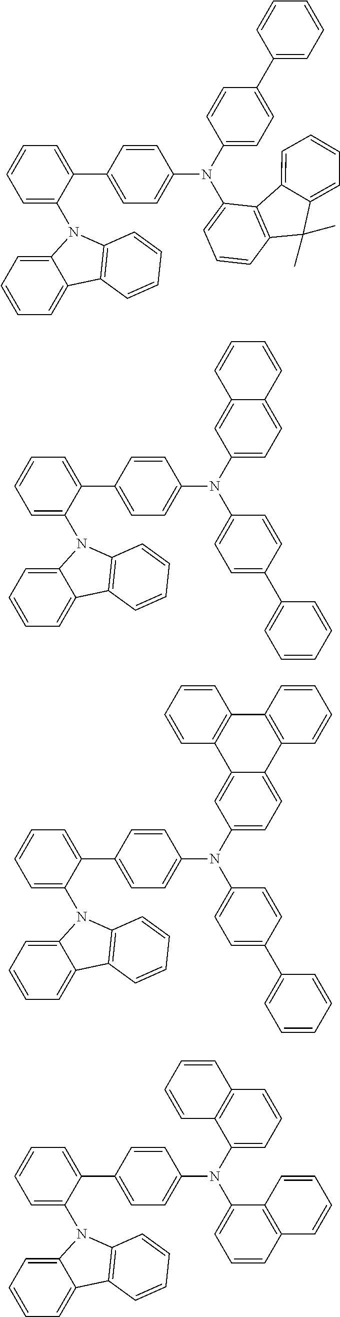

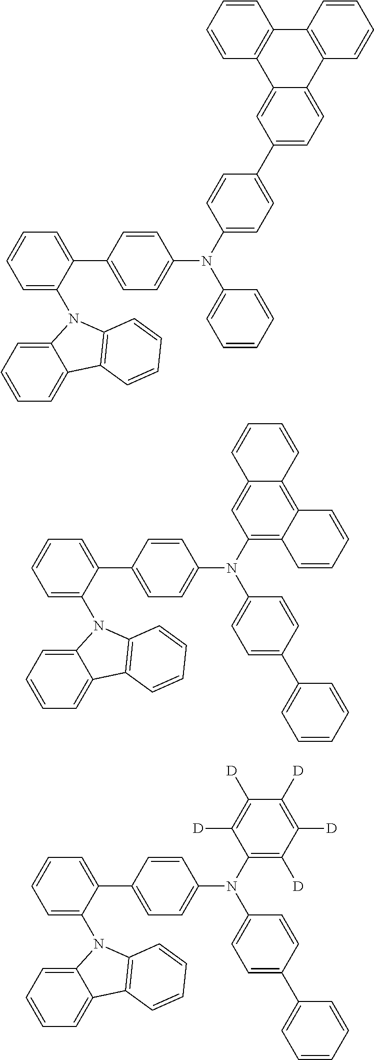

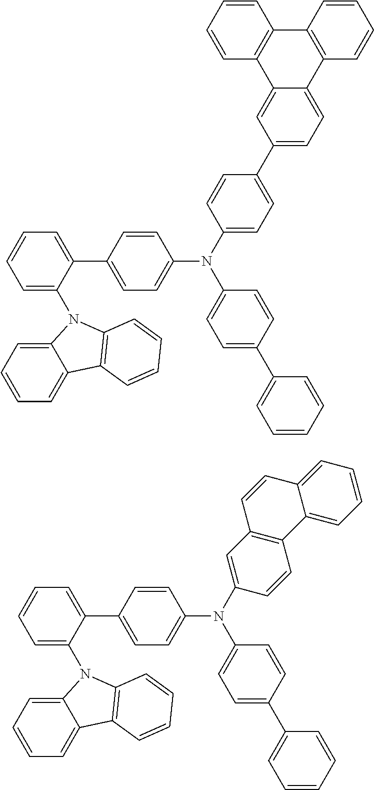

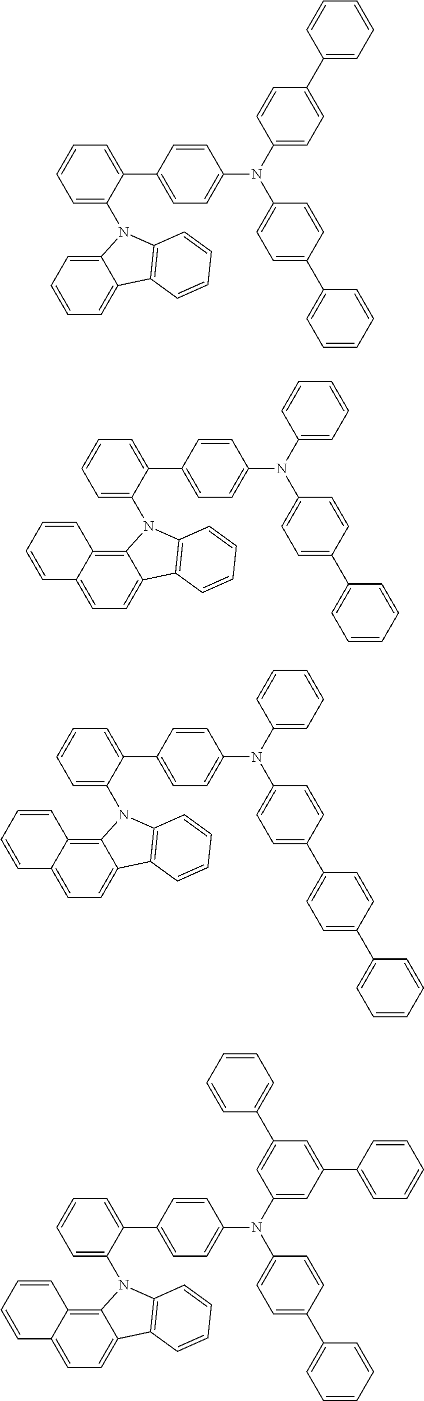

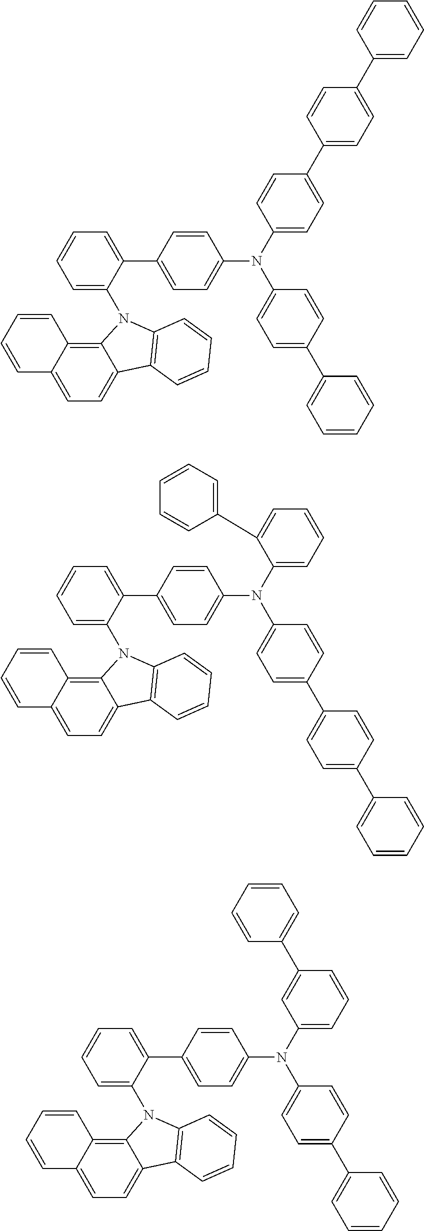 [SMILES: c1ccc(-c2ccc(-c3ccc(N(c4ccc(-c5ccccc5)cc4)c4ccc(-c5ccccc5-n5c6ccccc6c6ccc7ccccc7c65)cc4)cc3)cc2)cc1 ; c1ccc(-c2ccc(-c3ccc(N(c4ccc(-c5ccccc5-n5c6ccccc6c6ccc7ccccc7c65)cc4)c4ccccc4-c4ccccc4)cc3)cc2)cc1 ; c1ccc(-c2ccc(N(c3ccc(-c4ccccc4-n4c5ccccc5c5ccc6ccccc6c54)cc3)c3cccc(-c4ccccc4)c3)cc2)cc1]

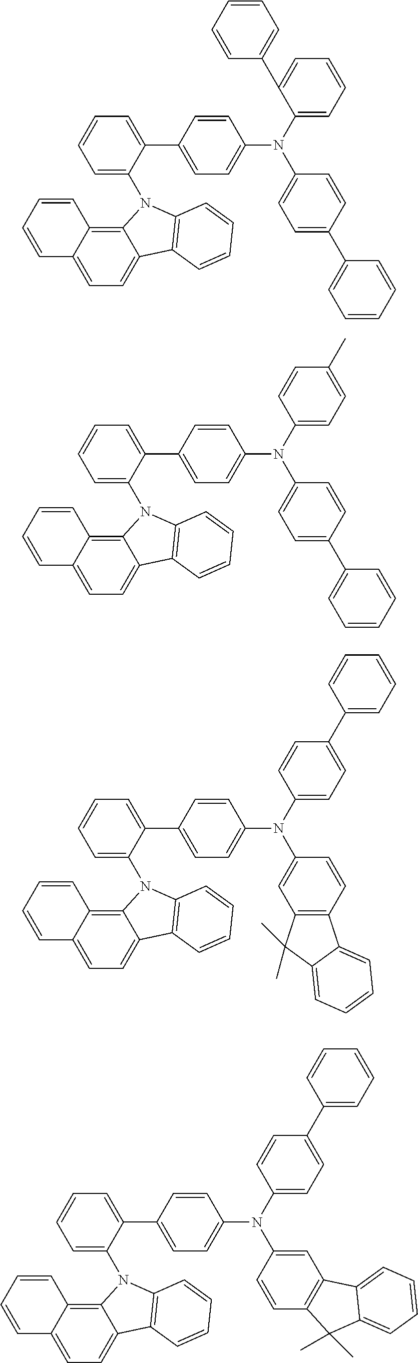

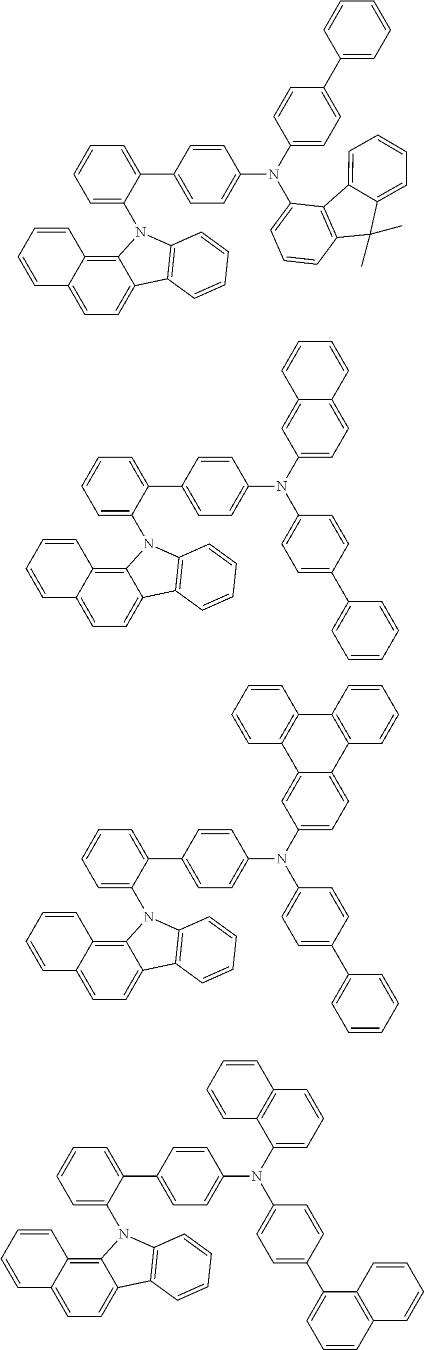

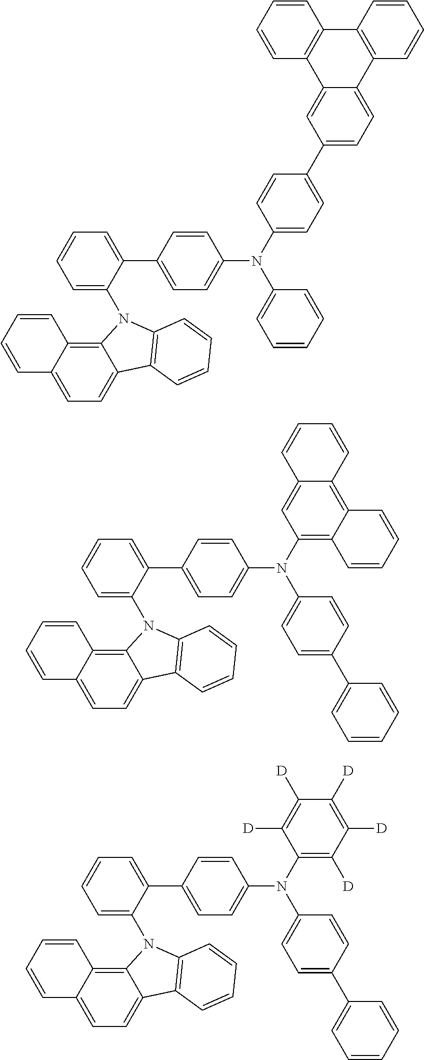

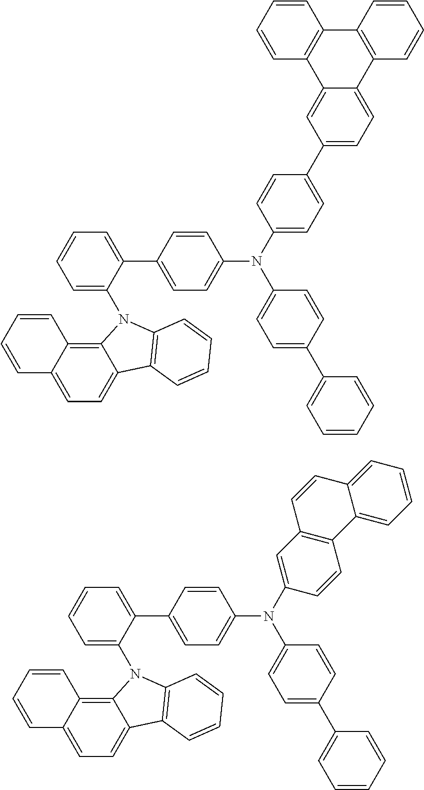

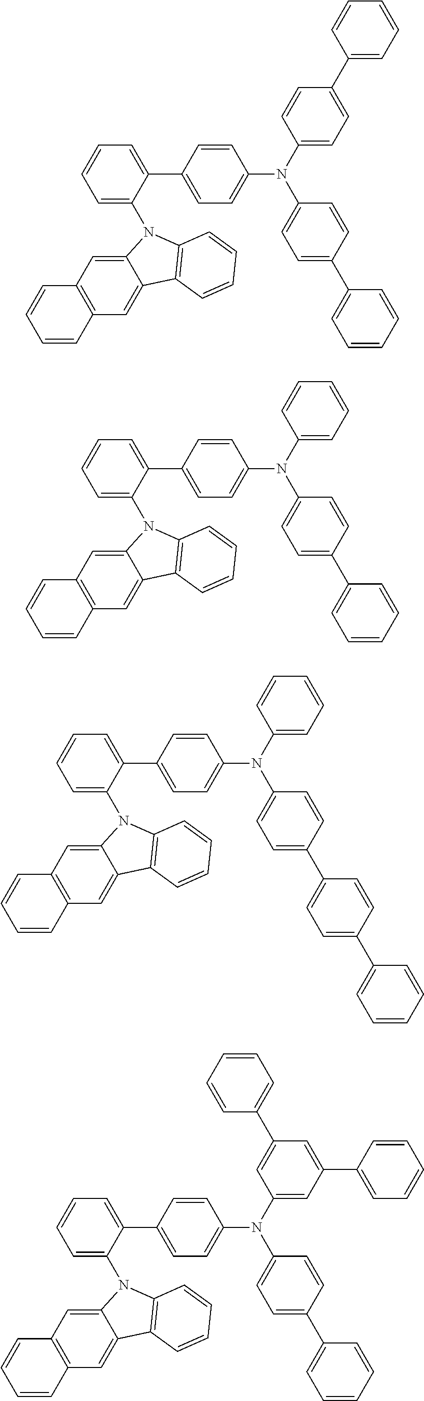

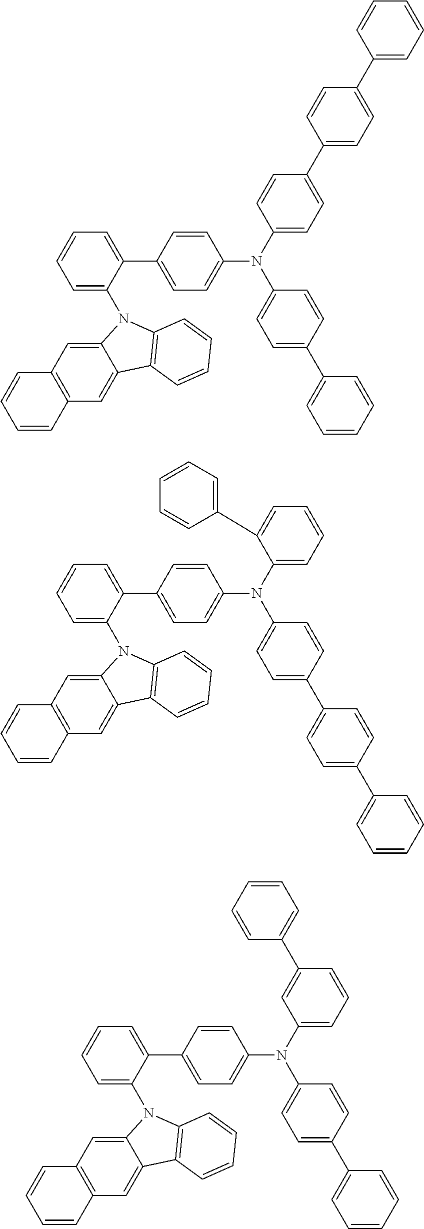 [SMILES: c1ccc(-c2ccc(-c3ccc(N(c4ccc(-c5ccccc5)cc4)c4ccc(-c5ccccc5-n5c6ccccc6c6cc7ccccc7cc65)cc4)cc3)cc2)cc1 ; c1ccc(-c2ccc(-c3ccc(N(c4ccc(-c5ccccc5-n5c6ccccc6c6cc7ccccc7cc65)cc4)c4ccccc4-c4ccccc4)cc3)cc2)cc1 ; c1ccc(-c2ccc(N(c3ccc(-c4ccccc4-n4c5ccccc5c5cc6ccccc6cc54)cc3)c3cccc(-c4ccccc4)c3)cc2)cc1]

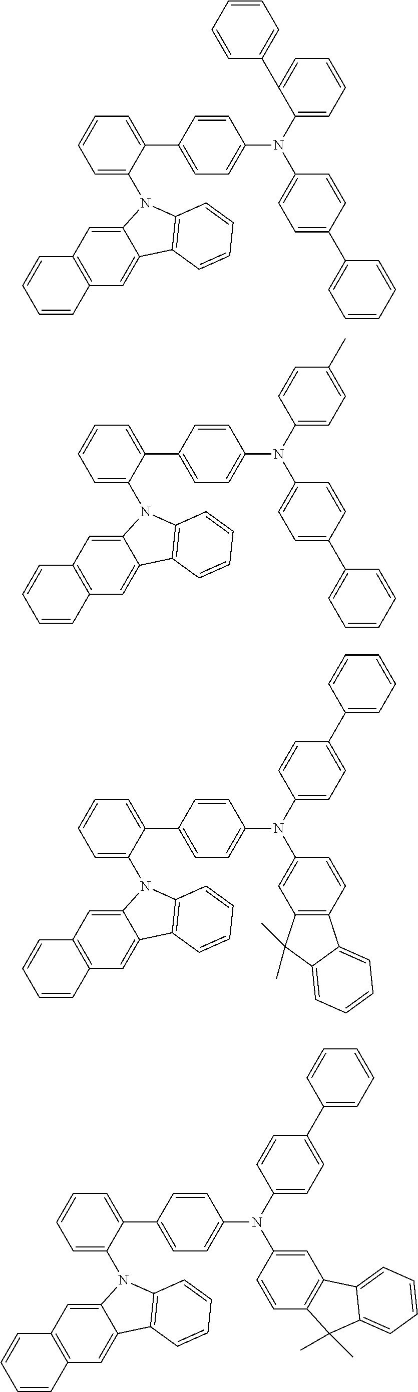

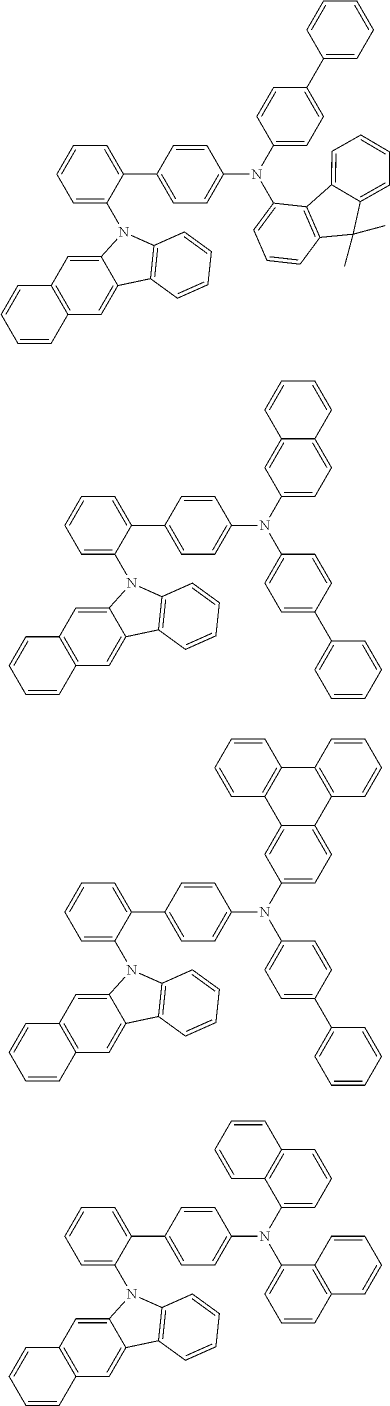

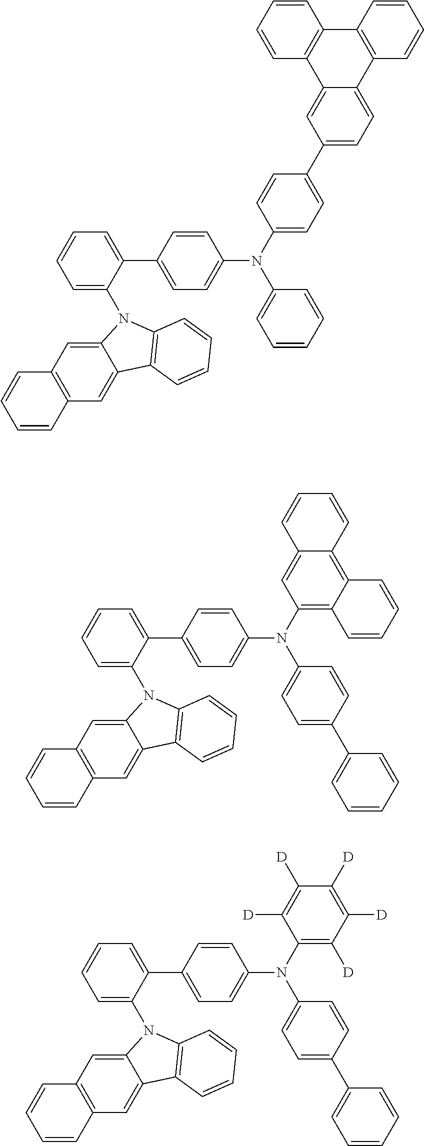

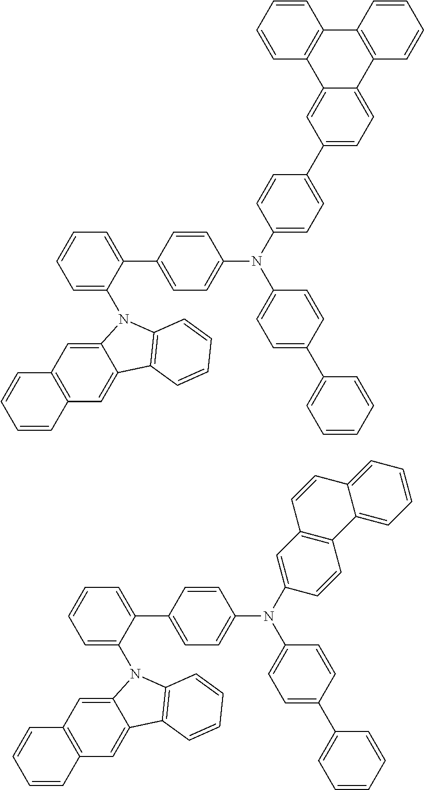

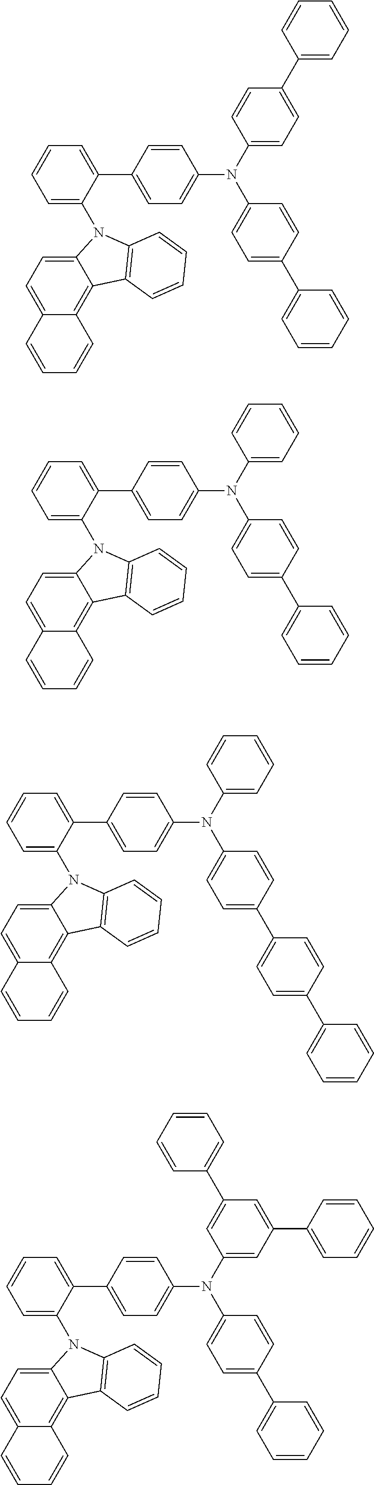 [SMILES: c1ccc(-c2ccc(N(c3ccc(-c4ccccc4)cc3)c3ccc(-c4ccccc4-n4c5ccccc5c5c6ccccc6ccc54)cc3)cc2)cc1 ; c1ccc(-c2ccc(N(c3ccccc3)c3ccc(-c4ccccc4-n4c5ccccc5c5c6ccccc6ccc54)cc3)cc2)cc1 ; c1ccc(-c2ccc(-c3ccc(N(c4ccccc4)c4ccc(-c5ccccc5-n5c6ccccc6c6c7ccccc7ccc65)cc4)cc3)cc2)cc1 ; c1ccc(-c2ccc(N(c3ccc(-c4ccccc4-n4c5ccccc5c5c6ccccc6ccc54)cc3)c3cc(-c4ccccc4)cc(-c4ccccc4)c3)cc2)cc1]

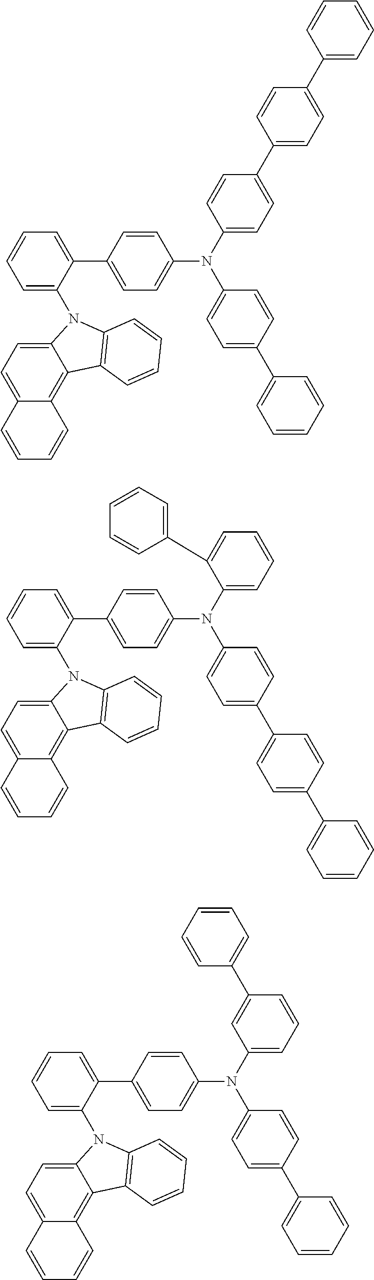 [SMILES: c1ccc(-c2ccc(-c3ccc(N(c4ccc(-c5ccccc5)cc4)c4ccc(-c5ccccc5-n5c6ccccc6c6c7ccccc7ccc65)cc4)cc3)cc2)cc1 ; c1ccc(-c2ccc(-c3ccc(N(c4ccc(-c5ccccc5-n5c6ccccc6c6c7ccccc7ccc65)cc4)c4ccccc4-c4ccccc4)cc3)cc2)cc1 ; c1ccc(-c2ccc(N(c3ccc(-c4ccccc4-n4c5ccccc5c5c6ccccc6ccc54)cc3)c3cccc(-c4ccccc4)c3)cc2)cc1]

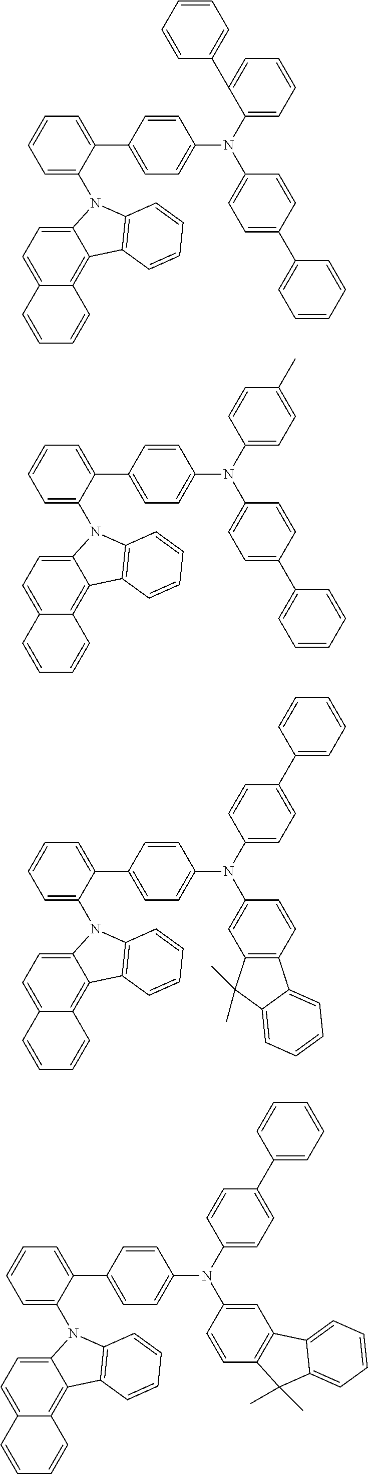

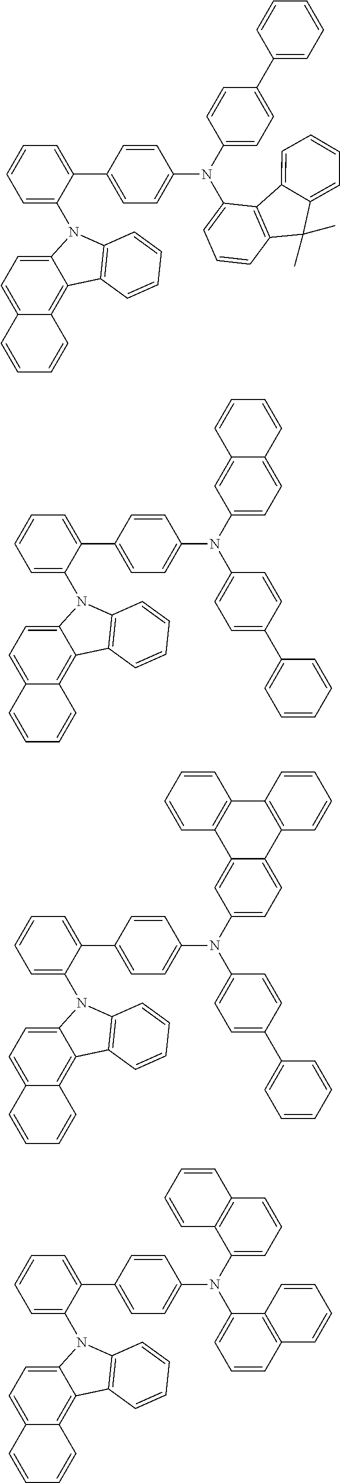 [SMILES: CC1(C)c2ccccc2-c2c(N(c3ccc(-c4ccccc4)cc3)c3ccc(-c4ccccc4-n4c5ccccc5c5c6ccccc6ccc54)cc3)cccc21 ; c1ccc(-c2ccc(N(c3ccc(-c4ccccc4-n4c5ccccc5c5c6ccccc6ccc54)cc3)c3ccc4ccccc4c3)cc2)cc1 ; c1ccc(-c2ccc(N(c3ccc(-c4ccccc4-n4c5ccccc5c5c6ccccc6ccc54)cc3)c3ccc4c5ccccc5c5ccccc5c4c3)cc2)cc1 ; c1ccc(-n2c3ccccc3c3c4ccccc4ccc32)c(-c2ccc(N(c3cccc4ccccc34)c3cccc4ccccc34)cc2)c1]

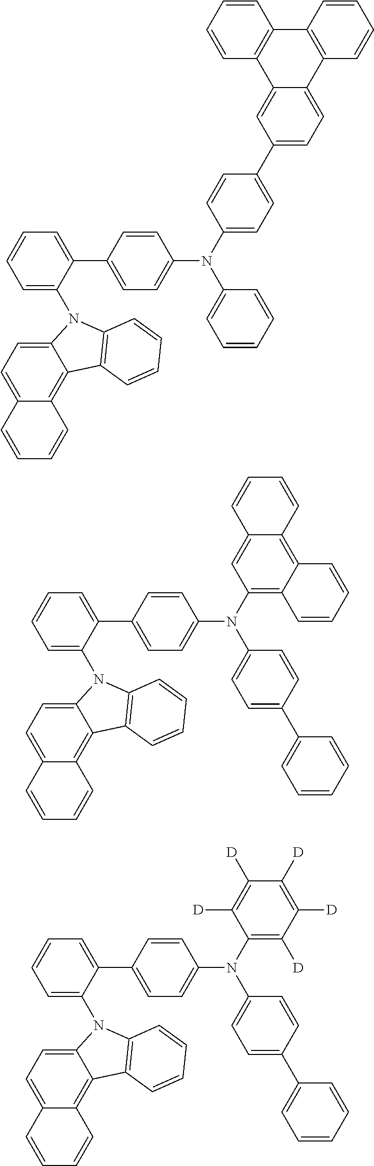 [SMILES: c1ccc(N(c2ccc(-c3ccc4c5ccccc5c5ccccc5c4c3)cc2)c2ccc(-c3ccccc3-n3c4ccccc4c4c5ccccc5ccc43)cc2)cc1 ; c1ccc(-c2ccc(N(c3ccc(-c4ccccc4-n4c5ccccc5c5c6ccccc6ccc54)cc3)c3cc4ccccc4c4ccccc34)cc2)cc1 ; [2H]c1c([2H])c([2H])c(N(c2ccc(-c3ccccc3)cc2)c2ccc(-c3ccccc3-n3c4ccccc4c4c5ccccc5ccc43)cc2)c([2H])c1[2H]]

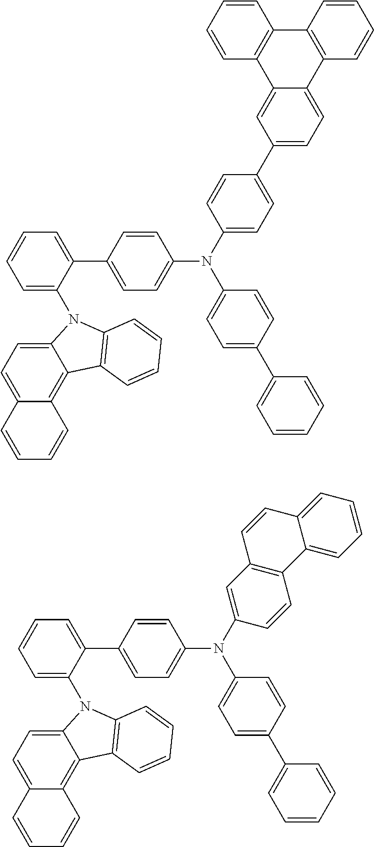 [SMILES: c1ccc(-c2ccc(N(c3ccc(-c4ccc5c6ccccc6c6ccccc6c5c4)cc3)c3ccc(-c4ccccc4-n4c5ccccc5c5c6ccccc6ccc54)cc3)cc2)cc1 ; c1ccc(-c2ccc(N(c3ccc(-c4ccccc4-n4c5ccccc5c5c6ccccc6ccc54)cc3)c3ccc4c(ccc5ccccc54)c3)cc2)cc1]

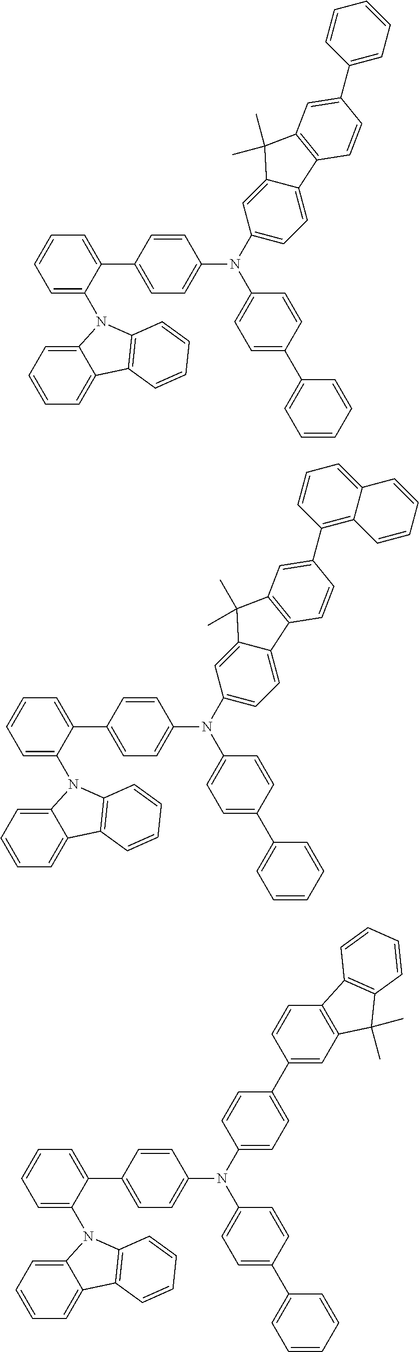

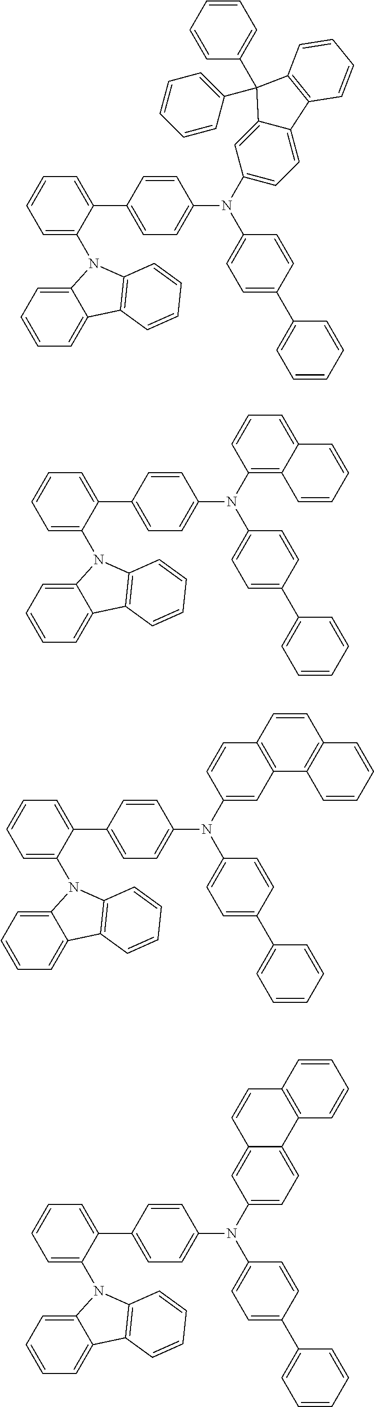

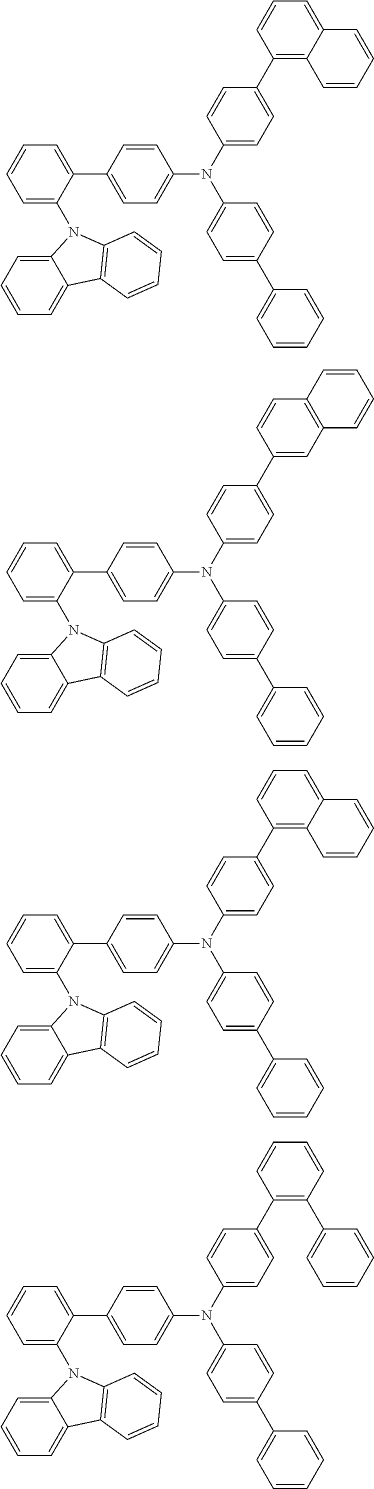

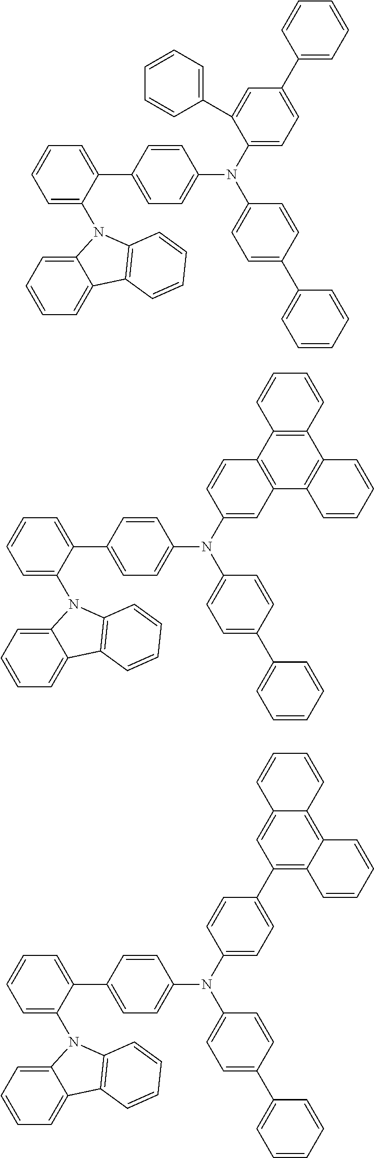

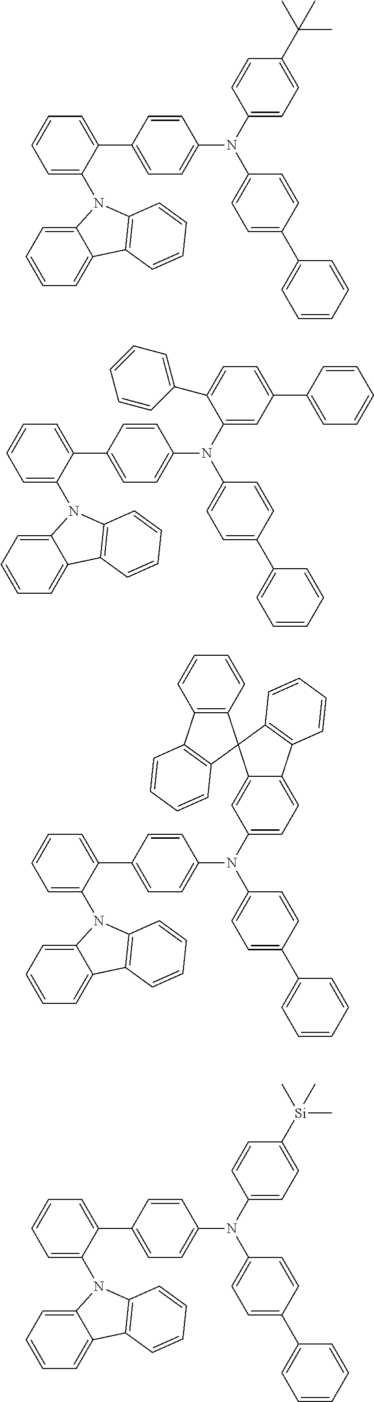 [SMILES: CC(C)(C)c1ccc(N(c2ccc(-c3ccccc3)cc2)c2ccc(-c3ccccc3-n3c4ccccc4c4ccccc43)cc2)cc1 ; c1ccc(-c2ccc(N(c3ccc(-c4ccccc4-n4c5ccccc5c5ccccc54)cc3)c3cc(-c4ccccc4)ccc3-c3ccccc3)cc2)cc1 ; c1ccc(-c2ccc(N(c3ccc(-c4ccccc4-n4c5ccccc5c5ccccc54)cc3)c3ccc4c(c3)C3(c5ccccc5-c5ccccc53)c3ccccc3-4)cc2)cc1 ; C[Si](C)(C)c1ccc(N(c2ccc(-c3ccccc3)cc2)c2ccc(-c3ccccc3-n3c4ccccc4c4ccccc43)cc2)cc1]

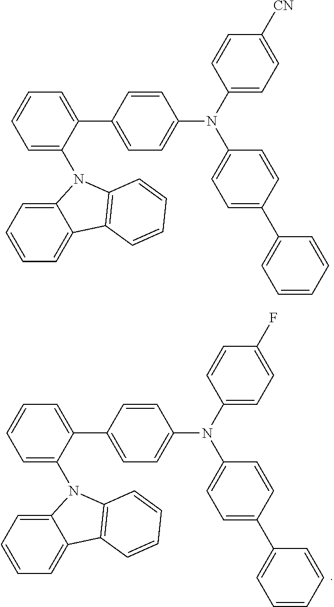

The compound of Chemical Formula 2 can be prepared by the preparation method as shown in the following Reaction Scheme 2:

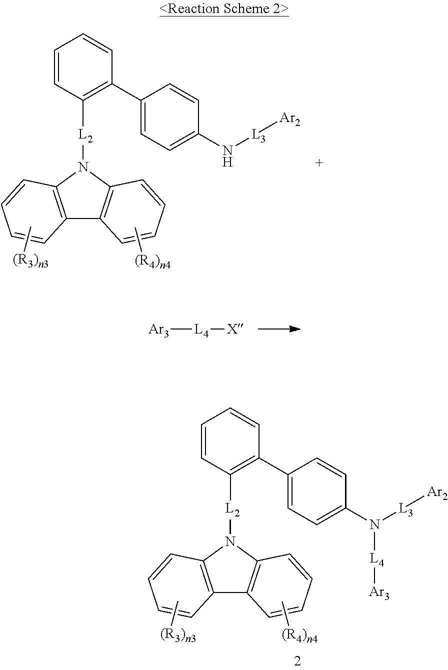

wherein in Reaction Scheme 2, the definition of the remaining substituents except for X″ are the same as defined above, and X″ is halogen, preferably bromo or chloro.

Reaction Scheme 2 is an amine substitution reaction which is preferably carried out in the presence of a palladium catalyst and a base, and a reactive group for the amine substitution reaction can be modified as known in the art. The above preparation method can be further embodied in the Preparation Examples described hereinafter.

Meanwhile, the remaining organic light emitting device excluding the light emitting layer and the hole adjustment layer described above is not particularly limited as long as it can be used for the organic light emitting device, and each configuration is described below.

(Anode and Cathode)

As the anode material, generally, a material having a large work function is preferably used so that holes can be smoothly injected into the organic material layer. Specific examples of the anode material include metals such as vanadium, chrome, copper, zinc, and gold, or an alloy thereof; metal oxides such as zinc oxides, indium oxides, indium tin oxides (ITO), and indium zinc oxides (IZO); a combination of metals and oxides, such as ZnO:Al or SnO₂:Sb; conductive polymers such as poly(3-methylthiophene), poly[3,4-(ethylene-1,2-dioxy)thiophene](PEDOT), polypyrrole, and polyaniline, and the like, but are not limited thereto.

As the cathode material, generally, a material having a small work function is preferably used so that electrons can be easily injected into the organic material layer. Specific examples of the cathode material include metals such as magnesium, calcium, sodium, potassium, titanium, indium, yttrium, lithium, gadolinium, aluminum, silver, tin, and lead, or an alloy thereof; a multilayered structure material such as LiF/Al or LiO₂/Al, and the like, but are not limited thereto.

(Hole Injection Layer)

The organic light emitting device according to the present disclosure can include a hole injection layer which injects holes from the electrode.

The hole injection material is preferably a compound which has an ability of transporting the holes, a hole injection effect in the anode and an excellent hole injection effect to the light emitting layer or the light emitting material, prevents movement of an exciton generated in the light emitting layer to the electron injection layer or the electron injection material, and has an excellent thin film forming ability. It is preferable that a HOMO (highest occupied molecular orbital) of the hole injection material is between the work function of the anode material and a HOMO of a peripheral organic material layer.

Specific examples of the hole injection material include metal porphyrine, oligothiophene, an arylamine-based organic material, a hexanitrilehexaazatriphenylene-based organic material, a quinacridone-based organic material, a perylene-based organic material, anthraquinone, polyaniline, polythiophene-based conductive polymer, and the like, but are not limited thereto.

(Hole Transport Layer)

The organic light emitting device according to the present disclosure can include a hole transport layer which receives holes from the anode or the hole injection layer and transport the holes to the light emitting layer.

The hole transport material is suitably a material having large mobility to the holes, which can receive holes from the anode or the hole injection layer and transfer the holes to the light emitting layer. Specific examples thereof include an arylamine-based organic material, a conductive polymer, a block copolymer in which a conjugate portion and a non-conjugate portion are present together, and the like, but are not limited thereto.

Electron Transport Layer

The organic light emitting device according to the present disclosure can include an electron transport layer which receives electrons from the cathode or the electron injection layer and transport the electrons to the electron adjustment layer.

The electron transport material is a material that can receive the electrons well from the cathode and transport the electrons to the light emitting layer, and a material having large mobility to the electrons is suitable. Specific examples thereof include an 8-hydroxyquinoline Al complex; a complex including Alq₃; an organic radical compound; a hydroxyflavone-metal complex, and the like, but are not limited thereto. The electron transport layer can be used together with a predetermined desired cathode material as used according to the prior art. Particularly, an example of an appropriate cathode material is a general material having the low work function and followed by an aluminum layer or a silver layer. Specific examples thereof include cesium, barium, calcium, ytterbium, and samarium, and each case is followed by the aluminum layer or the silver layer

Electron Injection Layer

The organic light emitting device according to the present disclosure can include an electron injection layer which injects electrons from an electrode.

The electron injection material is preferably a compound which has a capability of transporting electrons, has an effect of injecting electrons from a cathode and an excellent effect of injecting electrons into a light emitting layer or a light emitting material, prevents excitons produced from the light emitting layer from moving to a hole injection layer, and is also excellent in the ability to form a thin film.

Specific examples of the electron injection layer include fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like, but are not limited thereto. Examples of the metal complex compound include 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato)(o-cresolato)gallium, bis(2-methyl-8-quinolinato)(1-naphtholato)aluminum, bis(2-methyl-8-quinolinato)(2-naphtholato)gallium, and the like, but are not limited thereto.

Organic Light Emitting Layer

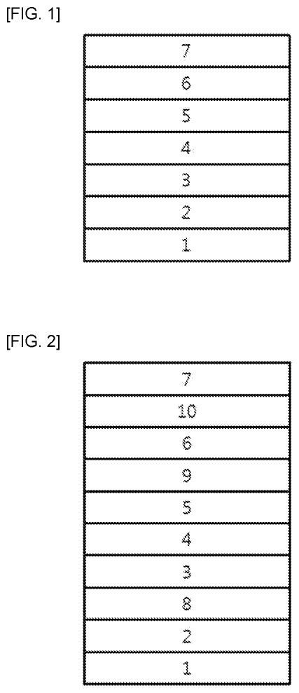

The structure of an organic light emitting device according to an embodiment of the present disclosure is illustrated in FIGS. 1 and 2. FIG. 1 shows an example of an organic light emitting device comprising a substrate 1, an anode 2, a hole transport layer 3, a hole adjustment layer 4, a light emitting layer 5, an electron transport layer 6 and a cathode 7. FIG. 2 shows an example of an organic light emitting device comprising a substrate 1, an anode 2, a hole injection layer 8, a hole transport layer 3, a hole adjustment layer 4, a light emitting layer 5, an electron adjustment layer 9, an electron transport layer 6, an electron injection layer 10 and a cathode 7.

The organic light emitting device according to the present disclosure can be manufactured by sequentially stacking the above-mentioned constitutional elements. In this case, the organic light emitting device can be manufactured by depositing a metal, metal oxides having conductivity, or an alloy thereof on a substrate using a PVD (physical vapor deposition) method such as a sputtering method or an e-beam evaporation method to form an anode, forming organic material layers including the hole injection layer, the hole transport layer, the light emitting layer and the electron transport layer thereon, and then depositing a material that can be used as the cathode thereon. In addition to such a method, the organic light emitting device can be manufactured by sequentially depositing a cathode material, an organic material layer and an anode material on a substrate. Further, the light emitting layer can be formed by subjecting hosts and dopants to a vacuum deposition method and a solution coating method. Herein, the solution coating method means a spin coating, a dip coating, a doctor blading, an inkjet printing, a screen printing, a spray method, a roll coating, or the like, but is not limited thereto.

In addition to such a method, the organic light emitting device can be manufactured by sequentially depositing a cathode material, an organic material layer, and an anode material on a substrate (International Publication WO 2003/012890). However, the manufacturing method is not limited thereto.

On the other hand, the organic light emitting device according to the present invention can be a front side emission type, a back side emission type, or a double side emission type according to the used material.

Hereinafter, preferred examples of the present disclosure will be provided for a better understanding of the invention. However, these examples are presented for illustrative purposes only, and the scope of the present disclosure is not limited thereto.

### PREPARATION EXAMPLES

### Preparation Example 1-1: Preparation of Compound 1-1

### Step 1) Preparation of Compound 1-1-a

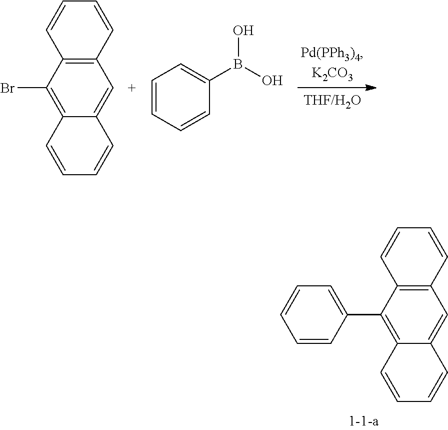

To a three-necked flask was added a solution where 9-bromoanthracene (20.0 g, 77.8 mmol) and phenylboronic acid (10.43 g, 85.6 mmol) were dissolved in THF (300 mL), and K₂CO₃ (43.0 g, 311.1 mmol) was dissolved in water (150 mL). Pd(PPh₃)₄ (3.6 g, 3.1 mmol) was added thereto, and the mixture was stirred at reflux under an argon atmosphere for 8 hours. When the reaction was completed, the reaction solution was cooled to room temperature, then transferred to a separatory funnel, and extracted with water and ethyl acetate. The extract was dried over MgSO₄, filtered and concentrated. Then, the sample was purified by silica gel column chromatography to give Compound 1-1-a (15.6 g, Yield: 79%, MS[M+H]⁺=254).

### Step 2) Preparation of Compound 1-1-b

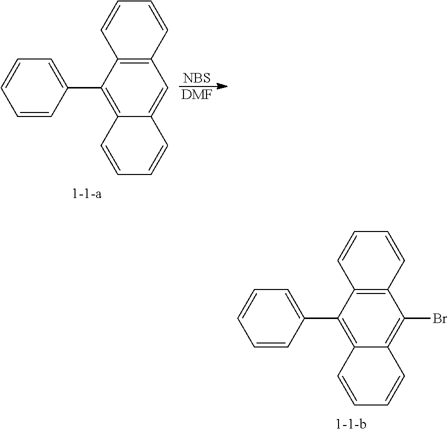

Compound 1-1-a (12.52 g, 49.2 mmol), NBS (9.2 g, 51.7 mmol) and DMF (300 mL) were added to a two-necked flask, and the mixture was stirred at room temperature under argon atmosphere for 8 hours. When the reaction was completed, the reaction solution was transferred to a separatory funnel and the organic layer was extracted with water and ethyl acetate. The extract was dried with MgSO₄, filtered and concentrated. Then, the sample was purified by silica gel column chromatography to give Compound 1-1-b (14.4 g, Yield: 88%, MS: [M+H]⁺=333).

### Step 3) Preparation of Compound 1-1

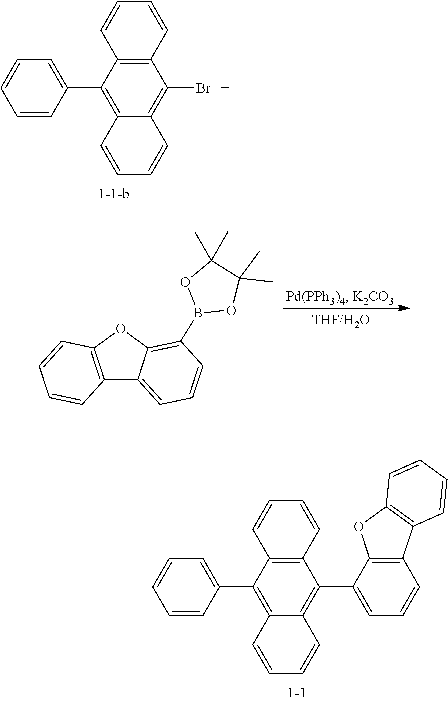 [SMILES: Brc1c2ccccc2c(-c2ccccc2)c2ccccc12 ; CC1(C)OB(c2cccc3c2oc2ccccc23)OC1(C)C ; c1ccc(-c2c3ccccc3c(-c3cccc4c3oc3ccccc34)c3ccccc23)cc1]

To a three-necked flask was added a solution where Compound 1-1-b (15.0 g, 45.01 mmol) and 2-(dibenzo[b,d]furan-2-yl)-4,4,5,5-tetramethyl-1,3,2-dioxaborolane (14.56 g, 49.51 mmol) were dissolved in THF (225 mL) and K₂CO₃ (24.88 g, 180.05 mmol) was dissolved in water (113 mL). Pd(PPh₃)₄ (2.08 g, 1.8 mmol) was added thereto, and the mixture was stirred at reflux under argon atmosphere for 8 hours. When the reaction was completed, the reaction solution was cooled to room temperature, transferred to a separatory funnel and then extracted with water and ethyl acetate. The extract was dried with MgSO₄, filtered and concentrated. The sample was purified by silica gel column chromatography, and then purified by sublimation to obtain Compound 1-1 (6.6 g, Yield: 35%, MS: [M+H]⁺=420).

### Preparation Example 1-2: Preparation of Compound 1-2

### Step 1) Preparation of Compound 1-2-a

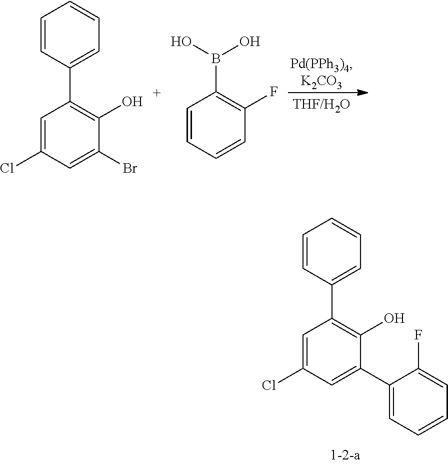 [SMILES: Oc1c(Br)cc(Cl)cc1-c1ccccc1 ; OB(O)c1ccccc1F ; Oc1c(-c2ccccc2)cc(Cl)cc1-c1ccccc1F]

To a three-necked flask was added a solution where 3-bromo-6-chloro-[1,1′-biphenyl]-2-ol (40.0 g, 141.1 mmol) and (2-fluorophenyl)boronic acid (21.71 g, 155.2 mmol) were dissolved in THF (705 mL) and K₂CO₃ (77.99 g, 564.3 mmol) was dissolved in water (1410 mL). Pd(PPh₃)₄ (6.52 g, 5.6 mmol) was added thereto, and the mixture was stirred at reflux under an argon atmosphere for 8 hours. When the reaction was completed, the reaction solution was cooled to room temperature, then transferred to a separatory funnel, and extracted with water and ethyl acetate. The extract was dried over MgSO₄, filtered and concentrated. Then, the sample was purified by silica gel column chromatography to give Compound 1-2-a (33.29 g, Yield: 79%, MS[M+H]⁺=298).

### Step 2) Preparation of Compound 1-2-b

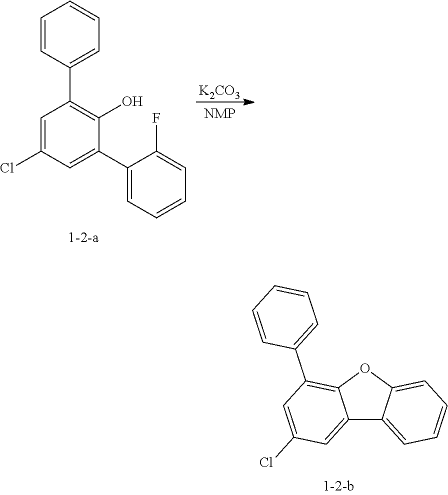

Compound 1-2-a (33.29 g, 111.4 mmol), K₂CO₃ (30.8 g, 222.9 mmol), and NMP (445 mL) were added to a two-necked flask, and the mixture was stirred at 120° C. overnight. When the reaction was completed, the reaction solution was cooled to room temperature and then water (412 mL) was added dropwise to the reaction solution. Then, the reaction solution was transferred to a separatory funnel, and the organic layer was extracted with water and ethyl acetate. The extract was dried over MgSO₄, filtered and concentrated. Then, the sample was purified by silica gel column chromatography to give Compound 1-2-b (25.47 g, Yield: 82%, MS[M+H]⁺=279).

### Step 3) Preparation of Compound 1-2-c

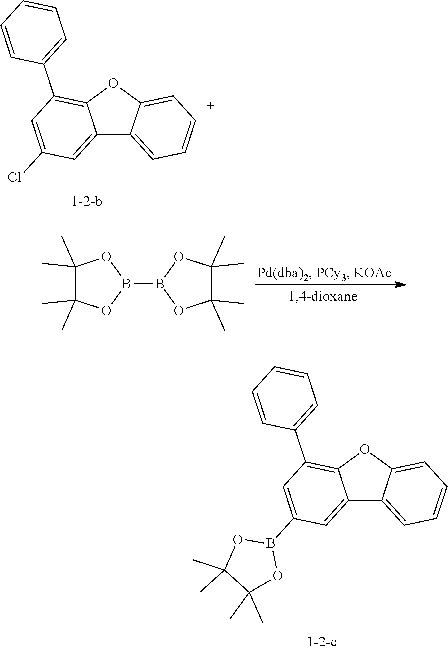

Compound 1-2-b (25.47 g, 91.4 mmol), bis(pinacolato)diboron (27.84 g, 109.7 mmol), Pd(dba)₂ (1.05 g, 1.8 mmol), tricyclohexylphosphine (1.02 g, 3.7 mmol), KOAc (17.94 g, 182.8 mmol), and 1,4-dioxane (380 mL) were added to a three-necked flask, and the mixture was stirred at reflux under an argon atmosphere for 12 hours. When the reaction was completed, the reaction solution was cooled to room temperature, then transferred to a separatory funnel, to which water (280 mL) was added and extracted with ethyl acetate. The extract was dried over MgSO₄, filtered and concentrated. Then, the sample was purified by silica gel column chromatography to give Compound 1-2-c (23 g, Yield: 73%, MS:[M+H]⁺=385).

### Step 4) Preparation of Compound 1-2

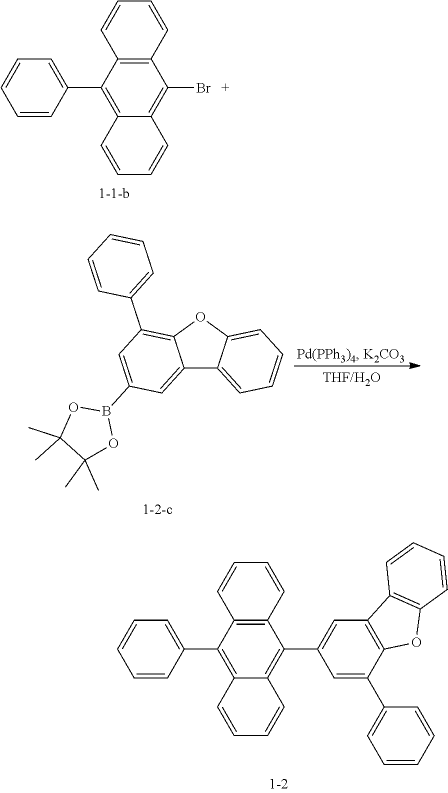 [SMILES: Brc1c2ccccc2c(-c2ccccc2)c2ccccc12 ; CC1(C)OB(c2cc(-c3ccccc3)c3oc4ccccc4c3c2)OC1(C)C ; c1ccc(-c2c3ccccc3c(-c3cc(-c4ccccc4)c4oc5ccccc5c4c3)c3ccccc23)cc1]

Compound 1-2 (20.19 g, Yield: 72%, MS:[M+H]⁺=497) was prepared in the same manner as in the Preparation of Compound 1-1, except that Compound 1-2-c was used instead of 2-(dibenzo[b,d]furan-2-yl)-4,4,5,5-tetramethyl-1,3,2-dioxaborolane in step 3 of Preparation Example 1-1.

### Preparation Example 1-3: Preparation of Compound 1-3

### Step 1) Preparation of Compound 1-3-a

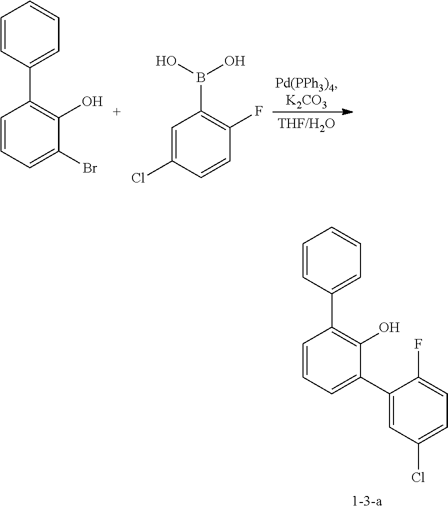 [SMILES: Oc1c(Br)cccc1-c1ccccc1 ; OB(O)c1cc(Cl)ccc1F ; Oc1c(-c2ccccc2)cccc1-c1cc(Cl)ccc1F]

To a three-necked flask was added a solution where 3-bromo-[1,1′-biphenyl]-2-01 (30.0 g, 120.4 mmol) and (5-chloro-2-fluorophenyl)boronic acid (23.1 g, 132.5 mmol) were dissolved in THF (450 mL) and K₂CO₃ (66.6 g, 481.7 mmol) was dissolved in water (225 mL). Pd(PPh₃)₄ (5.6 g, 4.8 mmol) was added thereto, and the mixture was stirred at reflux under an argon atmosphere for 8 hours. When the reaction was completed, the reaction solution was cooled to room temperature, then transferred to a separatory funnel, and extracted with water and ethyl acetate. The extract was dried over MgSO₄, filtered and concentrated. Then, the sample was purified by silica gel column chromatography to give Compound 1-3-a (27.0 g, Yield: 75%, MS[M+H]⁺=298).

### Step 2) Preparation of Compound 1-3-b

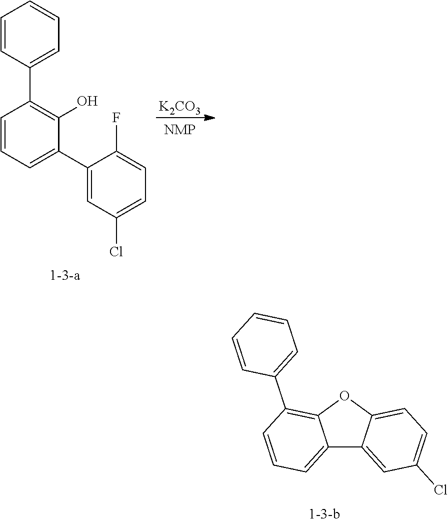

Compound 1-3-a (25.0 g, 83.7 mmol), K₂CO₃ (23.1 g, 167.4 mmol), and NMP (325 mL) were added to a three-necked flask, and the mixture was stirred at 120° C. overnight. When the reaction was completed, the reaction solution was cooled to room temperature, and then water (300 mL) was added dropwise to the reaction solution. Then, the reaction solution was transferred to a separatory funnel, and the organic layer was extracted with water and ethyl acetate. The extract was dried over MgSO₄, filtered and concentrated. Then, the sample was purified by silica gel column chromatography to give Compound 1-3-b (19.8 g, Yield: 85%, MS[M+H]⁺=279).

### Step 3) Preparation of Compound 1-3-c

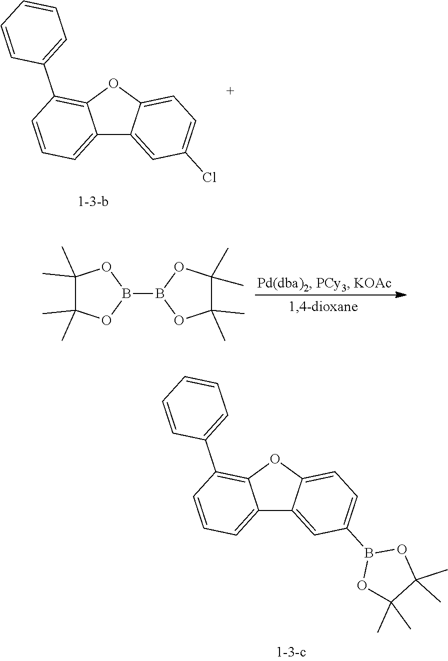

Compound 1-3-b (18.0 g, 64.6 mmol), bis(pinacolato)diborone (19.7 g, 77.5 mmol), Pd(dba)₂ (0.7 g, 1.3 mmol), tricyclohexylphosphine (0.7 g, 2.6 mmol), KOAc (12.7 g, 129.2 mmol), and 1,4-dioxane (270 mL) were added to a three-necked flask, and the mixture was stirred at reflux under an argon atmosphere for 12 hours. When the reaction was completed, the reaction solution was cooled to room temperature, then transferred to a separatory funnel, to which water (200 mL) was added and extracted with ethyl acetate. The extract was dried over MgSO₄, filtered and concentrated. Then, the sample was purified by silica gel column chromatography to give Compound 1-3-c (17.45 g, Yield: 73%, MS:[M+H]⁺=370).

### Step 4) Preparation of Compound 1-3

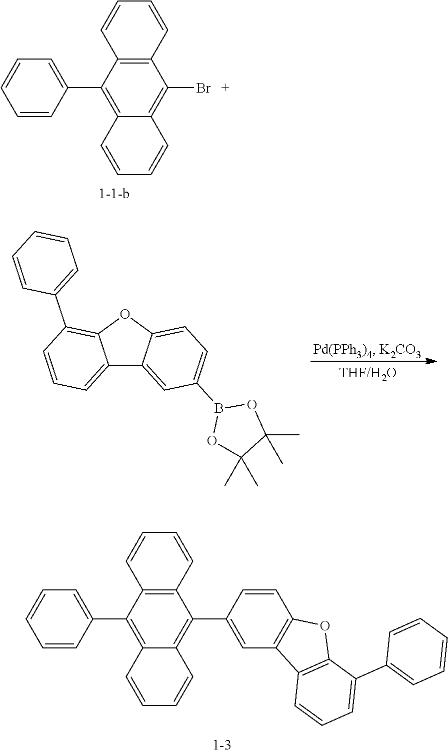 [SMILES: Brc1c2ccccc2c(-c2ccccc2)c2ccccc12 ; CC1(C)OB(c2ccc3oc4c(-c5ccccc5)cccc4c3c2)OC1(C)C ; c1ccc(-c2c3ccccc3c(-c3ccc4oc5c(-c6ccccc6)cccc5c4c3)c3ccccc23)cc1]

Compound 1-3 (8.97 g, Yield: 32%, MS:[M+H]⁺=497) was prepared in the same manner as in the Preparation of Compound 1-1, except that Compound 1-3-c was used instead of 2-(dibenzo[b,d]furan-4-yl)-4,4,5,5-tetramethyl-1,3,2-dioxaborolane in step 3 of Preparation Example 1-1.

### Preparation Example 1-4: Preparation of Compound 1-4

### Step 1) Preparation of Compound 1-4-a

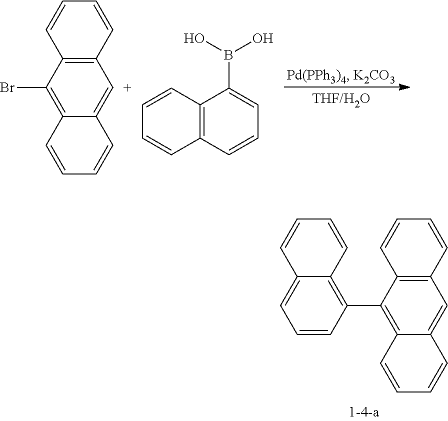

To a three-necked flask was added a solution where 9-bromoanthracene (20.0 g, 77.8 mmol) and naphthalen-1-ylboronic acid (14.7 g, 85.6 mmol) were dissolved in THF (300 mL) and K₂CO₃ (43.0 g, 311.1 mmol) was dissolved in water (150 mL). Pd(PPh₃)₄ (3.6 g, 3.1 mmol) was added thereto, and the mixture was stirred at reflux under an argon atmosphere for 8 hours. When the reaction was completed, the reaction solution was cooled to room temperature, then transferred to a separatory funnel, and extracted with water and ethyl acetate. The extract was dried over MgSO₄, filtered and concentrated. Then, the sample was purified by silica gel column chromatography to give Compound 1-4-a (18.5 g, Yield: 78%, MS[M+H]⁺=304).

### Step 2) Preparation of Compound 1-4-b

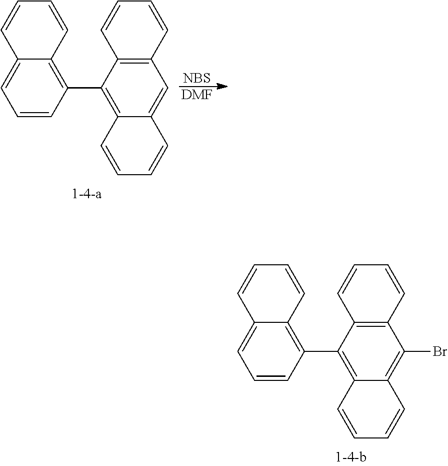

Compound 1-4-a (15.0 g, 49.3 mmol), NBS (9.2 g, 51.7 mmol) and DMF (300 mL) were added to a two-necked flask, and the mixture was stirred at room temperature under an argon atmosphere for 8 hours. When the reaction was completed, the reaction solution was transferred to a separatory funnel, and the organic layer was extracted with water and ethyl acetate. The extract was dried over MgSO₄, filtered and concentrated. Then, the sample was purified by silica gel column chromatography to give Compound 1-4-b (16.6 g, Yield: 88%, MS[M+H]⁺=383).

### Step 3) Preparation of Compound 1-4

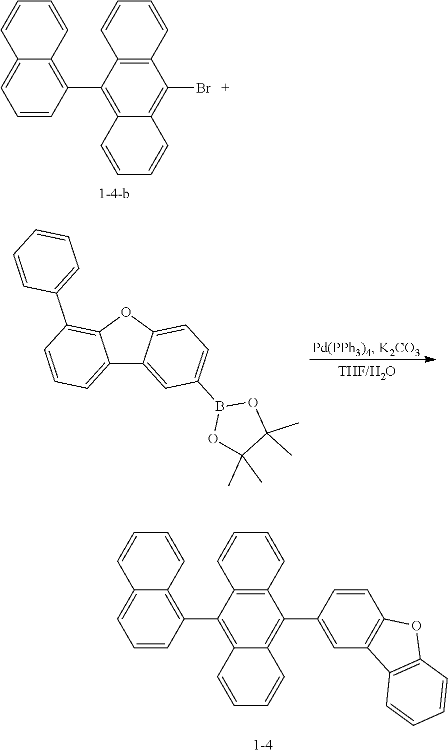

To a three-necked flask was added a solution where Compound 1-4-b (15.0 g, 39.1 mmol) and 2-(dibenzo[b,d]furan-2-yl)-4,4,5,5-tetramethyl-1,3,2-dioxaborolane (12.7 g, 43.0 mmol) were dissolved in THF (225 mL) and K₂CO₃ (21.6 g, 156.5 mmol) was dissolved in water (113 mL). Pd(PPh₃)₄ (1.8 g, 1.6 mmol) was added thereto, and the mixture was stirred at reflux under an argon atmosphere for 8 hours. When the reaction was completed, the reaction solution was cooled to room temperature, then transferred to a separatory funnel, and extracted with water and ethyl acetate. The extract was dried over MgSO₄, filtered and concentrated. Then, the sample was purified by silica gel column chromatography, and then purified by sublimation to give Compound 1-4 (6.4 g, Yield: 35%, MS: [M+H]¹=471).

### Preparation Example 1-5: Preparation of Compound 1-5

### Step 1) Preparation of Compound 1-5-a

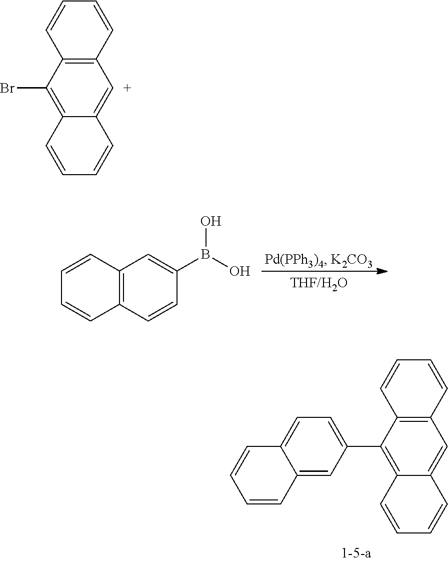

To a three-necked flask was added a solution where 9-bromoanthracene (20.0 g, 77.8 mmol) and naphthalen-2-ylboronic acid (14.7 g, 85.6 mmol) were dissolved in THF (300 mL) and K₂CO₃ (43.0 g, 311.1 mmol) was dissolved in water (150 mL). Pd(PPh₃)₄ (3.6 g, 3.1 mmol) was added thereto, and the mixture was stirred at reflux under an argon atmosphere for 8 hours. When the reaction was completed, the reaction solution was cooled to room temperature, then transferred to a separatory funnel, and extracted with water and ethyl acetate. The extract was dried over MgSO₄, filtered and concentrated. Then, the sample was purified by silica gel column chromatography to give Compound 1-1-a (18.5 g, Yield: 78%, MS: [M+H]+=304).

### Step 2) Preparation of Compound 1-5-b

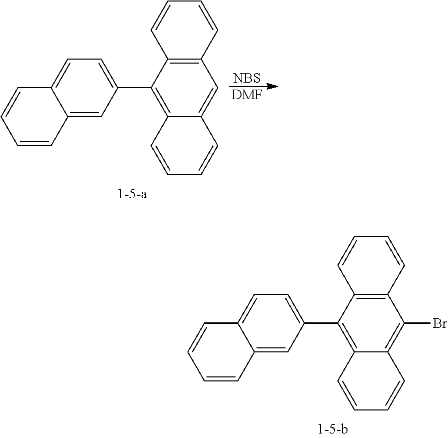

Compound 1-5-a (15.0 g, 49.3 mmol), NBS (9.2 g, 51.7 mmol) and DMF (300 mL) were added to a two-necked flask, and the mixture was stirred at room temperature under an argon atmosphere for 8 hours. When the reaction was completed, the reaction solution was transferred to a separatory funnel, and the organic layer was extracted with water and ethyl acetate. The extract was dried over MgSO₄, filtered and concentrated. Then, the sample was purified by silica gel column chromatography to give Compound 1-5-b (16.6 g, Yield: 88%, MS:[M+H]⁺=383).

### Step 3) Preparation of Compound 1-5

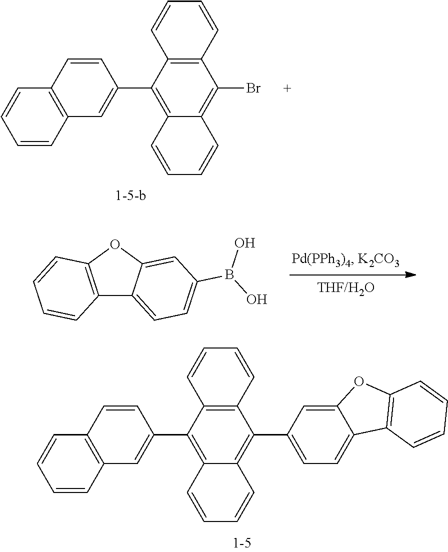

Compound 1-5 (5.8 g, Yield: 32%, MS:[M+H]⁺=470) was prepared in the same manner as in the Preparation of Compound 1-1, except that Compound 1-5-b was used instead of Compound 1-1-b and dibenzo[b,d]furan-3-ylboronic acid was used instead of 2-(dibenzo[b,d]furan-2-yl)-4,4,5,5-tetramethyl-1,3,2-dioxaborolane in step 3 of Preparation Example 1-1.

### Preparation Example 1-6: Preparation of Compound 1-6

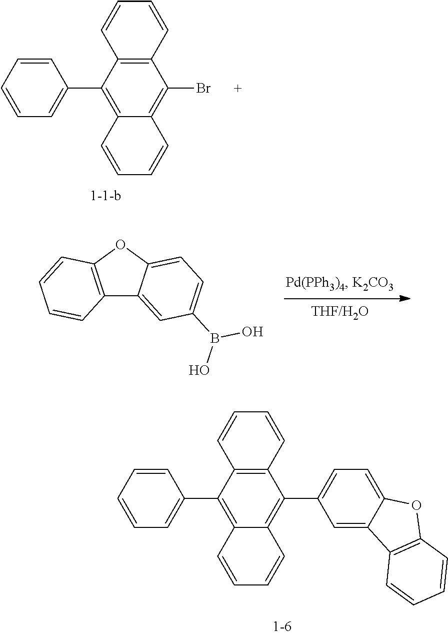 [SMILES: Brc1c2ccccc2c(-c2ccccc2)c2ccccc12 ; OB(O)c1ccc2oc3ccccc3c2c1 ; c1ccc(-c2c3ccccc3c(-c3ccc4oc5ccccc5c4c3)c3ccccc23)cc1]

Compound 1-6 (6.4 g, Yield: 35%, MS:[M+H]⁺=420) was prepared in the same manner as in the Preparation of Compound 1-1, except that dibenzo[b,d]furan-2-ylboronic acid was used instead of 2-(dibenzo[b,d]furan-2-yl)-4,4,5,5-tetramethyl-1,3,2-dioxaborolane of Preparation Example 1-1.

### Preparation Example 1-7: Preparation of Compound 1-7

### Step 1) Preparation of Compound 1-7-a

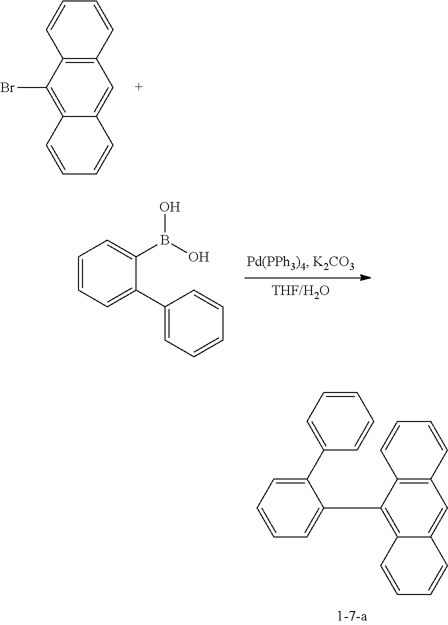

Compound 1-7-a (19.3 g, Yield: 75%, MS:[M+H]+=330) was prepared in the same manner as in the Preparation of Compound 1-1-a, except that [1,1′-biphenyl]-2-ylboronic acid was used instead of phenylboronic acid in step 1 of Preparation Example 1-1.

### Step 2) Preparation of Compound 1-7-b

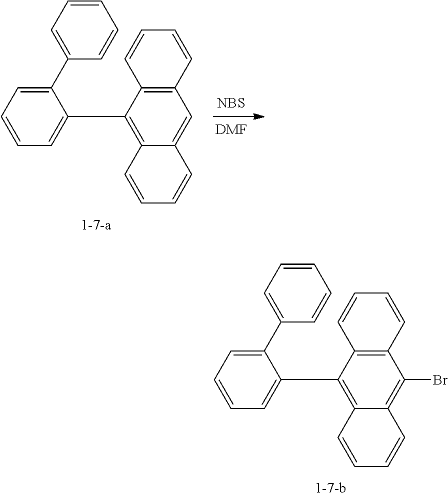

Compound 1-7-b (16.9 g, Yield: 91%, MS:[M+H]⁺=409) was prepared in the same manner as the Preparation of Compound 1-1-b, except that Compound 1-7-a was used instead of Compound 1-1-a in step 2 of Preparation Example 1-1.

### Step 3) Preparation of Compound 1-7

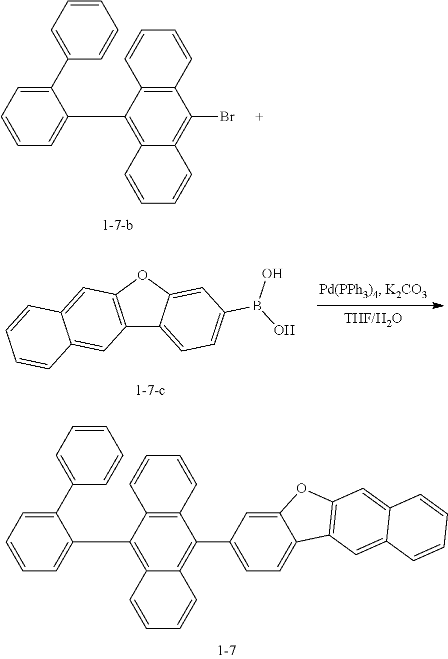 [SMILES: Brc1c2ccccc2c(-c2ccccc2-c2ccccc2)c2ccccc12 ; OB(O)c1ccc2c(c1)oc1cc3ccccc3cc12 ; c1ccc(-c2ccccc2-c2c3ccccc3c(-c3ccc4c(c3)oc3cc5ccccc5cc34)c3ccccc23)cc1]

Compound 1-7 (5.8 g, Yield: 32%, MS:[M+H]⁺=546) was prepared in the same manner as in the Preparation of Compound 1-1, except that Compound 1-7-b was used instead of Compound 1-1-b and Compound 1-7-c was used instead of 2-(dibenzo[b,d]furan-2-yl)-4,4,5,5-tetramethyl-1,3,2-dioxaborolane in step 3 of Preparation Example 1-1.

### Preparation Example 1-8: Preparation of Compound 1-8

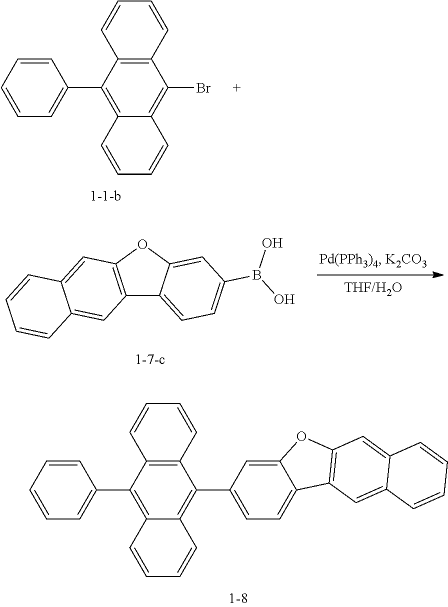 [SMILES: Brc1c2ccccc2c(-c2ccccc2)c2ccccc12 ; OB(O)c1ccc2c(c1)oc1cc3ccccc3cc12 ; c1ccc(-c2c3ccccc3c(-c3ccc4c(c3)oc3cc5ccccc5cc34)c3ccccc23)cc1]

Compound 1-8 (7.3 g, Yield: 64%, MS:[M+H]+=470) was prepared in the same manner as in the Preparation of Compound 1-1, except that Compound 1-7-c was used instead of 2-(dibenzo[b,d]furan-2-yl)-4,4,5,5-tetramethyl-1,3,2-dioxaborolane of Preparation Example 1-1.

### Preparation Example 1-9: Preparation of Compound 1-9

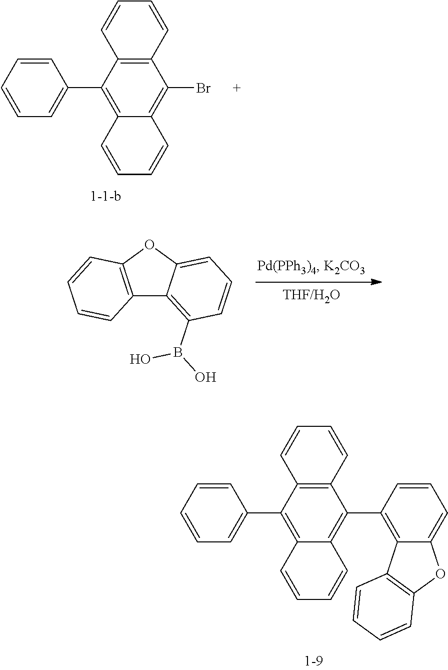 [SMILES: Brc1c2ccccc2c(-c2ccccc2)c2ccccc12 ; OB(O)c1cccc2oc3ccccc3c12 ; c1ccc(-c2c3ccccc3c(-c3cccc4oc5ccccc5c34)c3ccccc23)cc1]

Compound 1-9 (8.4 g, Yield: 52%, MS:[M+H]+=420) was prepared in the same manner as in the Preparation of Compound 1-1, except that dibenzo[b,d]furan-1-ylboronic acid was used instead of 2-(dibenzo[b,d]furan-2-yl)-4,4,5,5-tetramethyl-1,3,2-dioxaborolane of Preparation Example 1-1.

### Preparation Example 2-1: Preparation of Compound 2-1

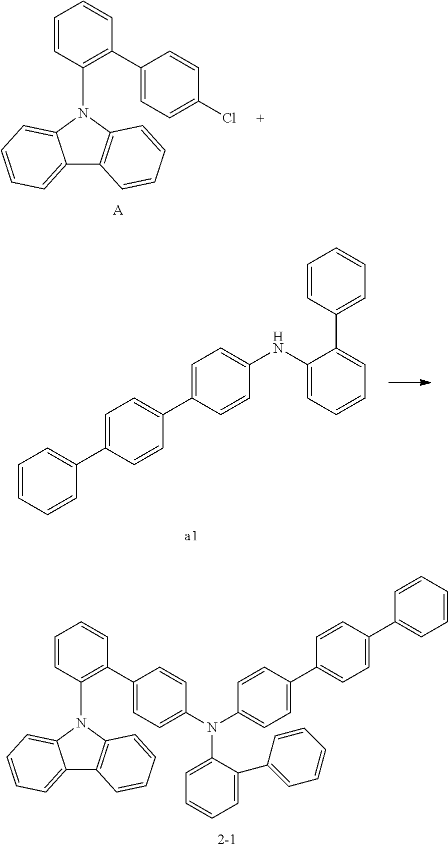

Compound A (10 g, 28.3 mmol) and Compound a1 (11.48 g, 28.9 mmol) were completely dissolved in xylene (200 mL) in a 500 mL round bottom flask under nitrogen atmosphere, to which NaOtBu (3.8 g, 39.6 mmol) was added and bis(tri-tert-butylphosphine)palladium (0) (0.72 g, 1.4 mmol) was added, and then the mixture was heated and stirred for 3 hours. The temperature was lowered to room temperature, and the reaction mixture was filtered to remove the base, and then xylene was concentrated under reduced pressure and recrystallized with ethyl acetate (240 mL) to prepare Compound 2-1 (14.9 g, Yield: 74%).

MS:[M+H]⁺=715

### Preparation Example 2-2: Preparation of Compound 2-2

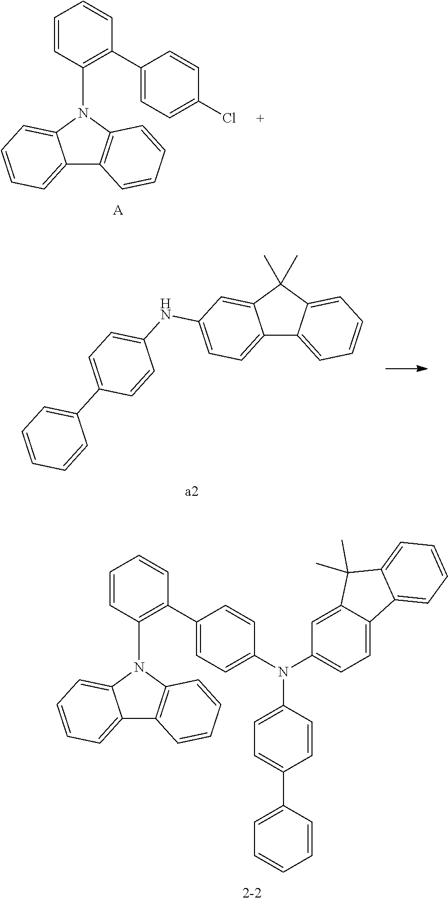

Compound A (10 g, 28.3 mmol) and Compound a2 (10.4 g, 28.9 mmol) were completely dissolved in xylene (200 mL) in a 500 mL round bottom flask under nitrogen atmosphere, to which NaOtBu (3.8 g, 39.6 mmol) was added and bis(tri-tert-butylphosphine)palladium (0) (0.72 g, 1.4 mmol) was added, and then the mixture was heated and stirred for 3 hours. The temperature was lowered to room temperature, and the reaction mixture was filtered to remove the base, and then xylene was concentrated under reduced pressure and recrystallized with ethyl acetate (240 mL) to prepare Compound 2-2 (14.6 g, Yield: 76%).

MS:[M+H]⁺=679

### Preparation Example 2-3: Preparation of Compound 2-3

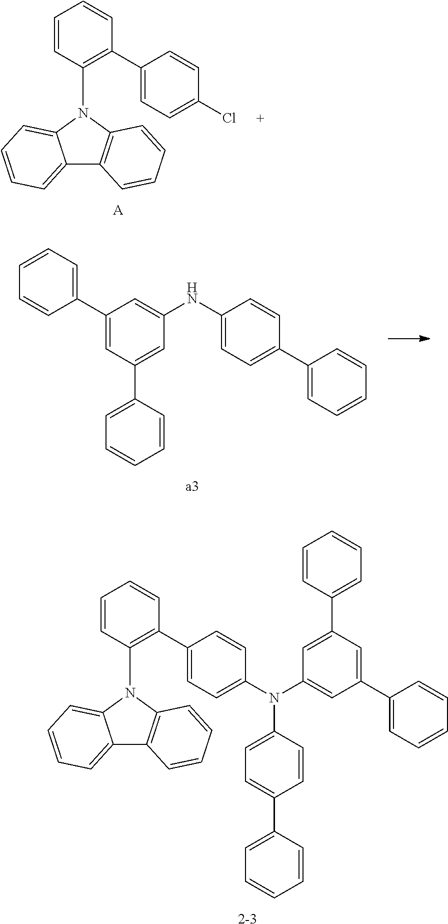

Compound A (10 g, 28.3 mmol) and Compound a3 (11.5 g, 28.9 mmol) were completely dissolved in xylene (200 mL) in a 500 mL round bottom flask under nitrogen atmosphere, to which NaOtBu (3.8 g, 39.6 mmol) was added and bis(tri-tert-butylphosphine)palladium (0) (0.72 g, 1.4 mmol) was added, and then the mixture was heated and stirred for 3 hours. The temperature was lowered to room temperature, and the reaction mixture was filtered to remove the base, and then xylene was concentrated under reduced pressure and recrystallized with ethyl acetate (240 mL) to prepare Compound 2-3 (14.1 g, Yield: 70%).

MS:[M+H]⁺=715

### Preparation Example 2-4: Preparation of Compound 2-4

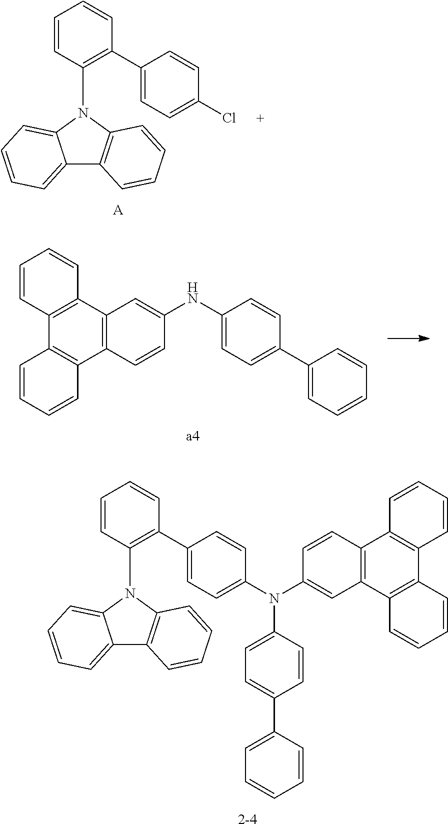

Compound A (10 g, 28.3 mmol) and Compound a4 (11.4 g, 28.9 mmol) were completely dissolved in xylene (200 mL) in a 500 mL round bottom flask under nitrogen atmosphere, to which NaOtBu (3.8 g, 39.6 mmol) was added and bis(tri-tert-butylphosphine)palladium (0) (0.72 g, 1.4 mmol) was added, and then the mixture was heated and stirred for 3 hours. The temperature was lowered to room temperature, and the reaction mixture was filtered to remove the base, and then xylene was concentrated under reduced pressure and recrystallized with ethyl acetate (240 mL) to prepare Compound 2-4 (15.5 g, Yield: 77%).

MS:[M+H]⁺=713

### Preparation Example 2-5: Preparation of Compound 2-5

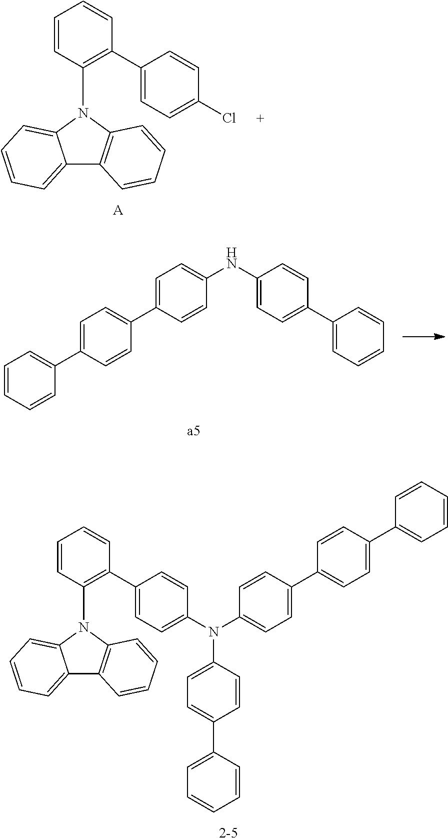

Compound A (10 g, 28.3 mmol), and Compound a5 (11.5 g, 28.9 mmol) were completely dissolved in xylene (200 mL) in a 500 mL round bottom flask under nitrogen atmosphere, to which NaOtBu (3.8 g, 39.6 mmol) was added and bis(tri-tert-butylphosphine)palladium (0) (0.72 g, 1.4 mmol) was added, and then the mixture was heated and stirred for 3 hours. The temperature was lowered to room temperature, and the reaction mixture was filtered to remove the base, and then xylene was concentrated under reduced pressure and recrystallized with ethyl acetate (240 mL) to prepare Compound 2-5 (14.9 g, Yield: 74%).

MS:[M+H]⁺=715

### Preparation Example 2-6: Preparation of Compound 2-6

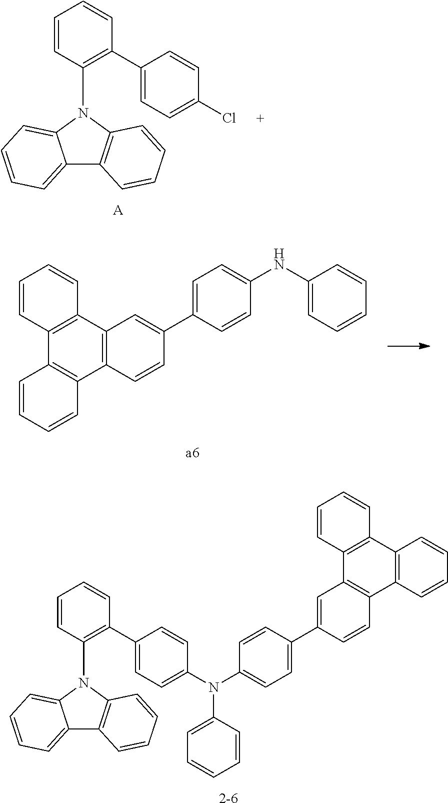

Compound A (10 g, 28.3 mmol), and Compound a6 (11.4 g, 28.9 mmol) were completely dissolved in xylene (200 mL) in a 500 mL round bottom flask under nitrogen atmosphere, to which NaOtBu (3.8 g, 39.6 mmol) was added and bis(tri-tert-butylphosphine)palladium (0) (0.72 g, 1.4 mmol) was added, and then the mixture was heated and stirred for 3 hours. The temperature was lowered to room temperature, and the reaction mixture was filtered to remove the base, and then xylene was concentrated under reduced pressure and recrystallized with ethyl acetate (240 mL) to prepare Compound 2-6 (15.9 g, Yield: 79%).

MS:[M+H]⁺=713

### Preparation Example 2-7: Preparation of Compound 2-7

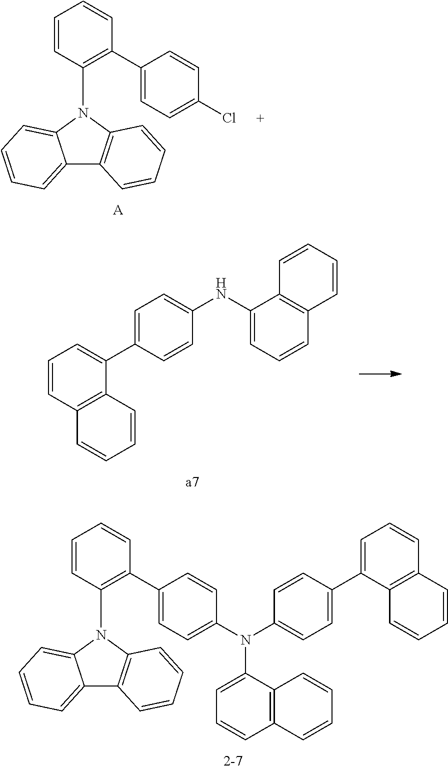

Compound A (10 g, 28.3 mmol), and Compound a7 (9.98 g, 28.9 mmol) were completely dissolved in xylene (200 mL) in a 500 mL round bottom flask under nitrogen atmosphere, to which NaOtBu (3.8 g, 39.6 mmol) was added and bis(tri-tert-butylphosphine)palladium (0) (0.72 g, 1.4 mmol) was added, and then the mixture was heated and stirred for 3 hours. The temperature was lowered to room temperature, and the reaction mixture was filtered to remove the base, and then xylene was concentrated under reduced pressure and recrystallized with ethyl acetate (240 mL) to prepare Compound 2-7 (12.9 g, Yield: 69%).

MS:[M+H]⁺=713

### EXAMPLES

### Example 1

A glass substrate on which a thin film of ITO (indium tin oxide) was coated in a thickness of 1,000 Å was put into distilled water containing a detergent dissolved therein and washed by the ultrasonic wave. In this case, the detergent used was a product commercially available from Fisher Co. and the distilled water was one which had been twice filtered by using a filter commercially available from Millipore Co. The ITO was washed for 30 minutes, and ultrasonic washing was then repeated twice for 10 minutes by using distilled water. After the washing with distilled water was completed, the substrate was ultrasonically washed with isopropyl alcohol, acetone, and methanol solvent, and dried, after which it was transported to a plasma cleaner. Then, the substrate was cleaned with oxygen plasma for 5 minutes, and then transferred to a vacuum evaporator.

On the ITO transparent electrode thus prepared, a compound HAT below was thermally vacuum-deposited in a thickness of 500 Å to form a hole injection layer. A compound NPB below was vacuum-deposited in a thickness of 300 Å on the hole injection layer to form a hole transport layer. The previously prepared compound 2-1 was vacuum-deposited in a thickness of 100 Å on the hole transport layer to form a hole adjustment layer. The previously prepared compound 1-1 and a compound BD below were vacuum-deposited at a weight ratio of 20:1 in a thickness of 300 Å to form a light emitting layer. A compound ETL below and a compound LiQ below were vacuum-deposited at a weight ratio of 1:1 to a thickness of 300 Å on the electron adjustment layer to form an electron injection and transport layer. Lithium fluoride (LiF) and aluminum were sequentially deposited to have a thickness of 12 Å and 2,000 Å, respectively, on the electron injection and transport layer to form a cathode.

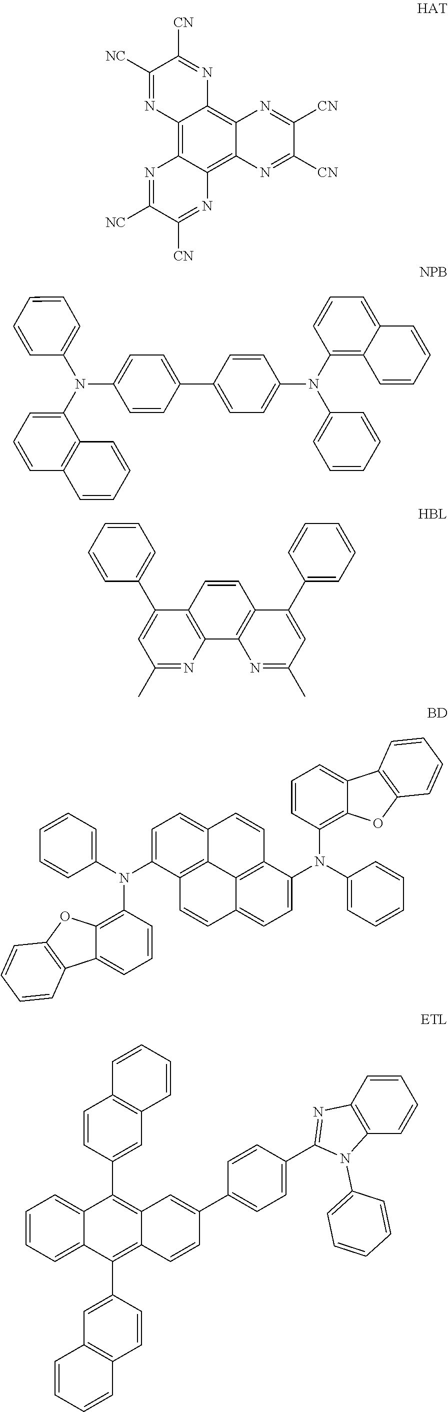

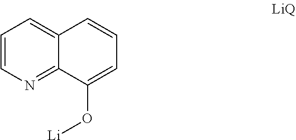

In the above process, the vapor deposition rate of the organic material was maintained at 0.4 to 0.7 Å/sec, the vapor deposition rate of lithium fluoride of the cathode was maintained at 0.3 Å/sec, the vapor deposition rate of aluminum was maintained at 2 Å/sec, and the degree of vacuum during vapor deposition was maintained at 2×10⁻⁷ to 5×10⁻⁶ torr to manufacture an organic light emitting device.

### Examples 2 to 20

The organic light emitting device was manufactured in the same manner as in Example 1, except that the compounds shown in Table 1 below were used instead of Compound 1-1 and Compound 2-1.

### Comparative Examples 1 to 16

The organic light emitting device was manufactured in the same manner as in Example 1, except that the compounds shown in Table 1 below were used instead of Compound 1-1 and Compound 2-1. In Table 1 below, the compounds of BH-1 to BH-9, and EB-1 to EB-7 are as follows, respectively.

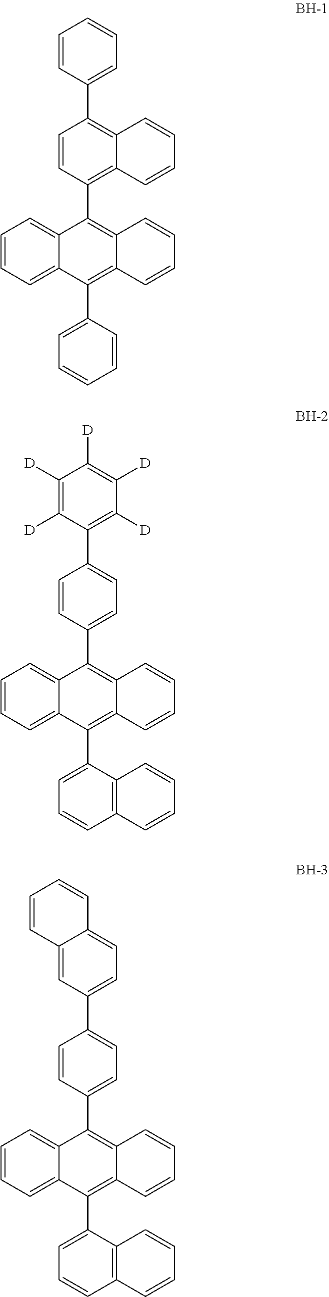

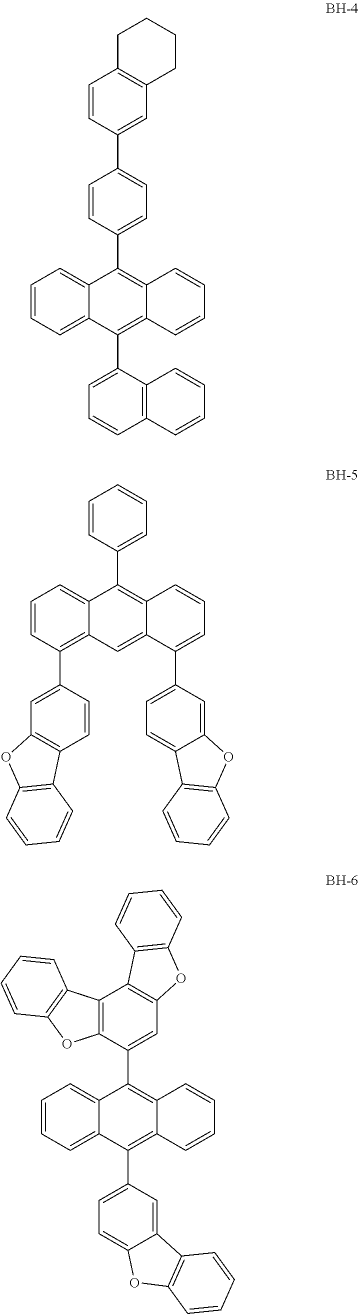

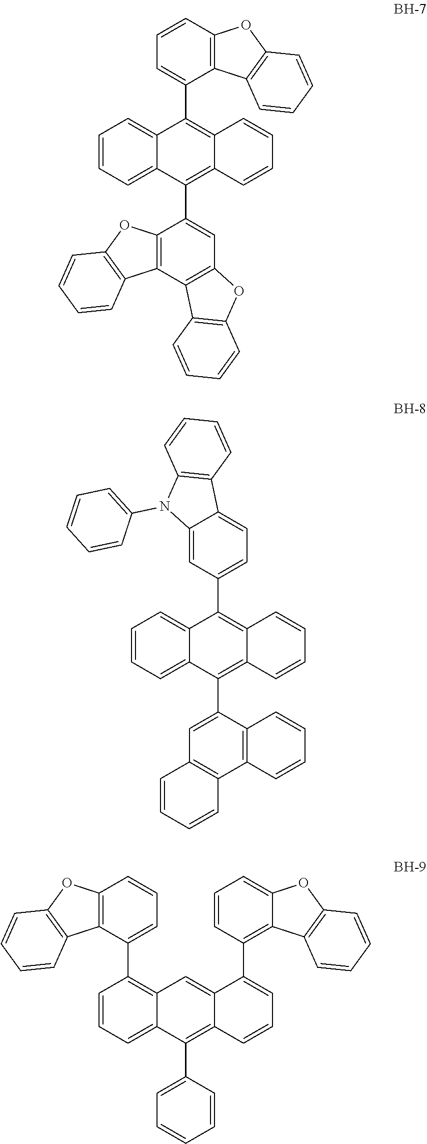

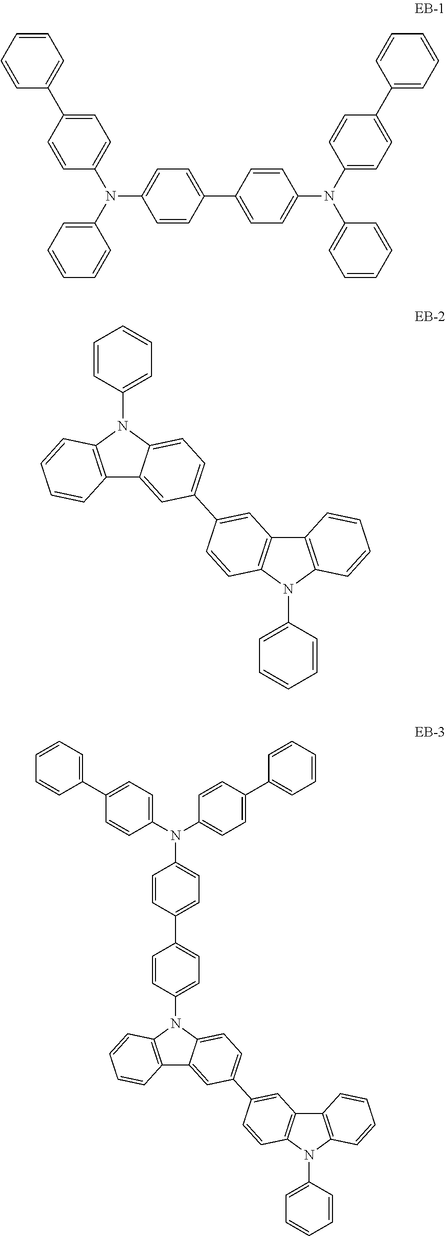 [SMILES: c1ccc(-c2ccc(N(c3ccccc3)c3ccc(-c4ccc(N(c5ccccc5)c5ccc(-c6ccccc6)cc5)cc4)cc3)cc2)cc1 ; c1ccc(-n2c3ccccc3c3cc(-c4ccc5c(c4)c4ccccc4n5-c4ccccc4)ccc32)cc1 ; c1ccc(-c2ccc(N(c3ccc(-c4ccccc4)cc3)c3ccc(-c4ccc(-n5c6ccccc6c6cc(-c7ccc8c(c7)c7ccccc7n8-c7ccccc7)ccc65)cc4)cc3)cc2)cc1]

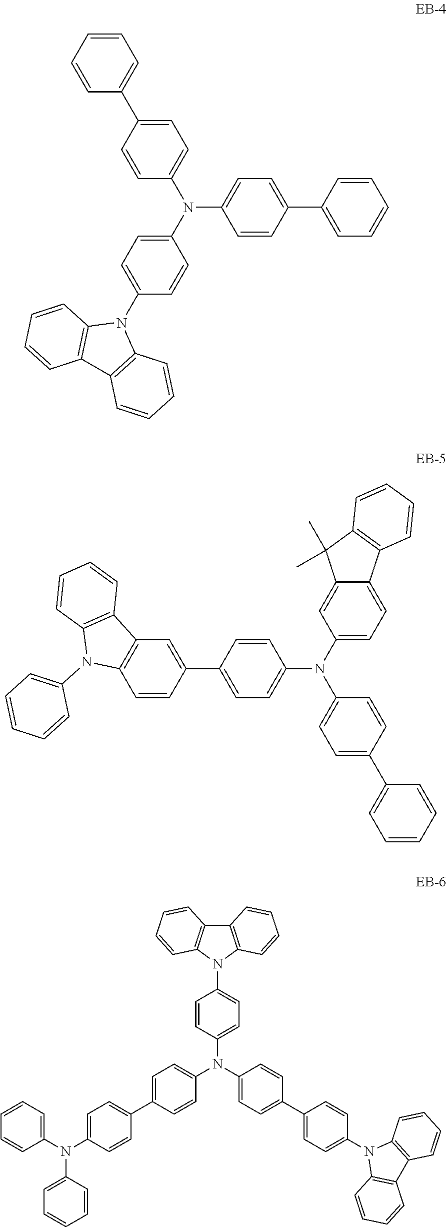 [SMILES: c1ccc(-c2ccc(N(c3ccc(-c4ccccc4)cc3)c3ccc(-n4c5ccccc5c5ccccc54)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccccc2)c2ccc(-c3ccc(N(c4ccc(-c5ccc(-n6c7ccccc7c7ccccc76)cc5)cc4)c4ccc(-n5c6ccccc6c6ccccc65)cc4)cc3)cc2)cc1]

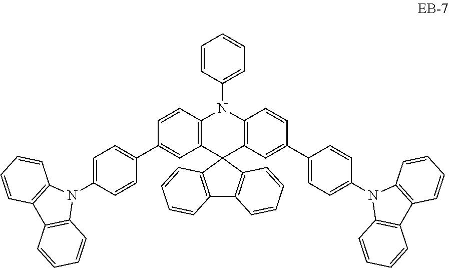 [SMILES: c1ccc(N2c3ccc(-c4ccc(-n5c6ccccc6c6ccccc65)cc4)cc3C3(c4ccccc4-c4ccccc43)c3cc(-c4ccc(-n5c6ccccc6c6ccccc65)cc4)ccc32)cc1]

The driving voltage and color coordinates of the organic light emitting devices prepared in the Examples and Comparative Examples were measured at a current density of 10 mA/cm², and the lifetime (T90) was measured at a current density of 20 mA/cm². Lifetime (T90) means the time required for the luminance to be reduced to 90% when the initial luminance is taken as 100%. The results are shown in Table 1 below, and the dipole moment values of the compounds used in the host and the hole adjustment layer are also shown together.

TABLE 1

| | | | Hole adjustment | | @10 mA/cm² | | | |
|---|---|---|---|---|---|---|---|---|
| | Host | | layer | | Driving | | | Lifetime(T90) |
| | Material | DM | Material | DM | voltage (V) | CIE_x | CIE_y | (hr@20 mA/cm²) |
| Example 1 | 1-1 | 0.40 | 2-1 | 1.20 | 3.62 | 0.133 | 0.119 | 180 |
| Example 2 | 1-1 | 0.40 | 2-2 | 1.47 | 3.65 | 0.132 | 0.119 | 185 |
| Example 3 | 1-2 | 0.49 | 2-3 | 1.50 | 3.59 | 0.133 | 0.118 | 178 |
| Example 4 | 1-2 | 0.49 | 2-4 | 1.51 | 3.68 | 0.132 | 0.119 | 188 |
| Example 5 | 1-3 | 0.53 | 2-4 | 1.51 | 3.61 | 0.133 | 0.120 | 171 |
| Example 6 | 1-3 | 0.53 | 2-5 | 1.75 | 3.64 | 0.131 | 0.123 | 192 |
| Example 7 | 1-4 | 0.66 | 2-5 | 1.75 | 3.58 | 0.132 | 0.120 | 195 |
| Example 8 | 1-4 | 0.66 | 2-6 | 1.88 | 3.68 | 0.133 | 0.119 | 184 |
| Example 9 | 1-5 | 0.69 | 2-6 | 1.88 | 3.70 | 0.132 | 0.118 | 179 |
| Example 10 | 1-5 | 0.69 | 2-7 | 1.93 | 3.54 | 0.133 | 0.120 | 181 |
| Example 11 | 1-6 | 0.82 | 2-2 | 1.47 | 3.52 | 0.131 | 0.120 | 180 |
| Example 12 | 1-6 | 0.82 | 2-3 | 1.50 | 3.61 | 0.132 | 0.121 | 181 |
| Example 13 | 1-6 | 0.82 | 2-5 | 1.75 | 3.58 | 0.130 | 0.121 | 199 |
| Example 14 | 1-7 | 0.90 | 2-1 | 1.20 | 3.70 | 0.132 | 0.126 | 187 |
| Example 15 | 1-7 | 0.90 | 2-2 | 1.47 | 3.65 | 0.133 | 0.118 | 178 |
| Example 16 | 1-7 | 0.90 | 2-3 | 1.50 | 3.60 | 0.132 | 0.125 | 184 |
| Example 17 | 1-8 | 1.03 | 2-1 | 1.20 | 3.66 | 0.133 | 0.119 | 181 |
| Example 18 | 1-8 | 1.03 | 2-2 | 1.47 | 3.57 | 0.132 | 0.120 | 177 |
| Example 19 | 1-8 | 1.03 | 2-5 | 1.75 | 3.64 | 0.133 | 0.125 | 189 |
| Example 20 | 1-9 | 1.13 | 2-7 | 1.93 | 3.66 | 0.133 | 0.119 | 182 |
| Comparative | BH-1 | 0.07 | EB-1 | 0.83 | 4.11 | 0.131 | 0.119 | 115 |
| Example 1 | | | | | | | | |
| Comparative | BH-2 | 0.21 | EB-2 | 0.90 | 4.21 | 0.132 | 0.120 | 120 |
| Example 2 | | | | | | | | |
| Comparative | BH-2 | 0.21 | 2-3 | 1.50 | 4.19 | 0.133 | 0.121 | 168 |
| Example 3 | | | | | | | | |
| Comparative | BH-3 | 0.29 | 2-6 | 1.88 | 4.30 | 0.133 | 0.125 | 170 |
| Example 4 | | | | | | | | |
| Comparative | BH-1 | 0.07 | EB-4 | 2.06 | 4.24 | 0.132 | 0.123 | 127 |
| Example 5 | | | | | | | | |
| Comparative | BH-3 | 0.29 | EB-7 | 4.34 | 4.27 | 0.132 | 0.119 | 102 |
| Example 6 | | | | | | | | |
| Comparative | 1-4 | 0.66 | EB-1 | 0.83 | 3.74 | 0.133 | 0.119 | 98 |
| Example 7 | | | | | | | | |
| Comparative | 1-6 | 0.82 | EB-3 | 1.13 | 3.81 | 0.134 | 0.123 | 112 |
| Example 8 | | | | | | | | |
| Comparative | 1-2 | 0.49 | EB-5 | 2.32 | 3.75 | 0.133 | 0.122 | 107 |
| Example 9 | | | | | | | | |
| Comparative | 1-5 | 0.69 | EB-6 | 3.02 | 3.68 | 0.133 | 0.123 | 110 |
| Example 10 | | | | | | | | |
| Comparative | BH-5 | 1.36 | EB-2 | 0.90 | 4.24 | 0.134 | 0.123 | 98 |
| Example 11 | | | | | | | | |
| Comparative | BH-7 | 1.66 | EB-3 | 1.13 | 4.30 | 0.132 | 0.121 | 101 |
| Example 12 | | | | | | | | |
| Comparative | BH-6 | 1.56 | 2-3 | 1.50 | 4.27 | 0.133 | 0.119 | 159 |
| Example 13 | | | | | | | | |
| Comparative | BH-9 | 1.93 | 2-7 | 1.93 | 4.20 | 0.132 | 0.122 | 164 |
| Example 14 | | | | | | | | |
| Comparative | BH-4 | 1.32 | EB-4 | 2.06 | 4.15 | 0.134 | 0.123 | 113 |
| Example 15 | | | | | | | | |
| Comparative | BH-8 | 1.67 | EB-7 | 4.34 | 4.22 | 0.132 | 0.126 | 120 |
| Example 16 | | | | | | | | |

As shown in Table 1, the compounds of Chemical Formula 1 of the present disclosure are advantageous for injection of holes and electrons and thus, exhibit the property of lowering the driving voltage when used as a host. In addition, the compound of Chemical Formula 2 of the present disclosure has excellent ability to block electrons passing from the light emitting layer and has excellent stability against electrons, and when this is applied to the hole adjustment layer, a device having a long lifetime can be obtained. In particular, when these two are applied at the same time, it is confirmed that electrons and holes are well balanced in the light emitting layer, and that the effect of low voltage and long lifetime is obtained,

Description of Symbols

| | |
|---|---|
| 1: substrate | 2: anode |
| 3: hole transport layer | 4: hole adjustment layer |
| 5: light emitting layer | 6: electron transport layer |
| 7: cathode | 8: hole injection layer |
| 9: electronic control layer | 10: electron injection layer |

1. An organic light emitting device comprising:
an anode;
a hole transport layer;
a hole adjustment layer;
a light emitting layer;
an electron transport layer; and
a cathode,
wherein the light emitting layer includes a host and a dopant,
the host has a dipole moment value of 0.4 to 1.3, and
the hole adjustment layer includes a compound having a dipole moment value of 1.2 to 2.0.

2. The organic light emitting device according to claim 1,
wherein the difference between the dipole moment value of the host and the dipole moment value of the compound contained in the hole adjustment layer is 0.15 to 1.25.

3. The organic light emitting device according to claim 1,
wherein the host is a compound of Chemical Formula 1: 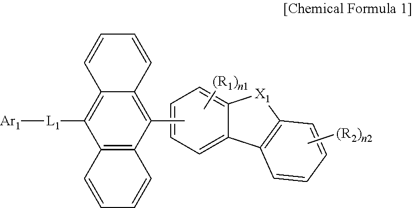
wherein in Chemical Formula 1:
X₁ is O or S;
L₁ is a single bond or a substituted or unsubstituted C₆₋₆₀ arylene;
Ar₁ is a substituted or unsubstituted C₆₋₆₀ aryl;
R₁ and R₂ are each independently hydrogen, deuterium, halogen, cyano, nitro, amino, a substituted or unsubstituted C₁₋₆₀ alkyl, a substituted or unsubstituted C₃₋₆₀ cycloalkyl, a substituted or unsubstituted C₂₋₆₀ alkenyl, a substituted or unsubstituted C₆₋₆₀ aryl, or a substituted or unsubstituted C₂₋₆₀ heteroaryl containing one or more heteroatoms selected from the group consisting of N, O and S, or two adjacent groups are bonded with each other to form a benzene ring;
n1 is an integer from 0 to 3; and
n2 is an integer from 0 to 4.

4. The organic light emitting device according to claim 1,
wherein L₁ is a single bond or phenylene.

5. The organic light emitting device according to claim 1,
wherein Ar₁ is phenyl, biphenylyl, terphenylyl, naphthyl, or naphthylphenyl.

6. The organic light emitting device according to claim 3,
wherein the compound of Chemical Formula 1 is any one compound selected from the group consisting of the following compounds:

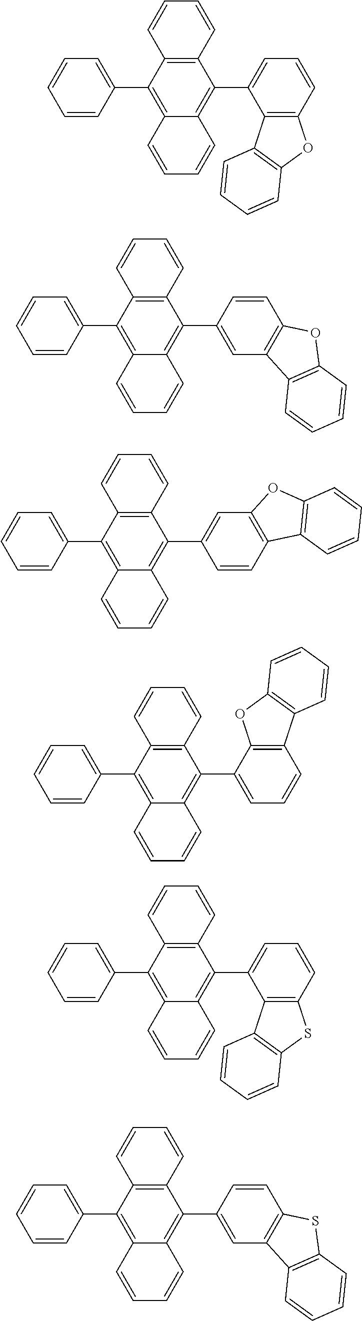

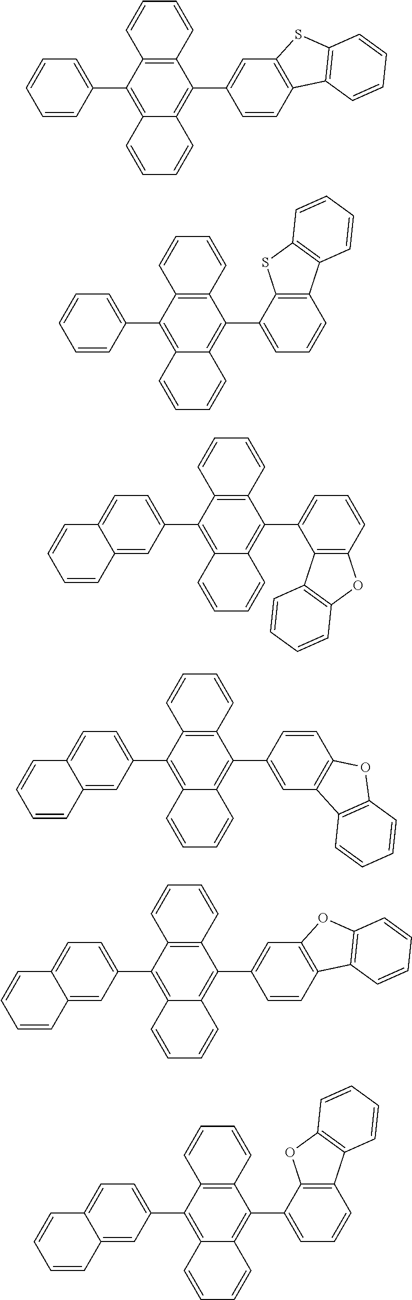

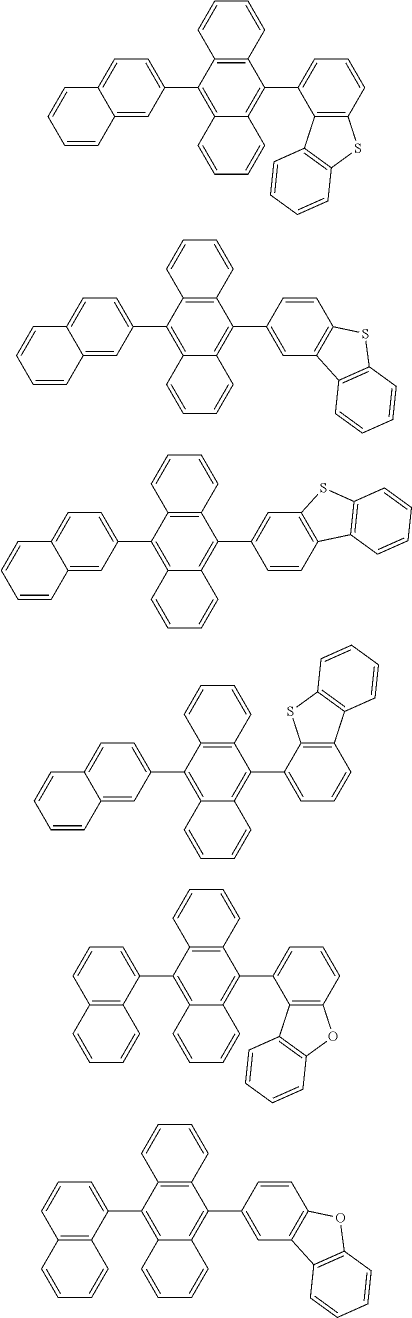

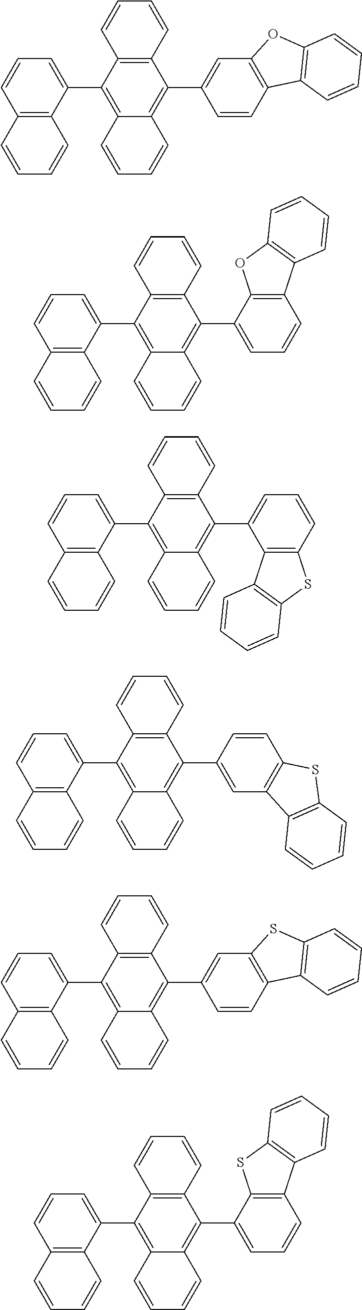

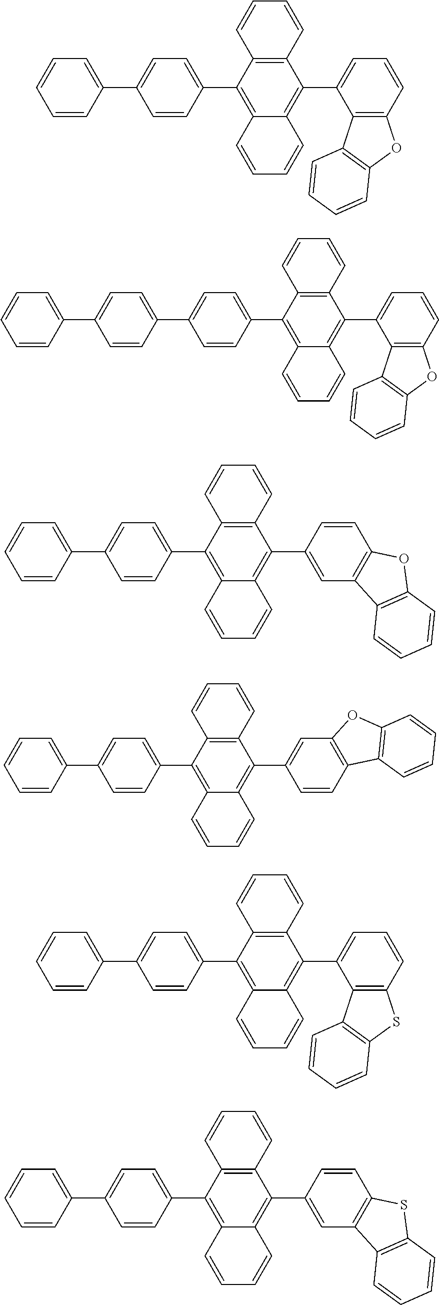

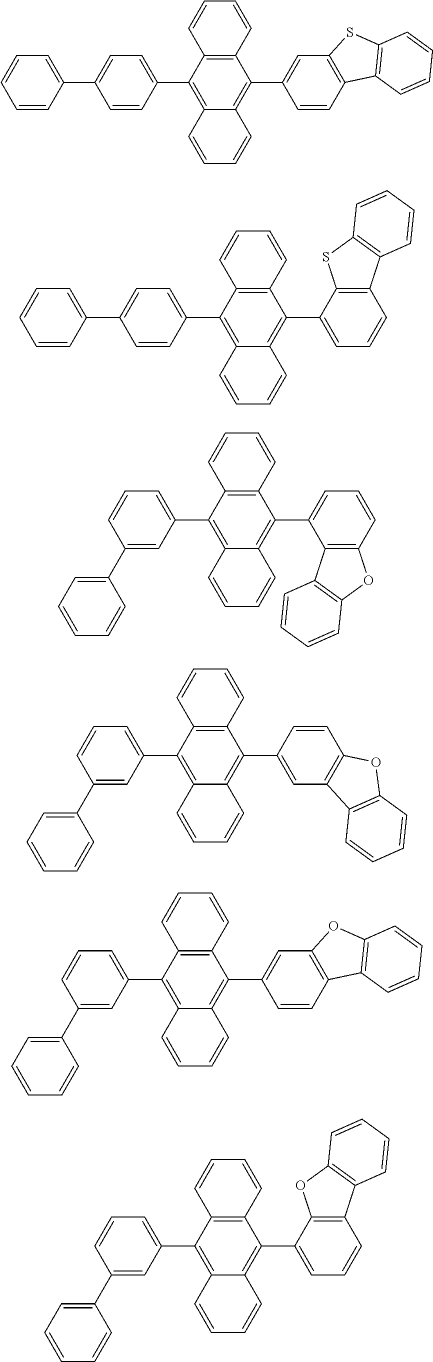

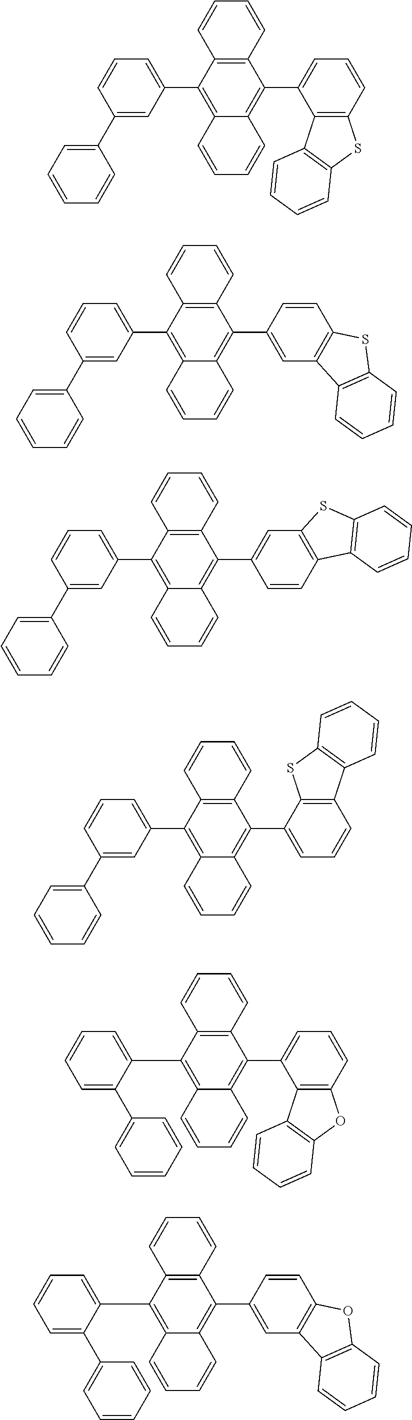

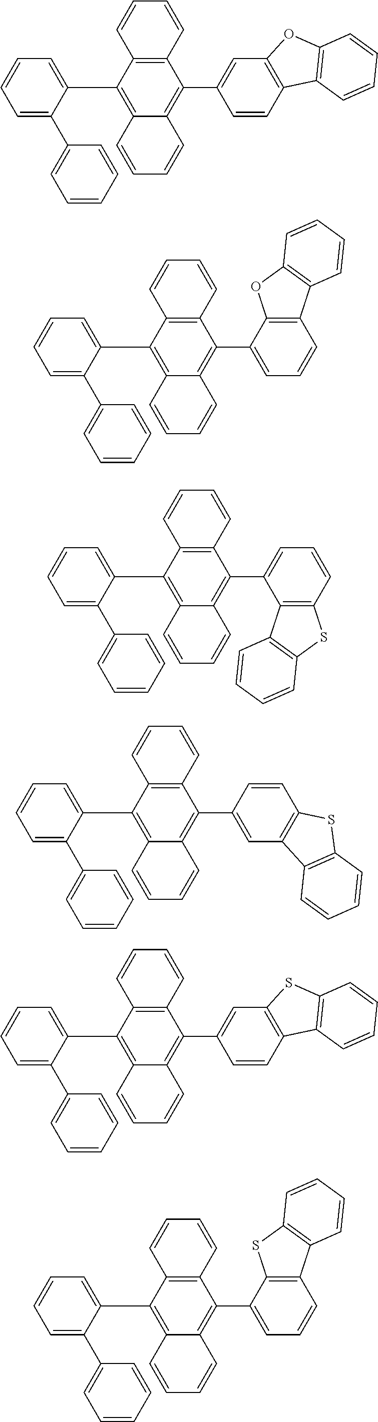

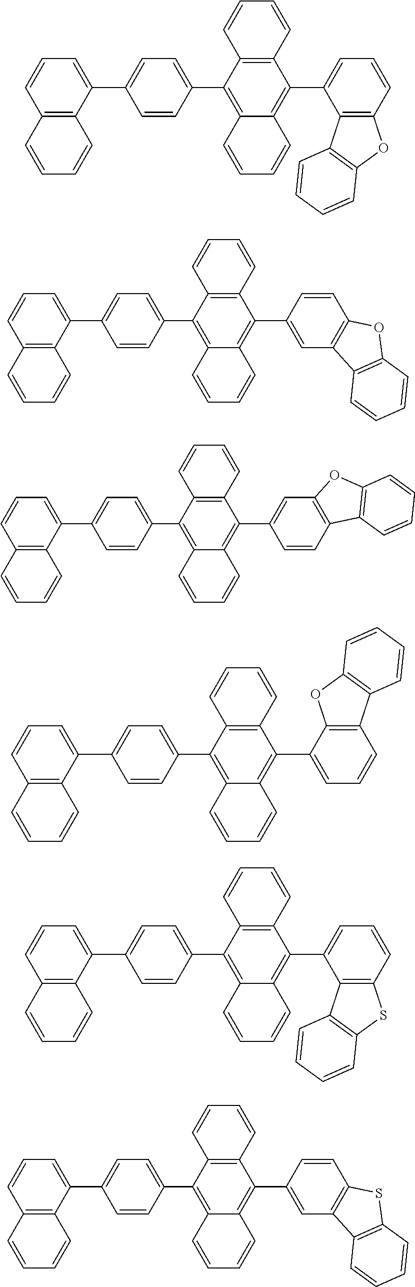

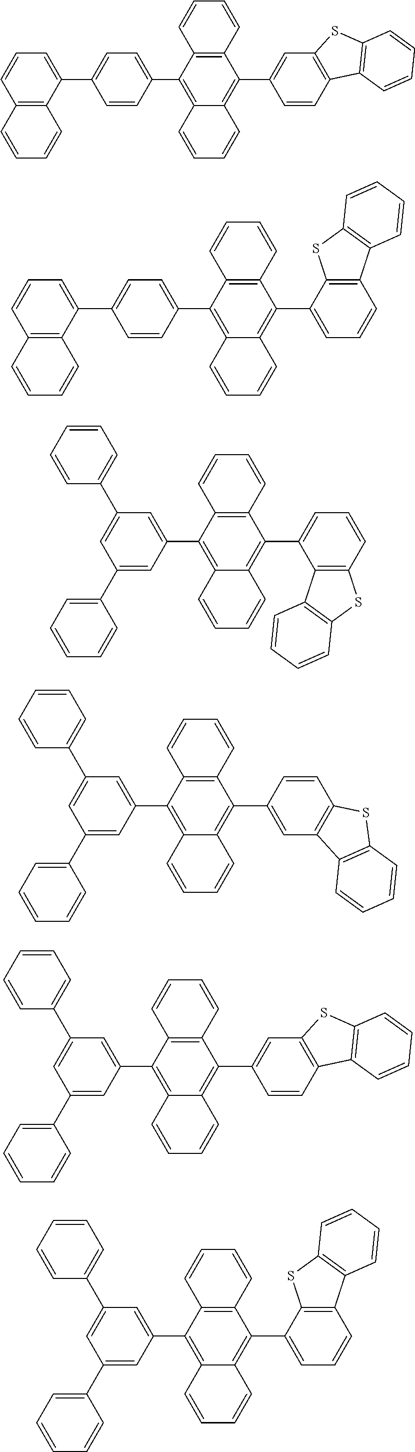

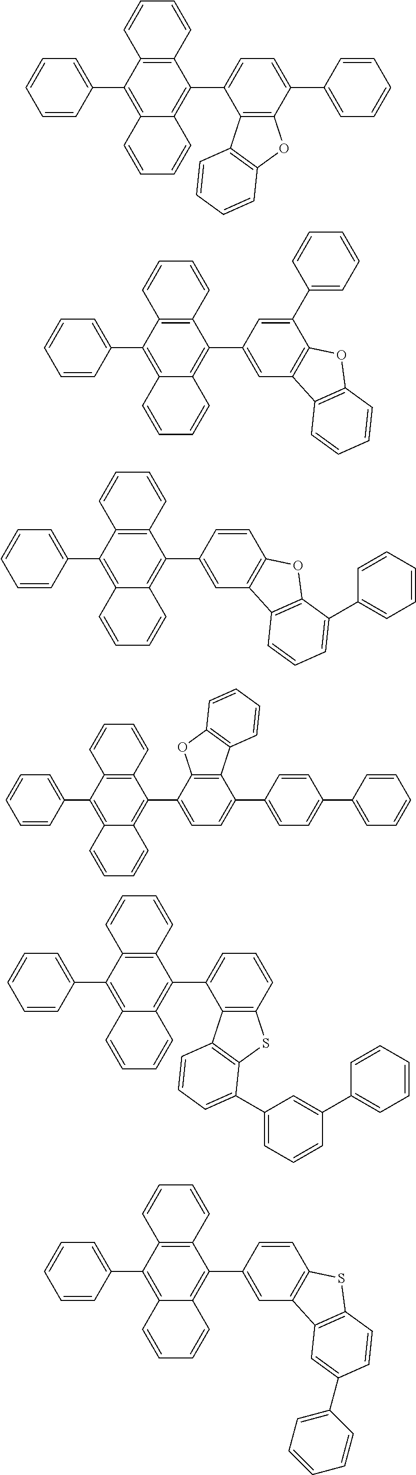

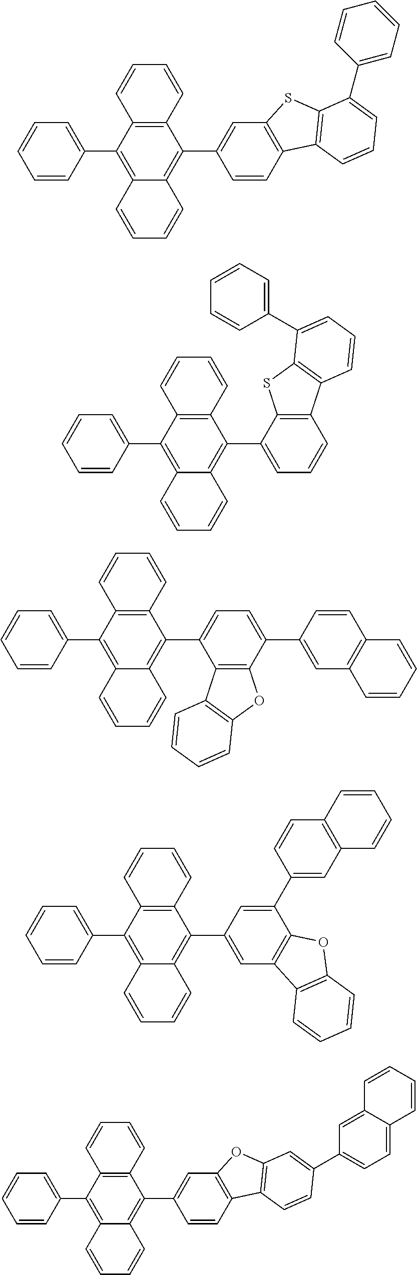

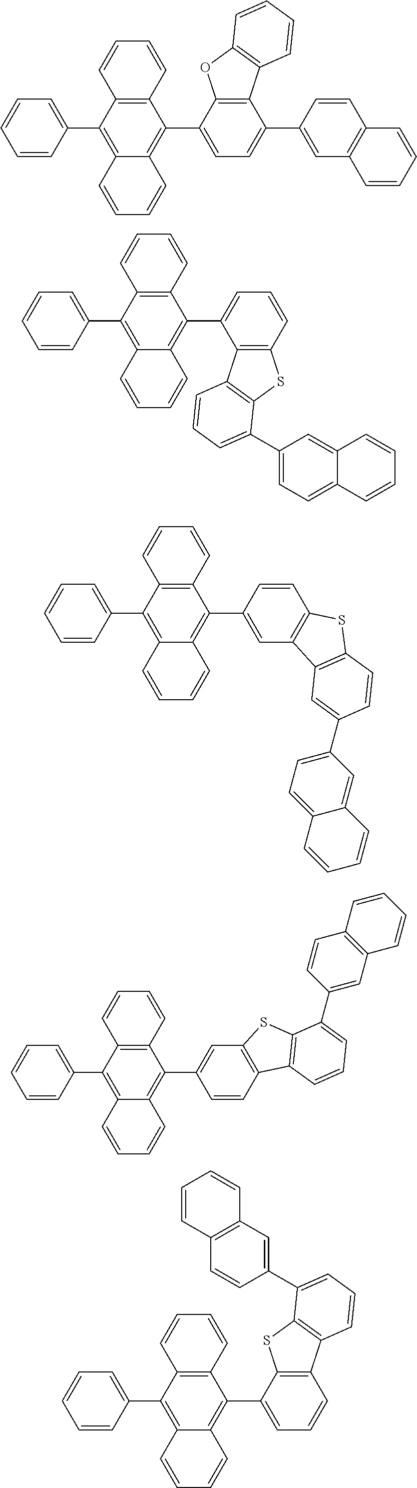

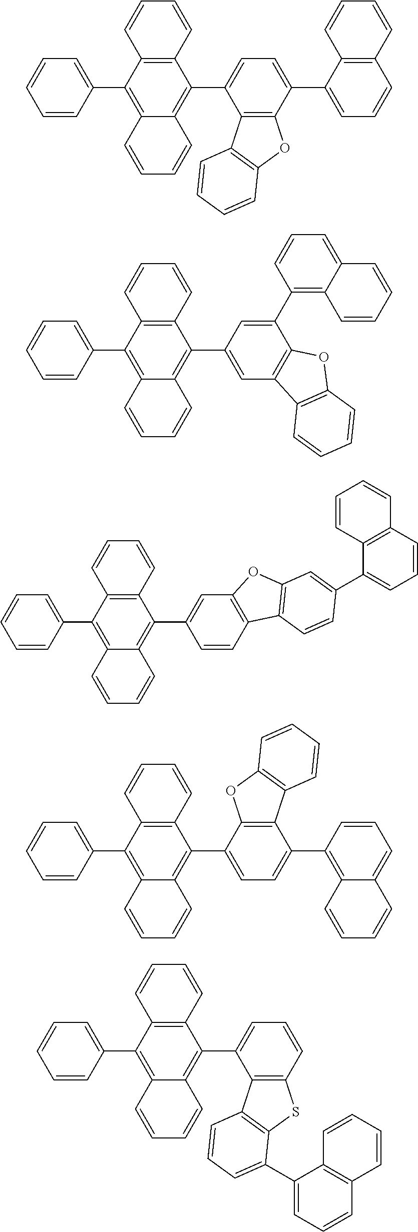

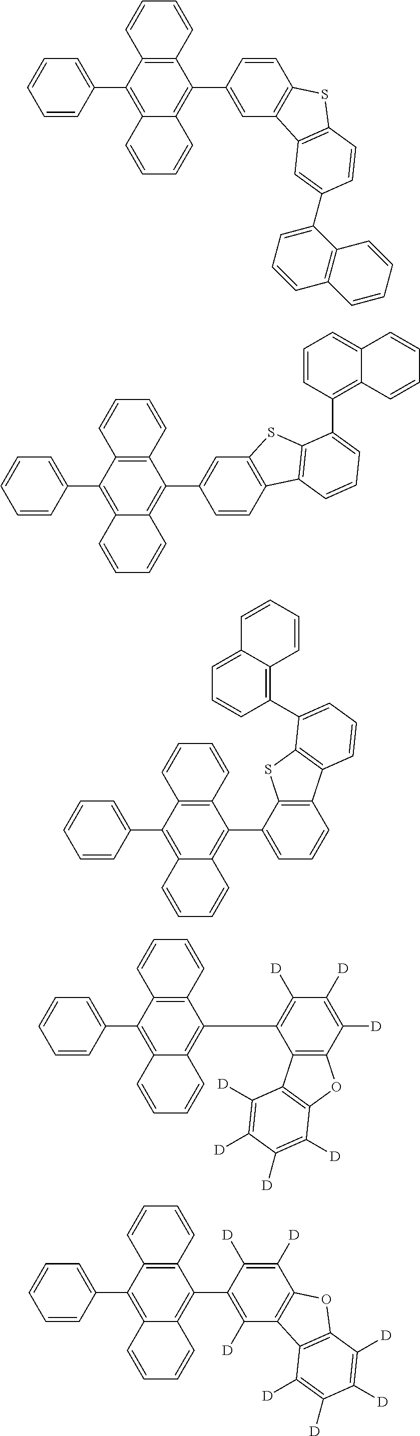

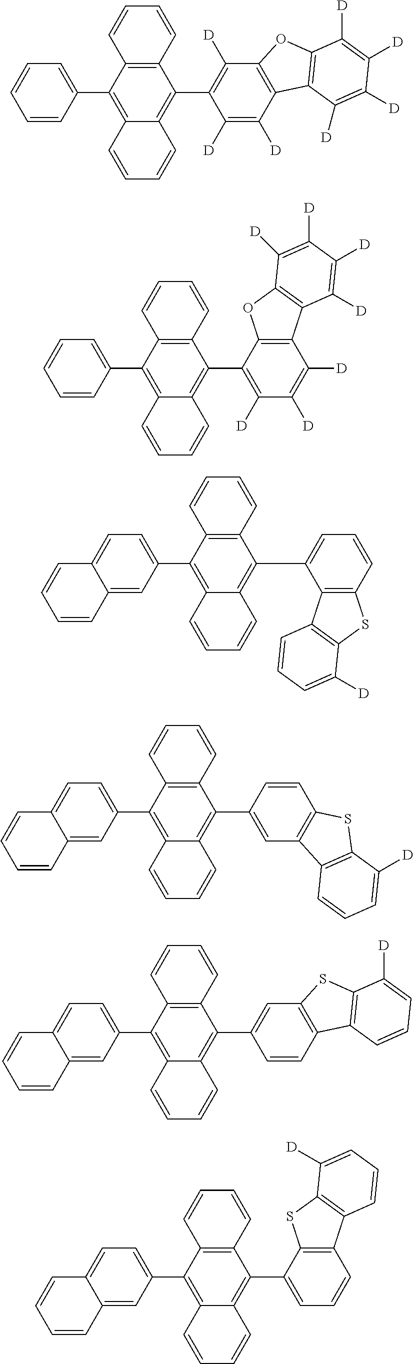

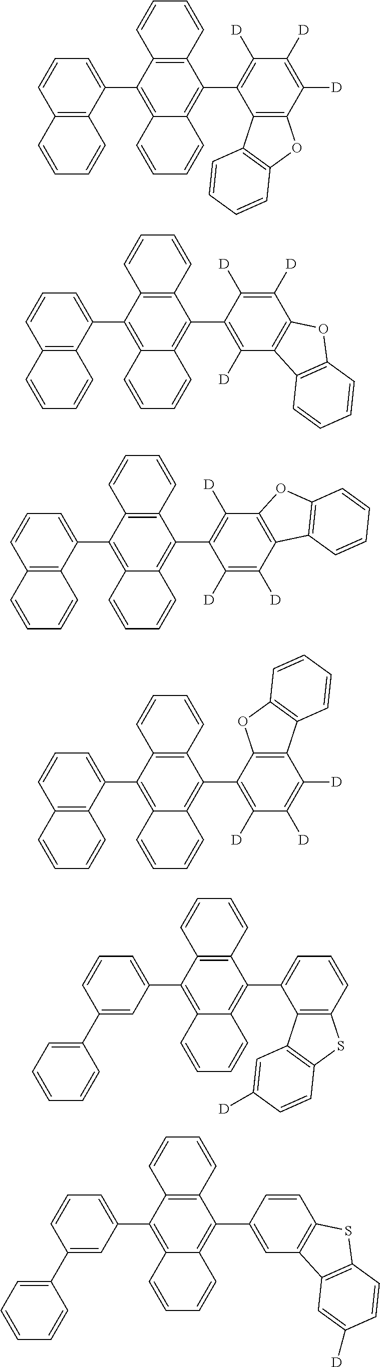

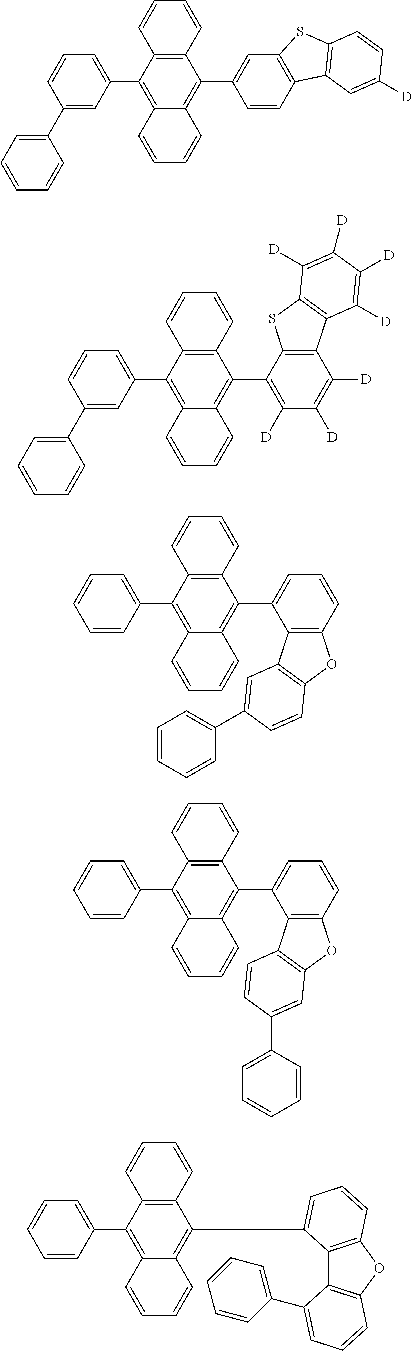

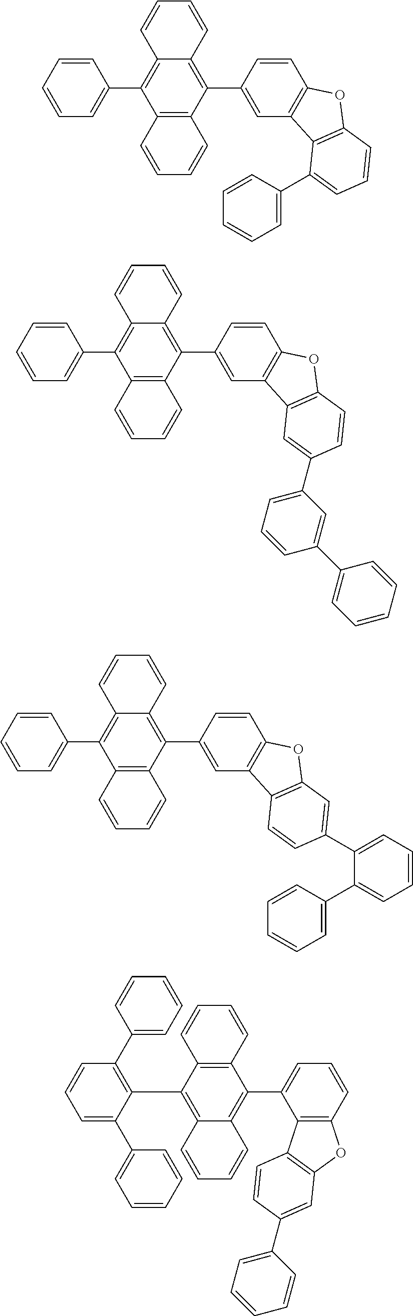 [SMILES: c1ccc(-c2c3ccccc3c(-c3ccc4oc5cccc(-c6ccccc6)c5c4c3)c3ccccc23)cc1 ; c1ccc(-c2cccc(-c3ccc4oc5ccc(-c6c7ccccc7c(-c7ccccc7)c7ccccc67)cc5c4c3)c2)cc1 ; c1ccc(-c2ccccc2-c2ccc3c(c2)oc2ccc(-c4c5ccccc5c(-c5ccccc5)c5ccccc45)cc23)cc1 ; c1ccc(-c2ccc3c(c2)oc2cccc(-c4c5ccccc5c(-c5c(-c6ccccc6)cccc5-c5ccccc5)c5ccccc45)c23)cc1]

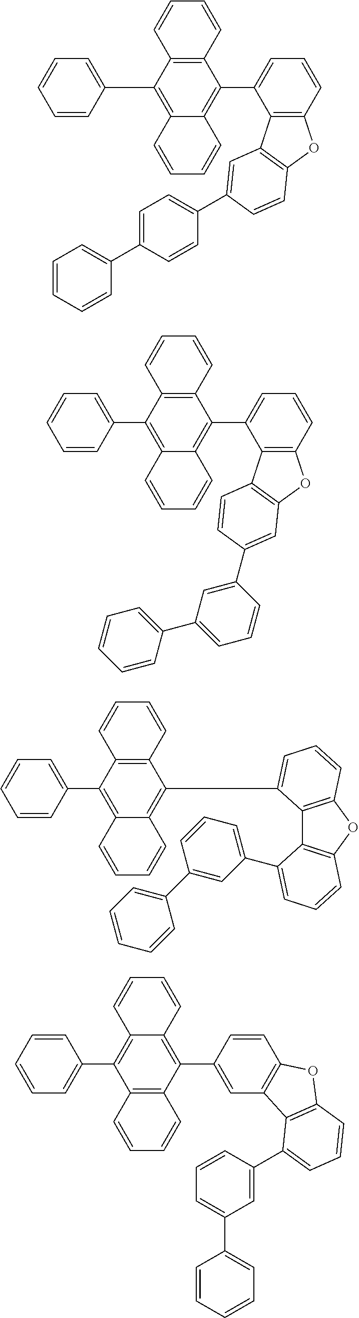

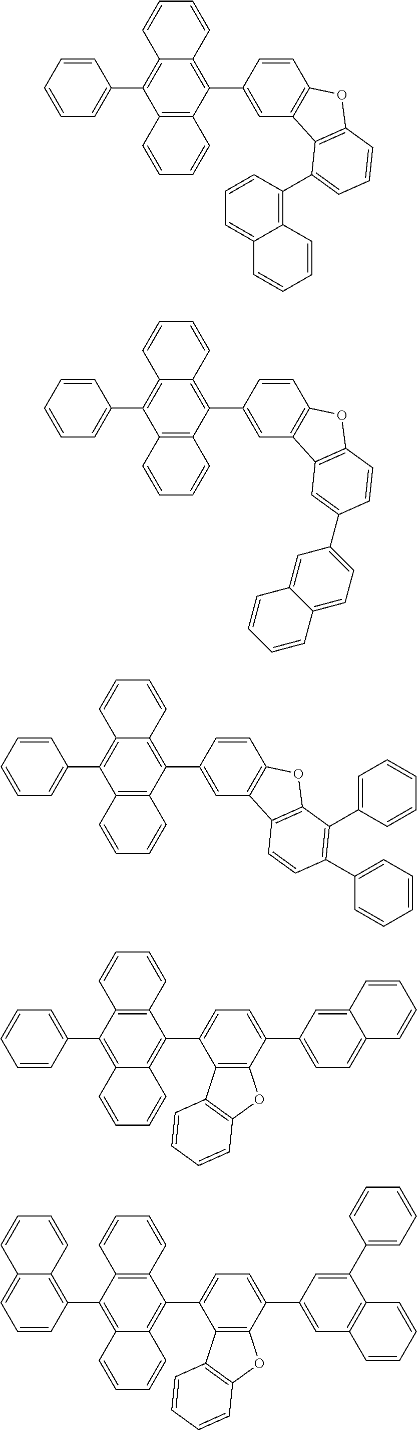 [SMILES: c1ccc(-c2c3ccccc3c(-c3ccc4oc5cccc(-c6cccc7ccccc67)c5c4c3)c3ccccc23)cc1 ; c1ccc(-c2c3ccccc3c(-c3ccc4oc5ccc(-c6ccc7ccccc7c6)cc5c4c3)c3ccccc23)cc1 ; c1ccc(-c2ccc3c(oc4ccc(-c5c6ccccc6c(-c6ccccc6)c6ccccc56)cc43)c2-c2ccccc2)cc1 ; c1ccc(-c2c3ccccc3c(-c3ccc(-c4ccc5ccccc5c4)c4oc5ccccc5c34)c3ccccc23)cc1 ; c1ccc(-c2cc(-c3ccc(-c4c5ccccc5c(-c5cccc6ccccc56)c5ccccc45)c4c3oc3ccccc34)cc3ccccc23)cc1]

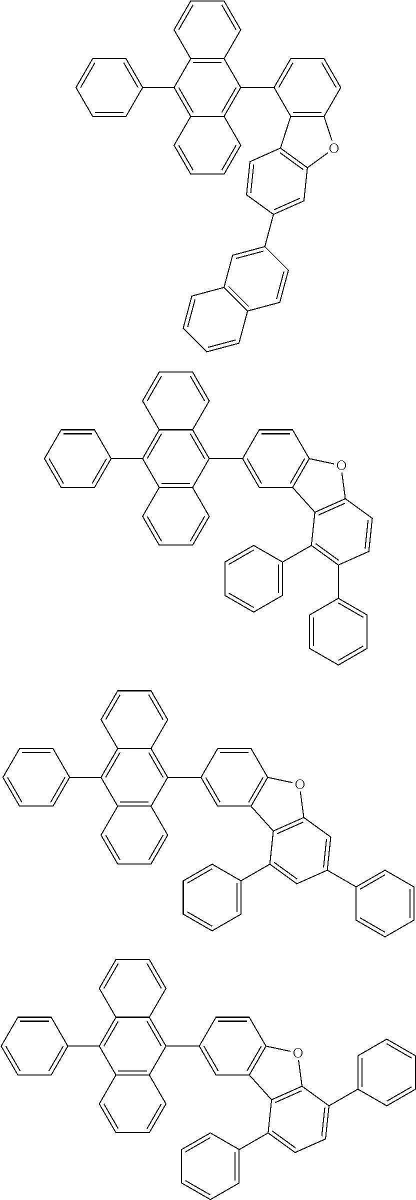

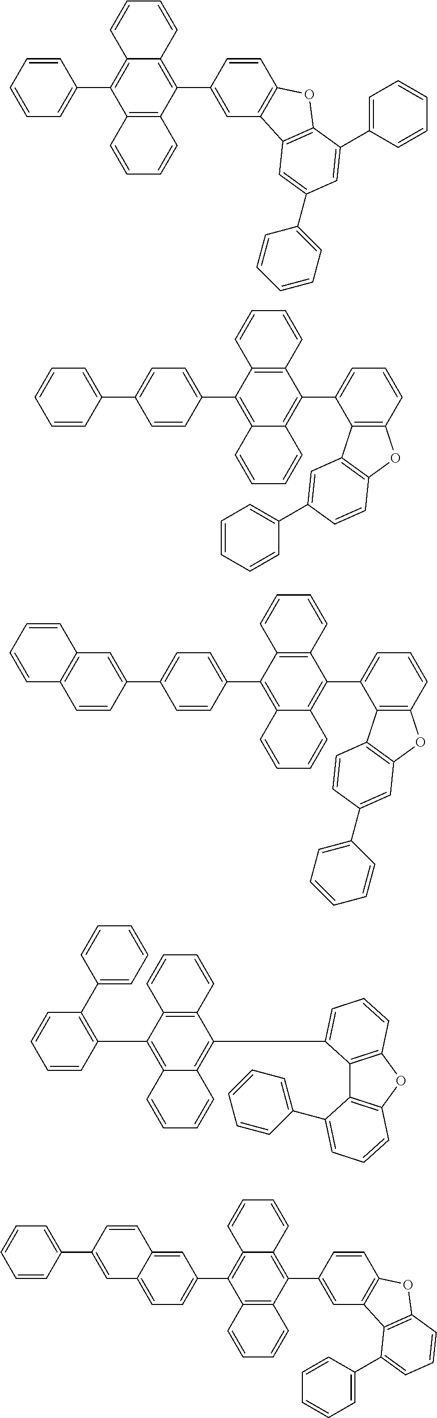

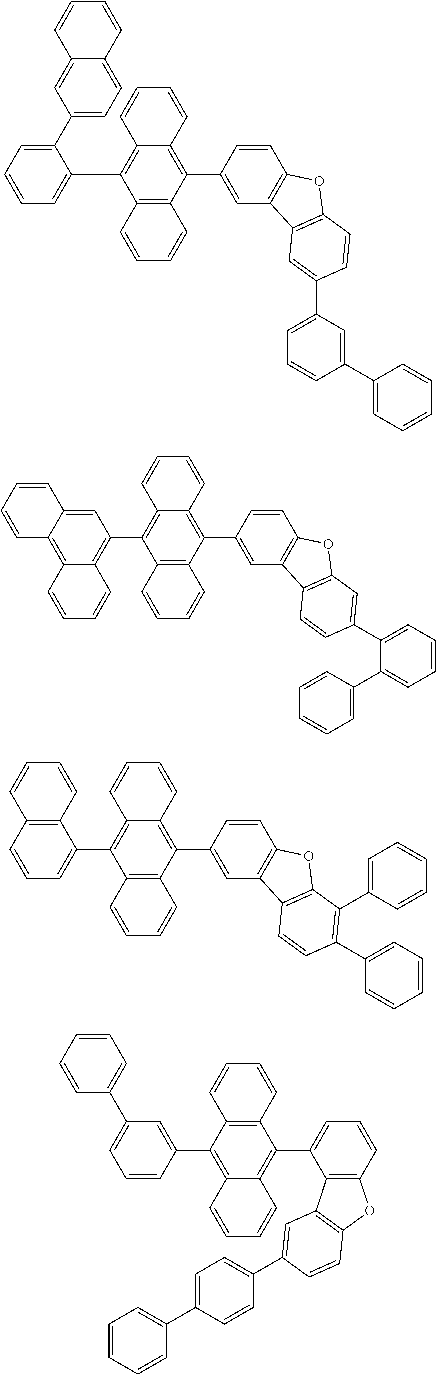 [SMILES: c1ccc(-c2cccc(-c3ccc4oc5ccc(-c6c7ccccc7c(-c7ccccc7-c7ccc8ccccc8c7)c7ccccc67)cc5c4c3)c2)cc1 ; c1ccc(-c2ccccc2-c2ccc3c(c2)oc2ccc(-c4c5ccccc5c(-c5cc6ccccc6c6ccccc56)c5ccccc45)cc23)cc1 ; c1ccc(-c2ccc3c(oc4ccc(-c5c6ccccc6c(-c6cccc7ccccc67)c6ccccc56)cc43)c2-c2ccccc2)cc1 ; c1ccc(-c2ccc(-c3ccc4oc5cccc(-c6c7ccccc7c(-c7cccc(-c8ccccc8)c7)c7ccccc67)c5c4c3)cc2)cc1]

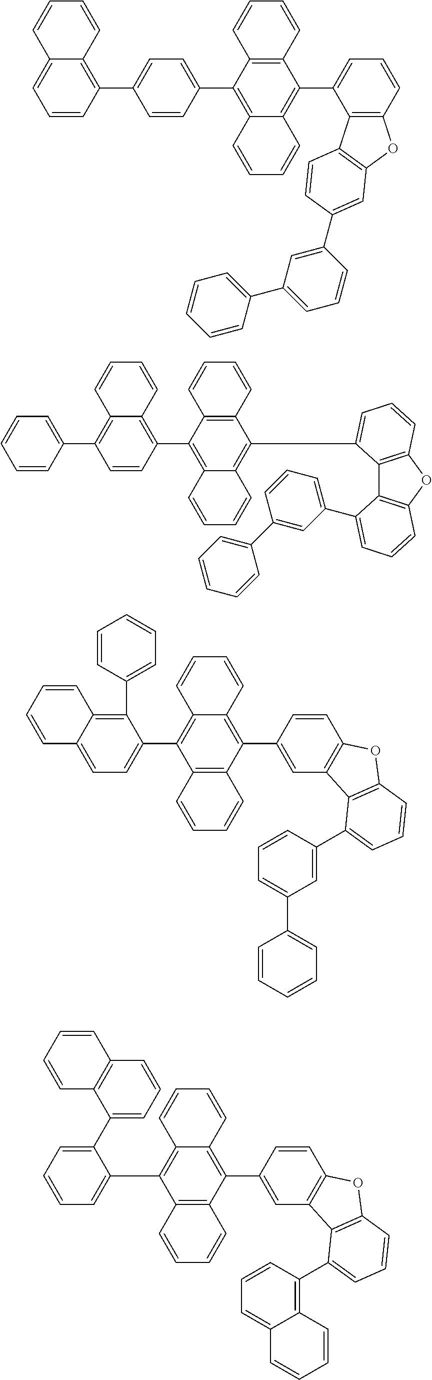

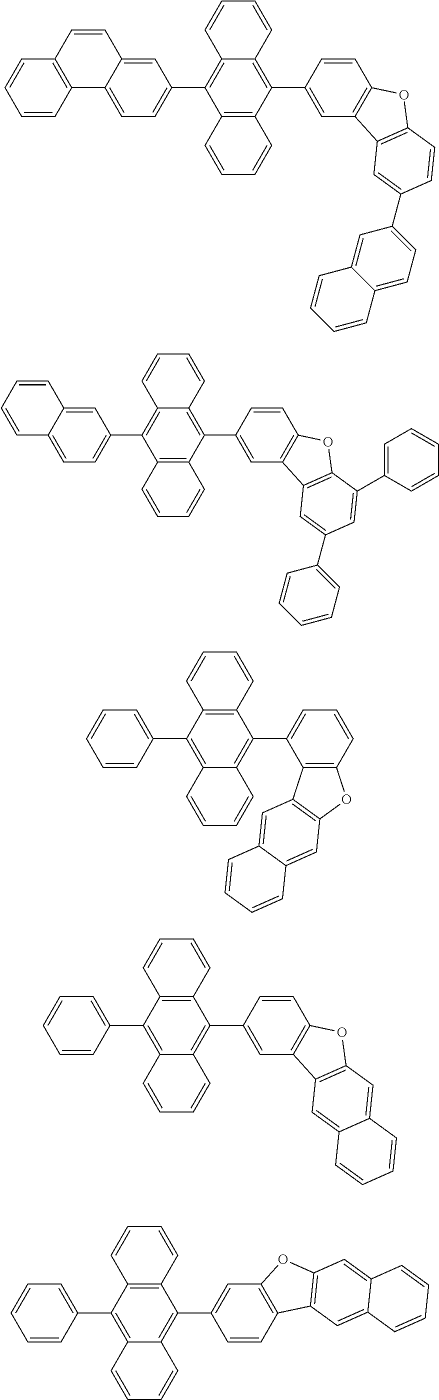 [SMILES: c1ccc2cc(-c3ccc4oc5ccc(-c6c7ccccc7c(-c7ccc8c(ccc9ccccc98)c7)c7ccccc67)cc5c4c3)ccc2c1 ; c1ccc(-c2cc(-c3ccccc3)c3oc4ccc(-c5c6ccccc6c(-c6ccc7ccccc7c6)c6ccccc56)cc4c3c2)cc1 ; c1ccc(-c2c3ccccc3c(-c3cccc4oc5cc6ccccc6cc5c34)c3ccccc23)cc1 ; c1ccc(-c2c3ccccc3c(-c3ccc4oc5cc6ccccc6cc5c4c3)c3ccccc23)cc1 ; c1ccc(-c2c3ccccc3c(-c3ccc4c(c3)oc3cc5ccccc5cc34)c3ccccc23)cc1]

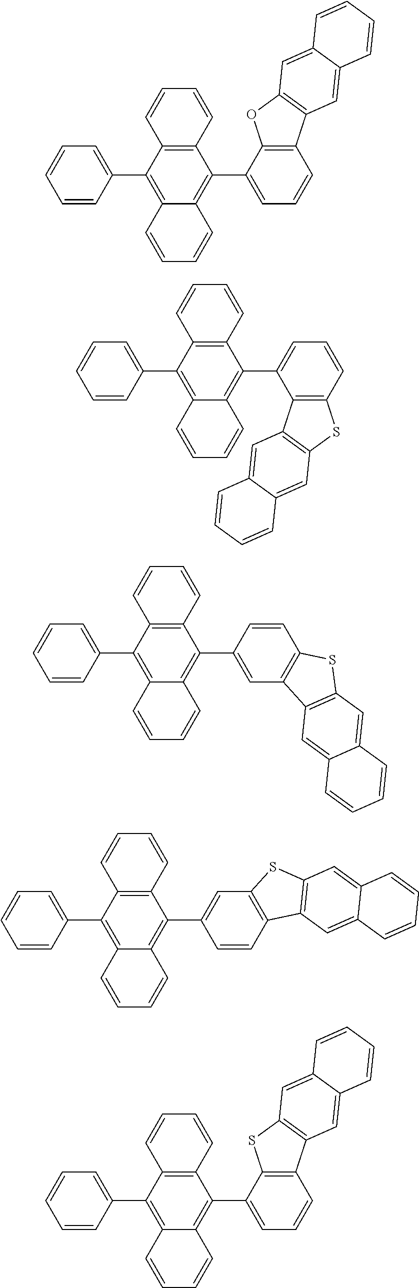

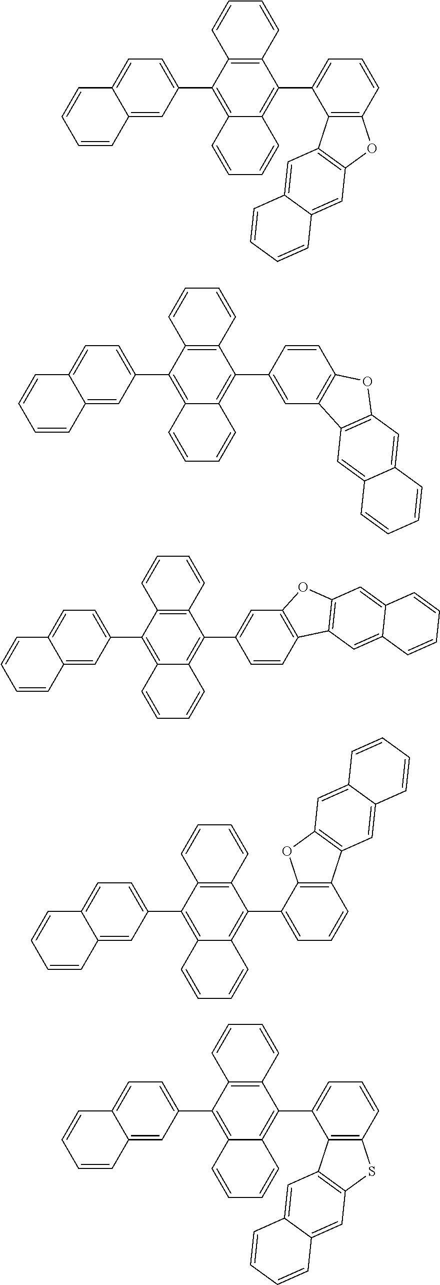

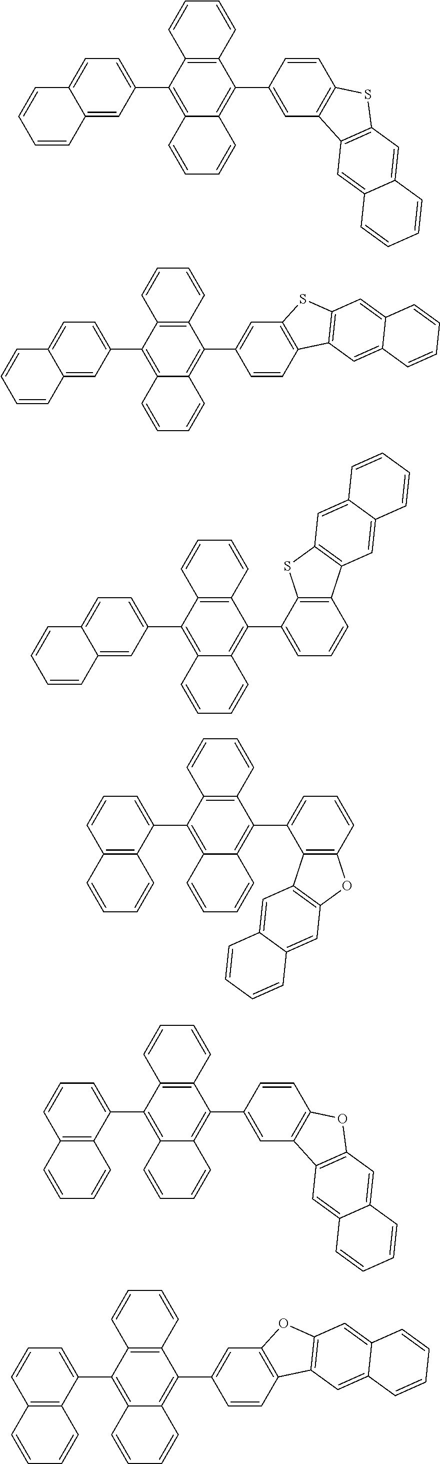

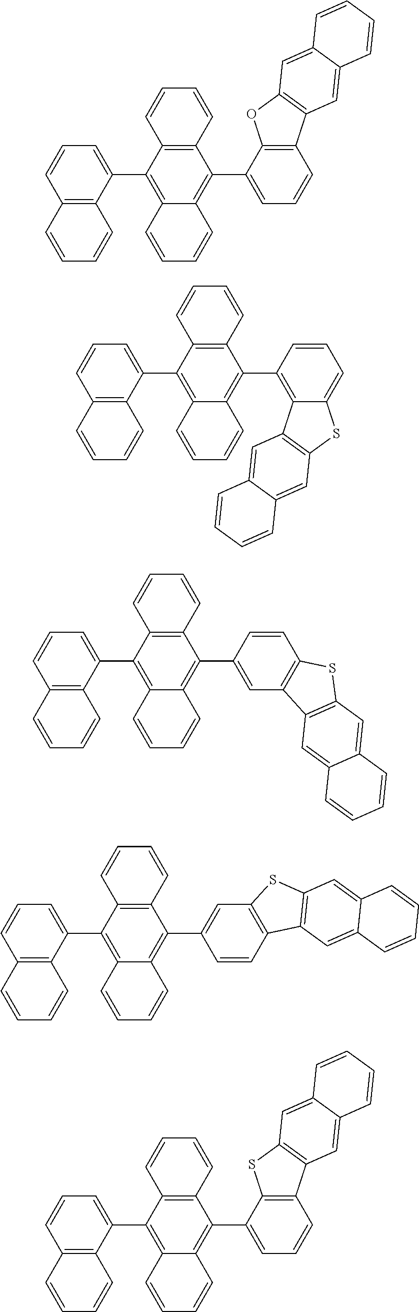

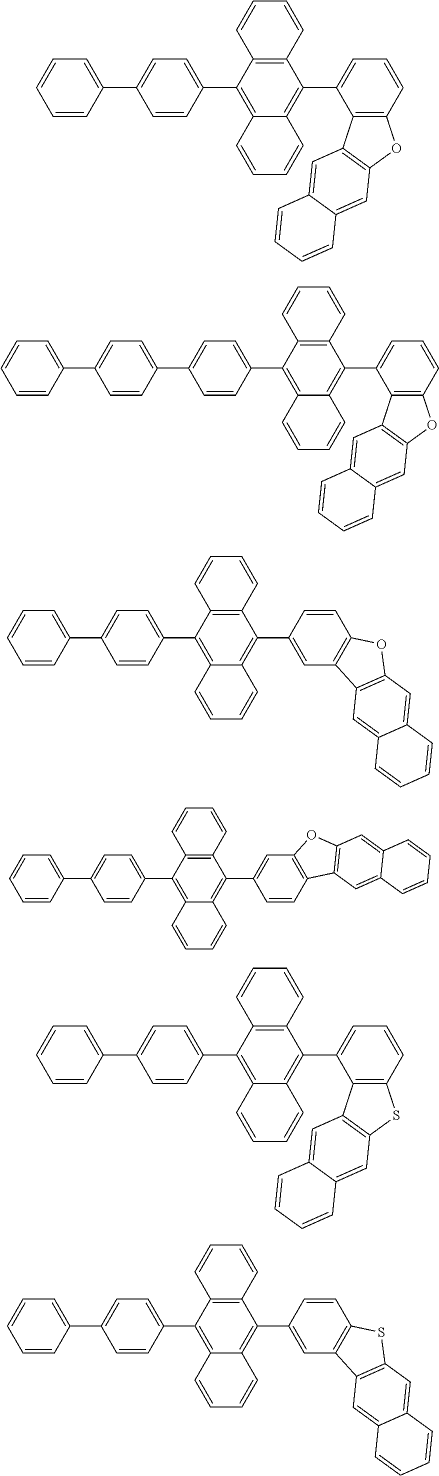

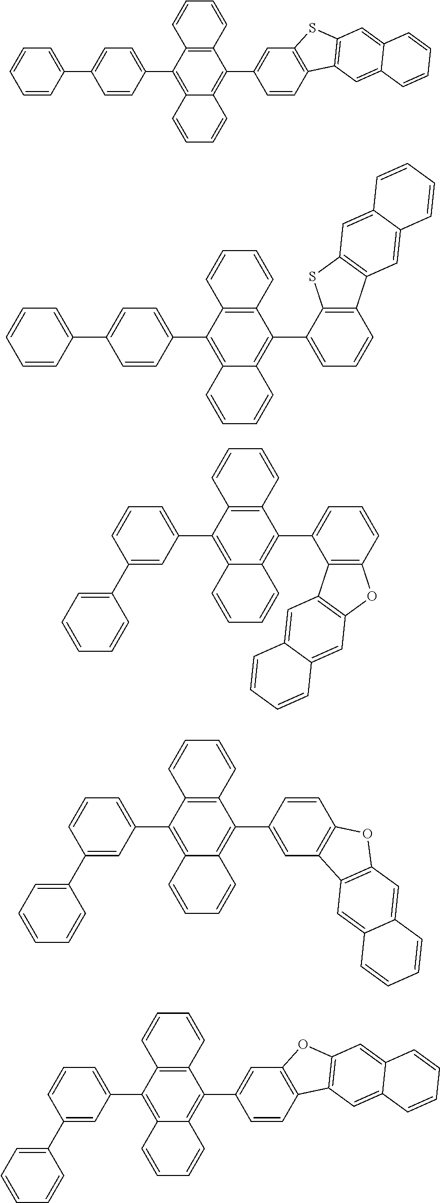

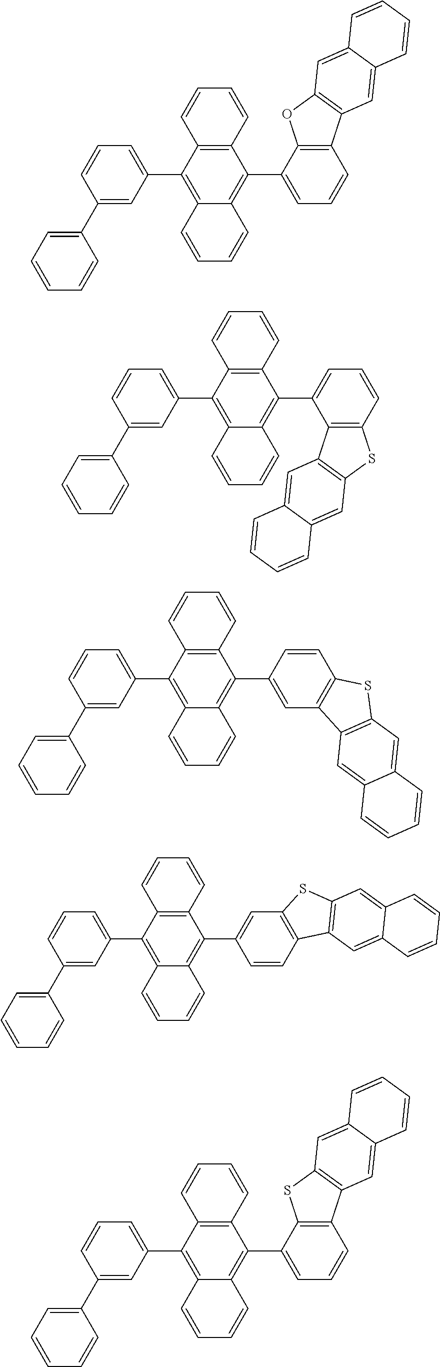 [SMILES: c1ccc(-c2cccc(-c3c4ccccc4c(-c4cccc5c4oc4cc6ccccc6cc45)c4ccccc34)c2)cc1 ; c1ccc(-c2cccc(-c3c4ccccc4c(-c4cccc5sc6cc7ccccc7cc6c45)c4ccccc34)c2)cc1 ; c1ccc(-c2cccc(-c3c4ccccc4c(-c4ccc5sc6cc7ccccc7cc6c5c4)c4ccccc34)c2)cc1 ; c1ccc(-c2cccc(-c3c4ccccc4c(-c4ccc5c(c4)sc4cc6ccccc6cc45)c4ccccc34)c2)cc1 ; c1ccc(-c2cccc(-c3c4ccccc4c(-c4cccc5c4sc4cc6ccccc6cc45)c4ccccc34)c2)cc1]

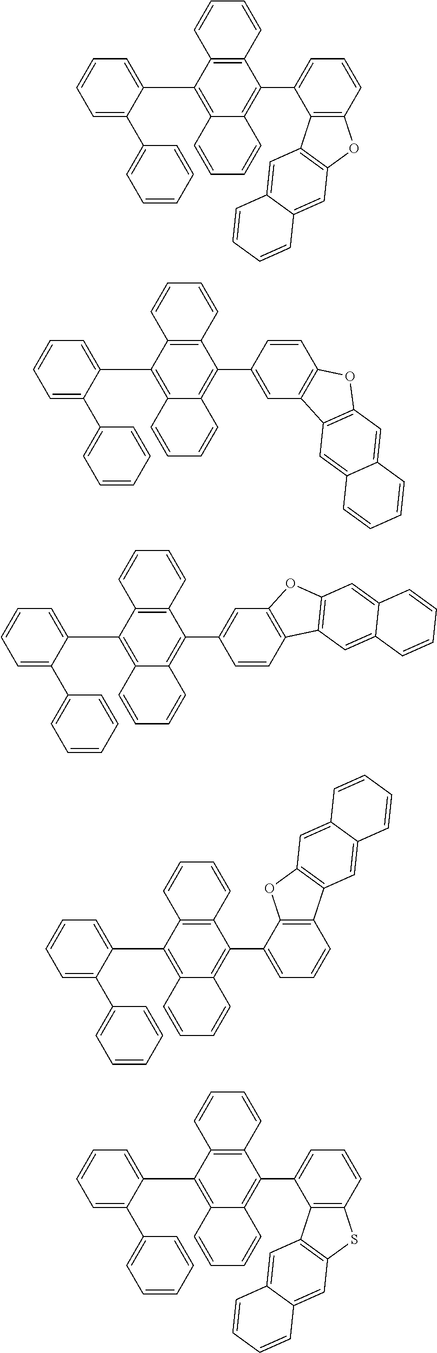 [SMILES: c1ccc(-c2ccccc2-c2c3ccccc3c(-c3cccc4oc5cc6ccccc6cc5c34)c3ccccc23)cc1 ; c1ccc(-c2ccccc2-c2c3ccccc3c(-c3ccc4oc5cc6ccccc6cc5c4c3)c3ccccc23)cc1 ; c1ccc(-c2ccccc2-c2c3ccccc3c(-c3ccc4c(c3)oc3cc5ccccc5cc34)c3ccccc23)cc1 ; c1ccc(-c2ccccc2-c2c3ccccc3c(-c3cccc4c3oc3cc5ccccc5cc34)c3ccccc23)cc1 ; c1ccc(-c2ccccc2-c2c3ccccc3c(-c3cccc4sc5cc6ccccc6cc5c34)c3ccccc23)cc1]

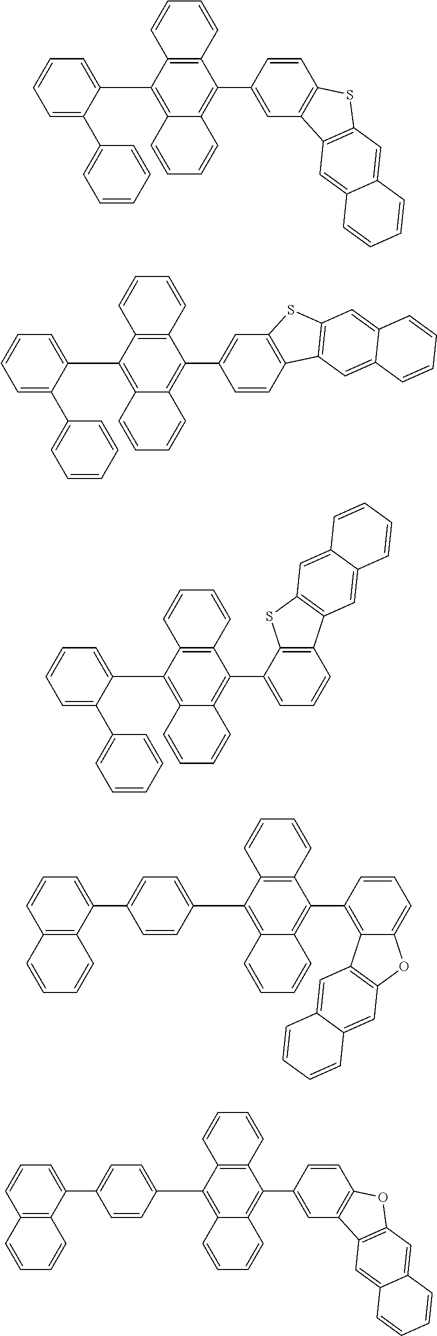 [SMILES: c1ccc(-c2ccccc2-c2c3ccccc3c(-c3ccc4sc5cc6ccccc6cc5c4c3)c3ccccc23)cc1 ; c1ccc(-c2ccccc2-c2c3ccccc3c(-c3ccc4c(c3)sc3cc5ccccc5cc34)c3ccccc23)cc1 ; c1ccc(-c2ccccc2-c2c3ccccc3c(-c3cccc4c3sc3cc5ccccc5cc34)c3ccccc23)cc1 ; c1ccc2cc3c(cc2c1)oc1cccc(-c2c4ccccc4c(-c4ccc(-c5cccc6ccccc56)cc4)c4ccccc24)c13 ; c1ccc2cc3c(cc2c1)oc1ccc(-c2c4ccccc4c(-c4ccc(-c5cccc6ccccc56)cc4)c4ccccc24)cc13]

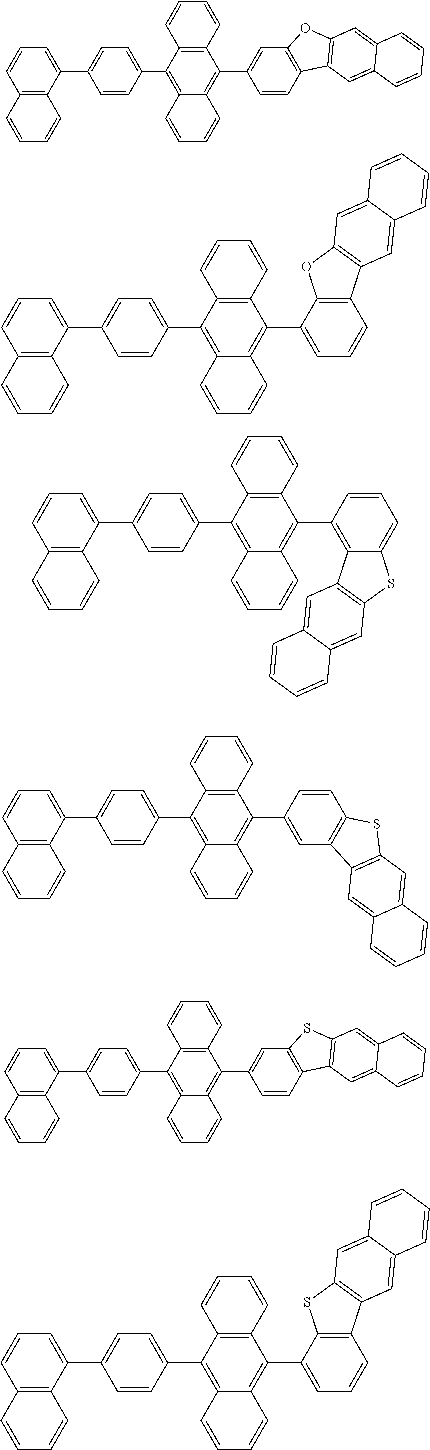

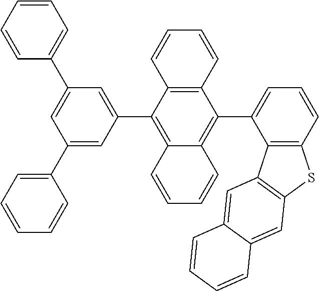 [SMILES: c1ccc(-c2cc(-c3ccccc3)cc(-c3c4ccccc4c(-c4cccc5sc6cc7ccccc7cc6c45)c4ccccc34)c2)cc1]

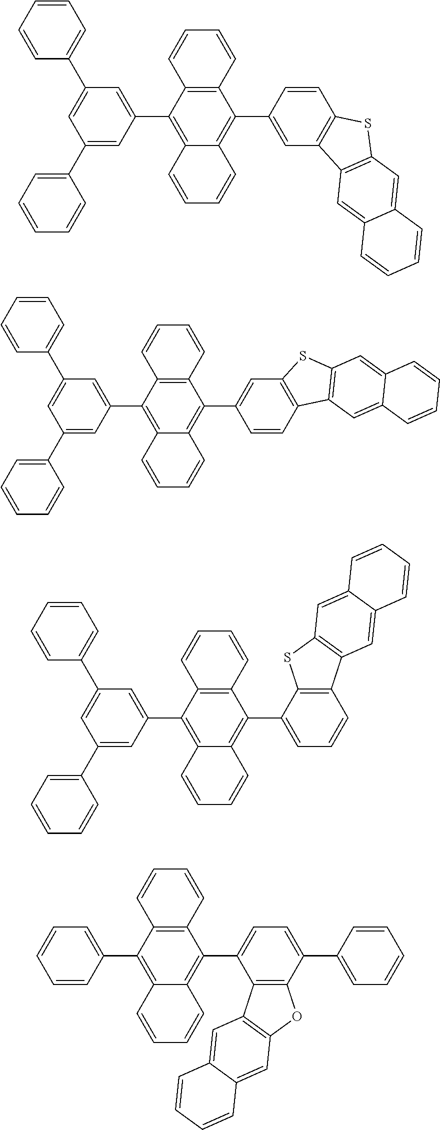 [SMILES: c1ccc(-c2cc(-c3ccccc3)cc(-c3c4ccccc4c(-c4ccc5sc6cc7ccccc7cc6c5c4)c4ccccc34)c2)cc1 ; c1ccc(-c2cc(-c3ccccc3)cc(-c3c4ccccc4c(-c4ccc5c(c4)sc4cc6ccccc6cc45)c4ccccc34)c2)cc1 ; c1ccc(-c2cc(-c3ccccc3)cc(-c3c4ccccc4c(-c4cccc5c4sc4cc6ccccc6cc45)c4ccccc34)c2)cc1 ; c1ccc(-c2c3ccccc3c(-c3ccc(-c4ccccc4)c4oc5cc6ccccc6cc5c34)c3ccccc23)cc1]

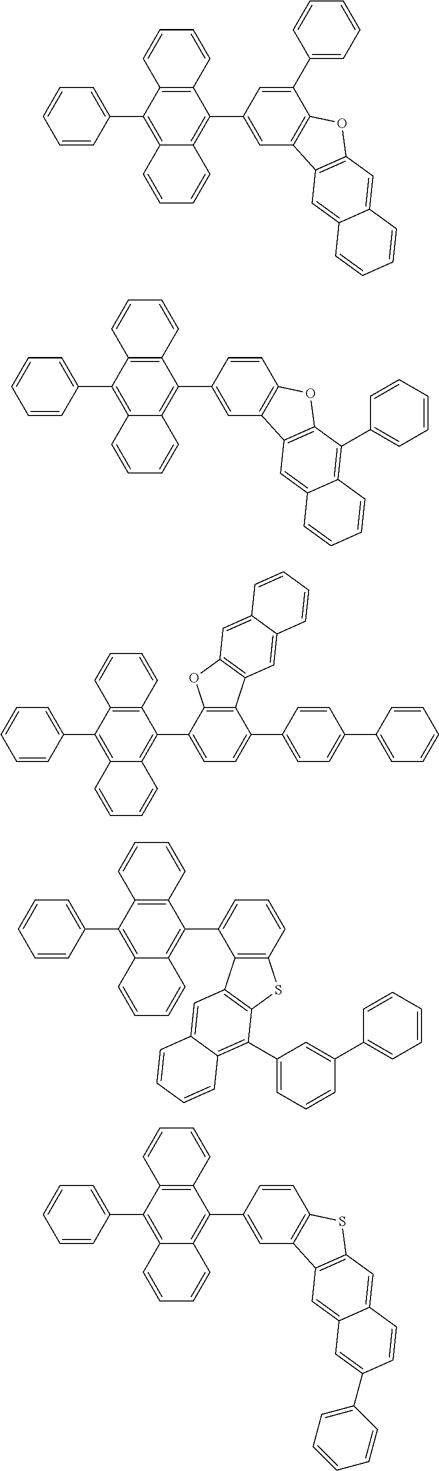

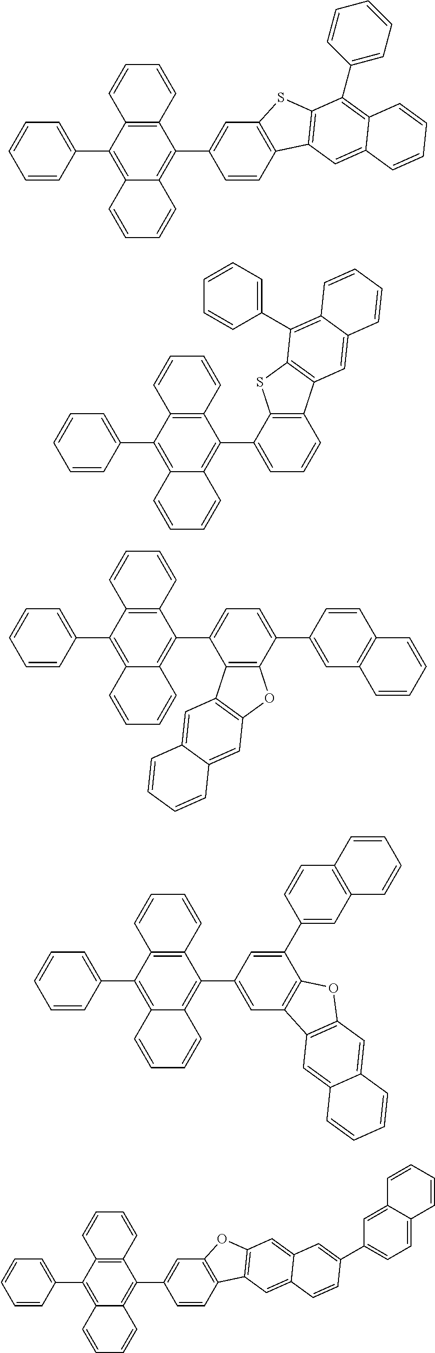

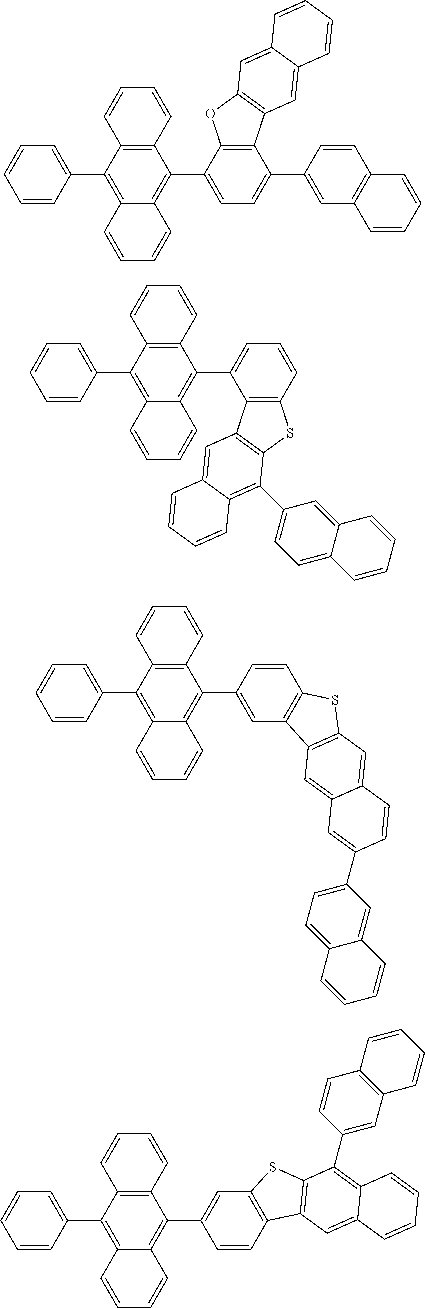

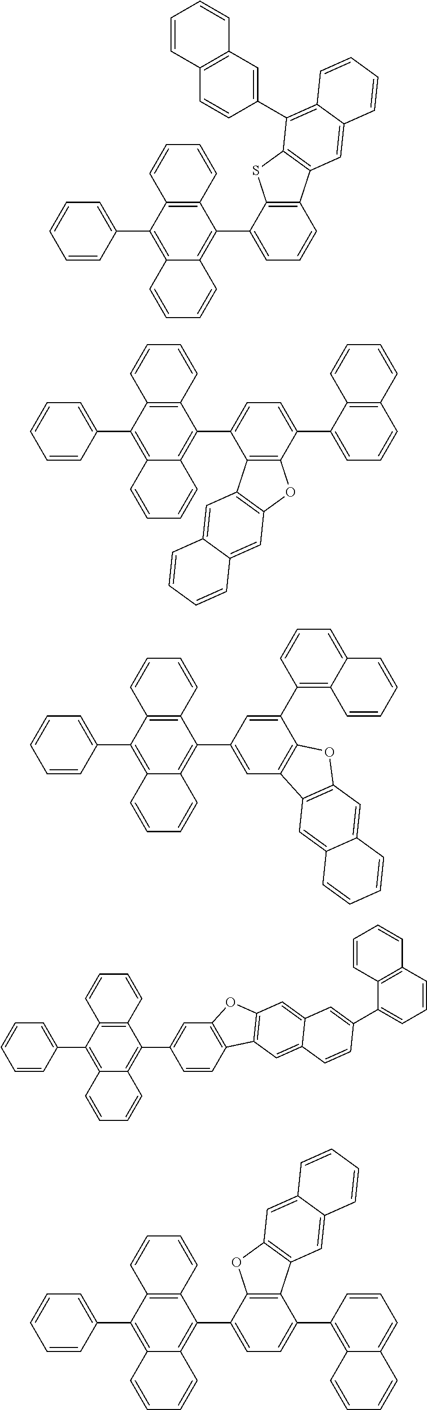

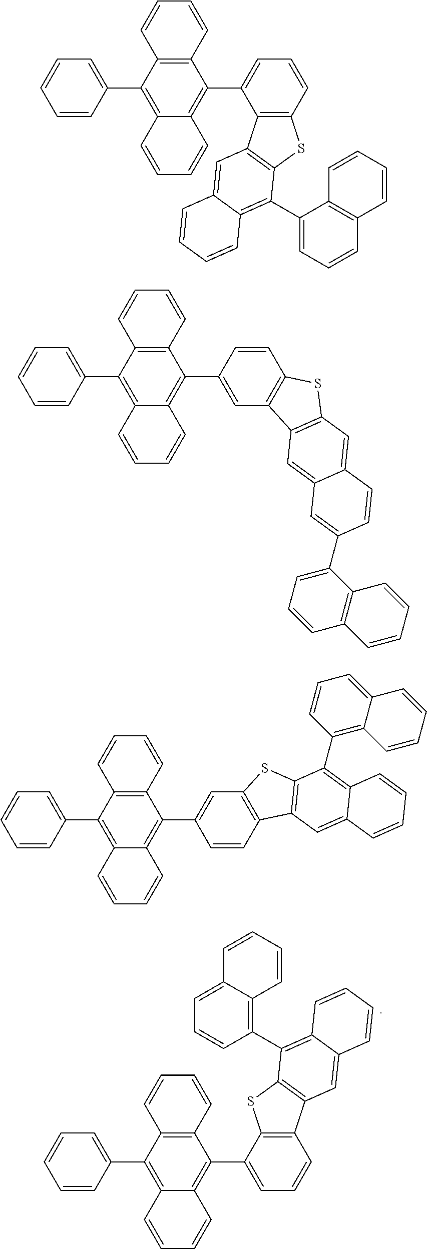

7. The organic light emitting device according to claim 1,
wherein the hole adjustment layer includes a compound of Chemical Formula 2: 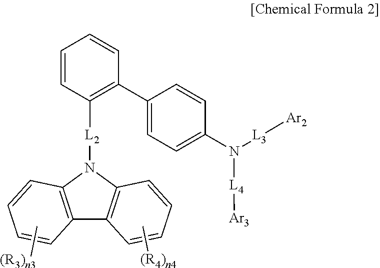
wherein in Chemical Formula 2:
L₂, L₃ and L₄ are each independently a single bond or a substituted or unsubstituted C₆₋₆₀ arylene;
Ar₂ and Ar₃ are each independently a substituted or unsubstituted C₆₋₆₀ aryl, or a substituted or unsubstituted C₂₋₆₀ heteroaryl containing one or more heteroatoms selected from the group consisting of N, O and S;
R₃ and R₄ are each independently hydrogen, deuterium, halogen, cyano, nitro, amino, a substituted or unsubstituted C₁₋₆₀ alkyl, a substituted or unsubstituted C₃₋₆₀ cycloalkyl, a substituted or unsubstituted C₂₋₆₀ alkenyl, a substituted or unsubstituted C₆₋₆₀ aryl, or a substituted or unsubstituted C₂₋₆₀ heteroaryl containing one or more heteroatoms selected from the group consisting of N, O and S, or two adjacent groups are bonded with each other to form a benzene ring;
n3 is an integer from 0 to 4; and
n4 is an integer from 0 to 4.

8. The organic light emitting device according to claim 7,
wherein L₂ is a single bond.

9. The organic light emitting device according to claim 7,
wherein L₃ and L₄ are each independently a single bond, phenylene, or dimethylfluorenediyl.

10. The organic light emitting device according to claim 7,
wherein Ar₂ and Ar₃ are each independently phenyl, biphenylyl, terphenylyl, naphthyl, phenanthrenyl, triphenylenyl, dimethylfluorenyl, or diphenylfluorenyl; and
the Ar₂ and Ar₃ are each independently unsubstituted, or substituted with 1 to 5 substituent groups selected from the group consisting of deuterium, C₁₋₁₀ alkyl, tri(C₁₋₁₀ alkyl)silyl, halogen and cyano.

11. The organic light emitting device according to claim 7,
wherein n3 is 2, and two R₃s are bonded with each other to form a benzene ring.

12. The organic light emitting device according to claim 7,
wherein the compound of Chemical Formula 2 is any one compound selected from the group consisting of the following compounds: 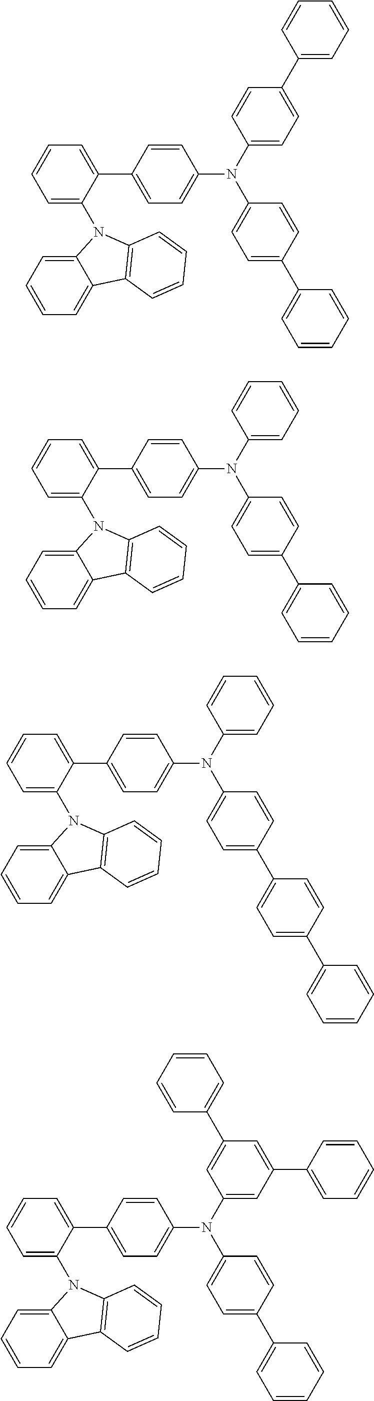 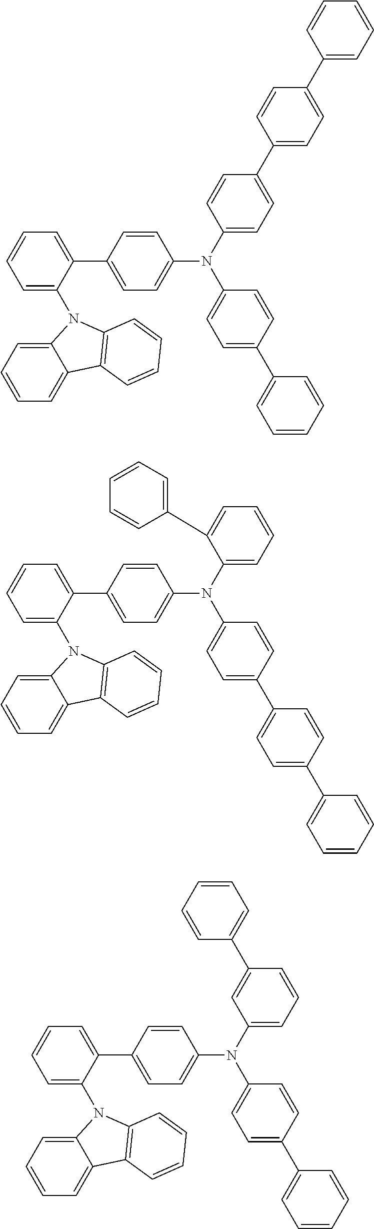 [SMILES: c1ccc(-c2ccc(-c3ccc(N(c4ccc(-c5ccccc5)cc4)c4ccc(-c5ccccc5-n5c6ccccc6c6ccccc65)cc4)cc3)cc2)cc1 ; c1ccc(-c2ccc(-c3ccc(N(c4ccc(-c5ccccc5-n5c6ccccc6c6ccccc65)cc4)c4ccccc4-c4ccccc4)cc3)cc2)cc1 ; c1ccc(-c2ccc(N(c3ccc(-c4ccccc4-n4c5ccccc5c5ccccc54)cc3)c3cccc(-c4ccccc4)c3)cc2)cc1] 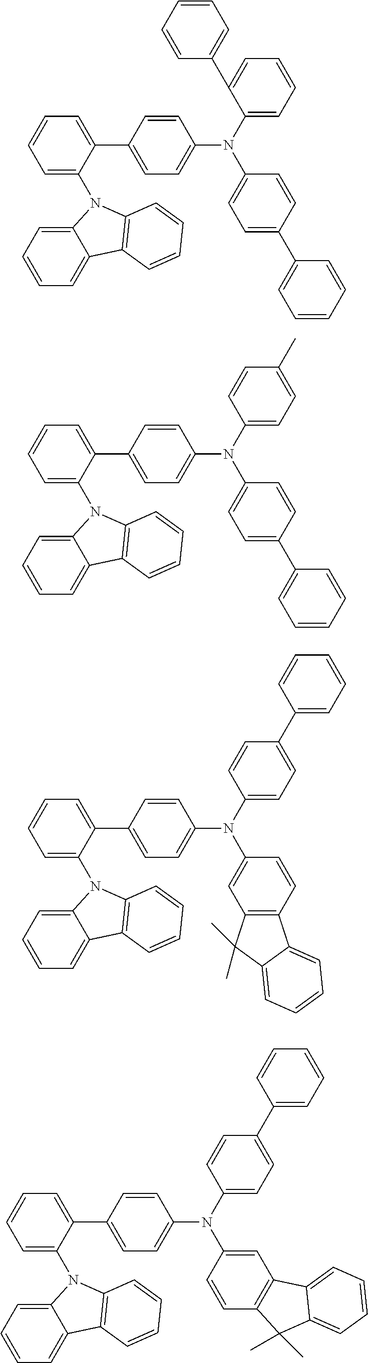 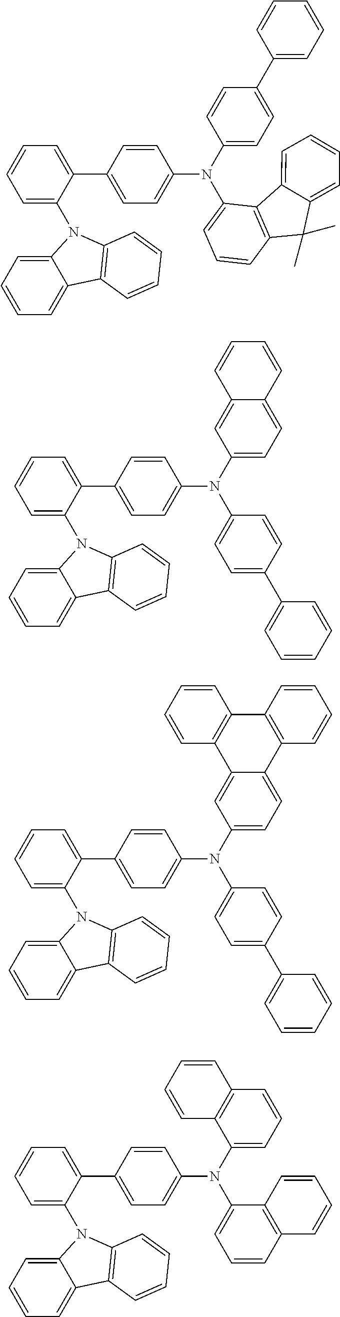 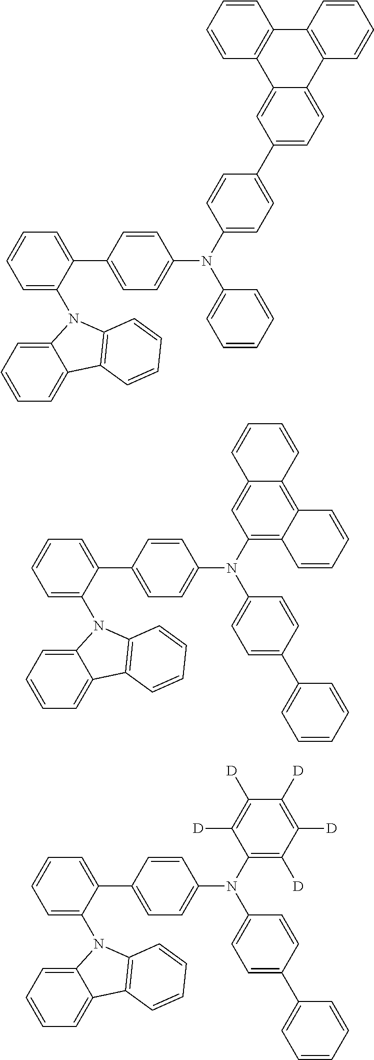 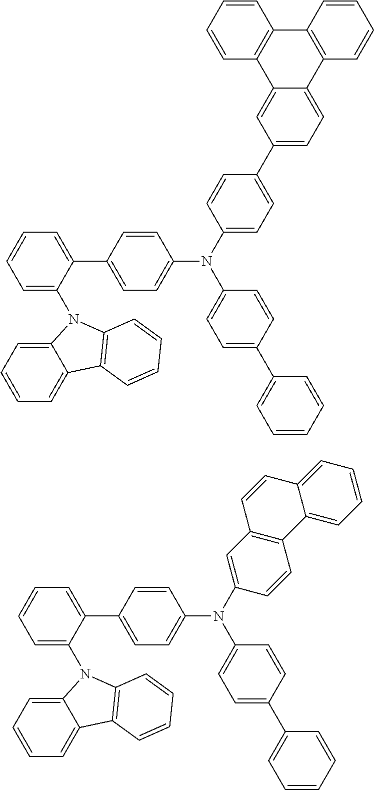 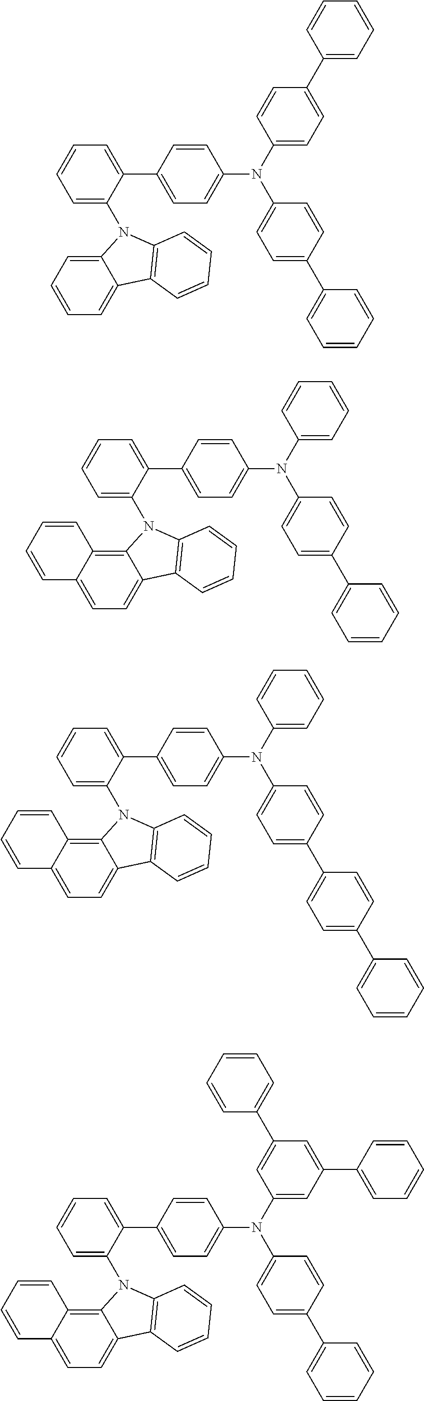 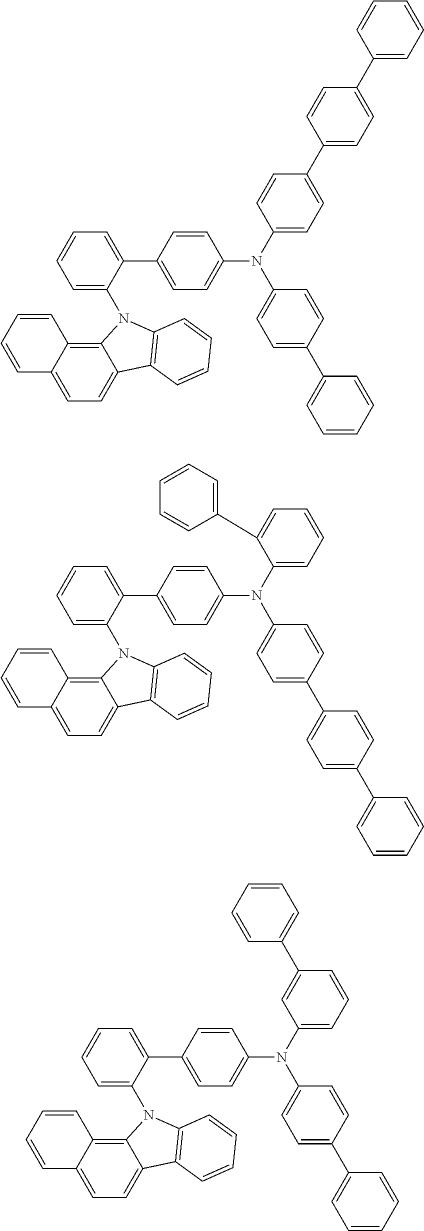 [SMILES: c1ccc(-c2ccc(-c3ccc(N(c4ccc(-c5ccccc5)cc4)c4ccc(-c5ccccc5-n5c6ccccc6c6ccc7ccccc7c65)cc4)cc3)cc2)cc1 ; c1ccc(-c2ccc(-c3ccc(N(c4ccc(-c5ccccc5-n5c6ccccc6c6ccc7ccccc7c65)cc4)c4ccccc4-c4ccccc4)cc3)cc2)cc1 ; c1ccc(-c2ccc(N(c3ccc(-c4ccccc4-n4c5ccccc5c5ccc6ccccc6c54)cc3)c3cccc(-c4ccccc4)c3)cc2)cc1] 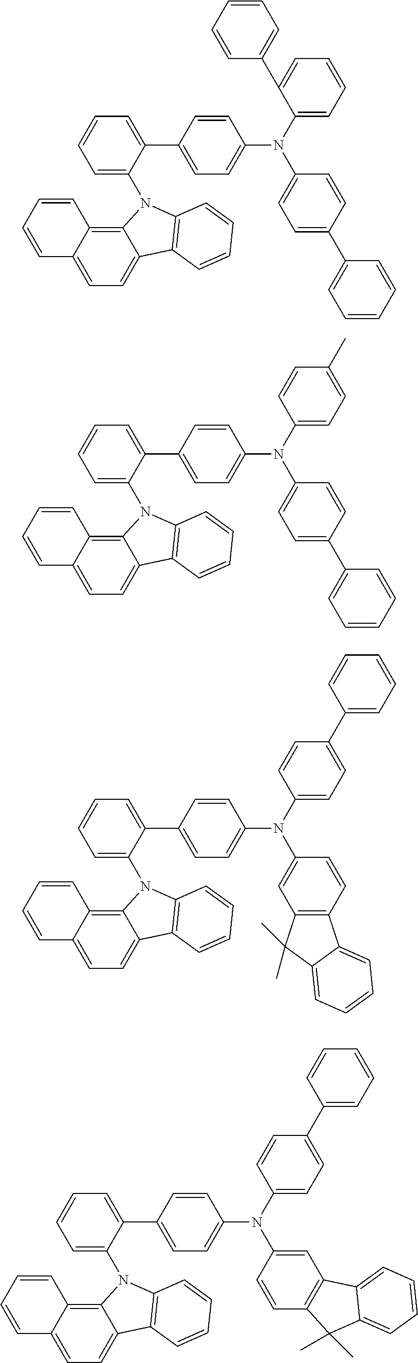 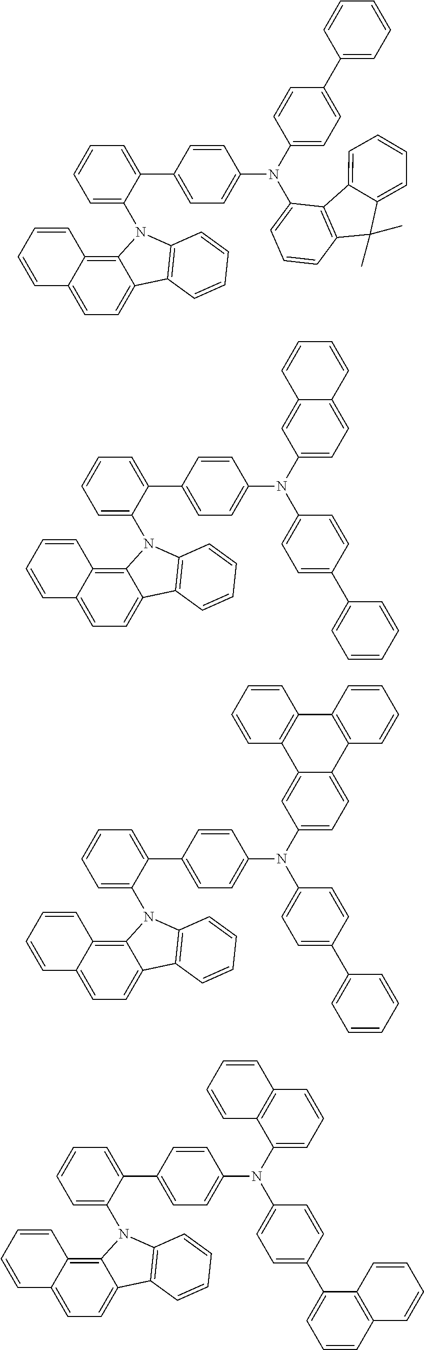 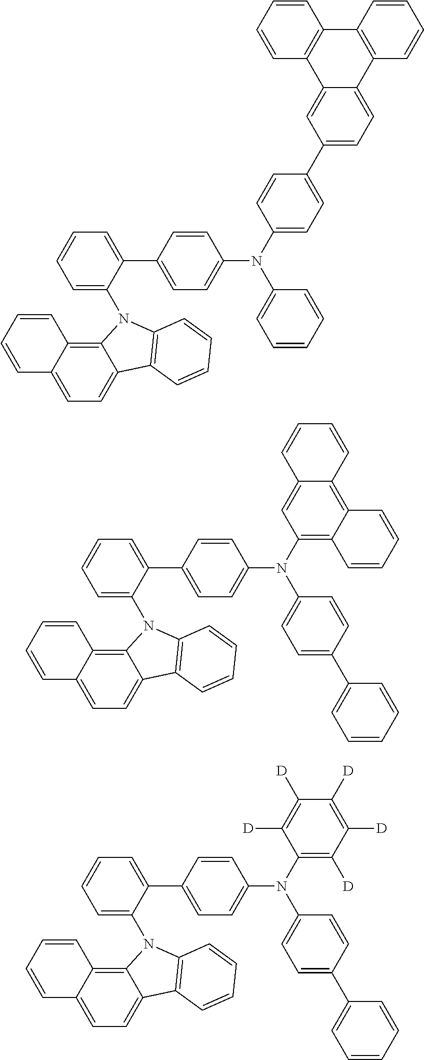 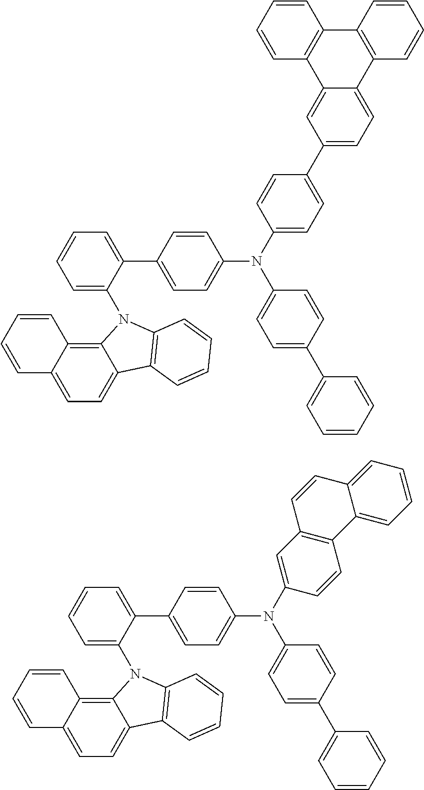 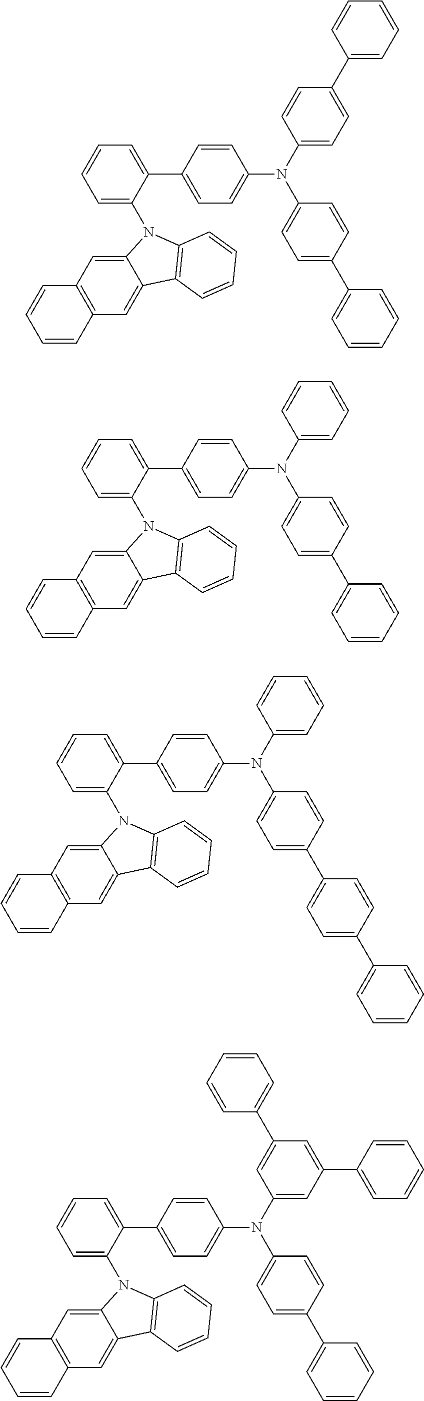 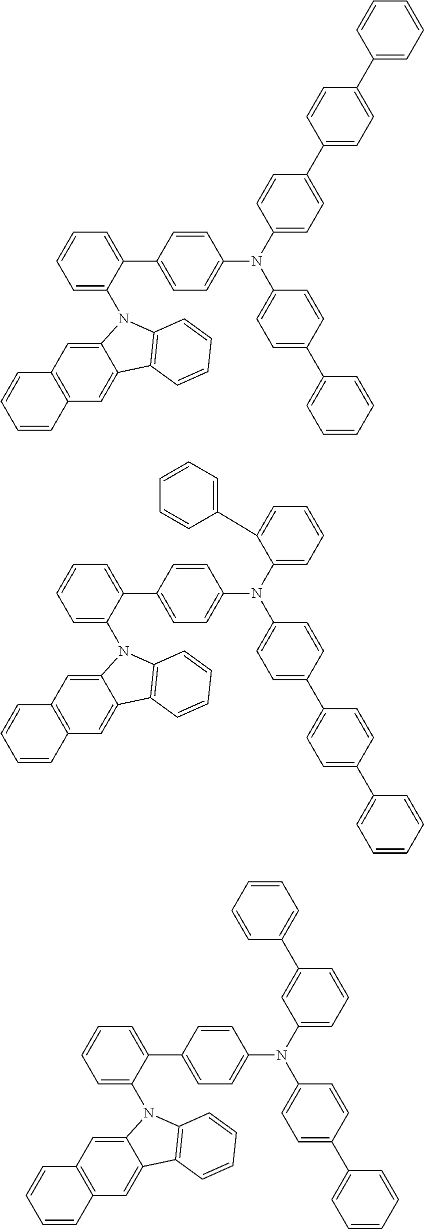 [SMILES: c1ccc(-c2ccc(-c3ccc(N(c4ccc(-c5ccccc5)cc4)c4ccc(-c5ccccc5-n5c6ccccc6c6cc7ccccc7cc65)cc4)cc3)cc2)cc1 ; c1ccc(-c2ccc(-c3ccc(N(c4ccc(-c5ccccc5-n5c6ccccc6c6cc7ccccc7cc65)cc4)c4ccccc4-c4ccccc4)cc3)cc2)cc1 ; c1ccc(-c2ccc(N(c3ccc(-c4ccccc4-n4c5ccccc5c5cc6ccccc6cc54)cc3)c3cccc(-c4ccccc4)c3)cc2)cc1] 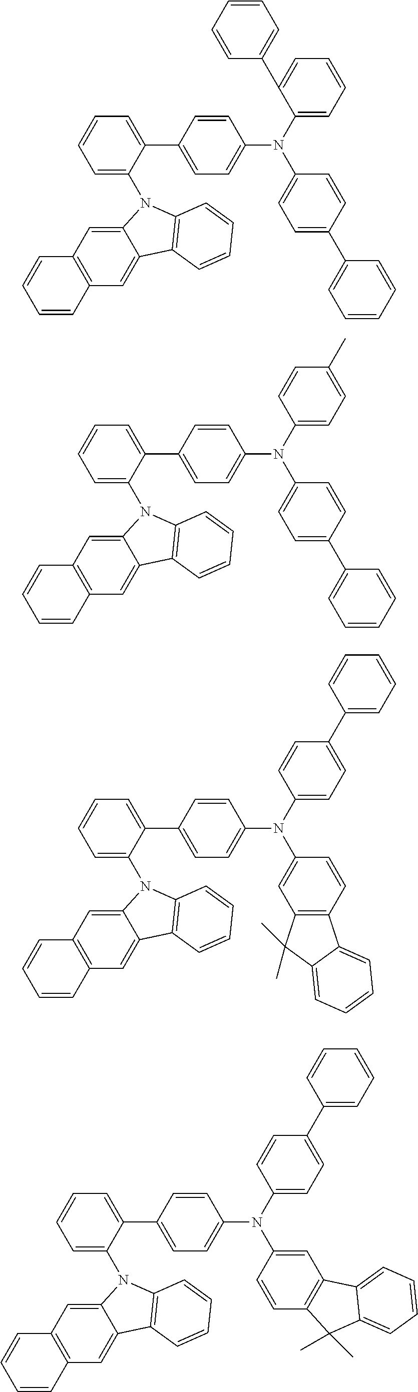 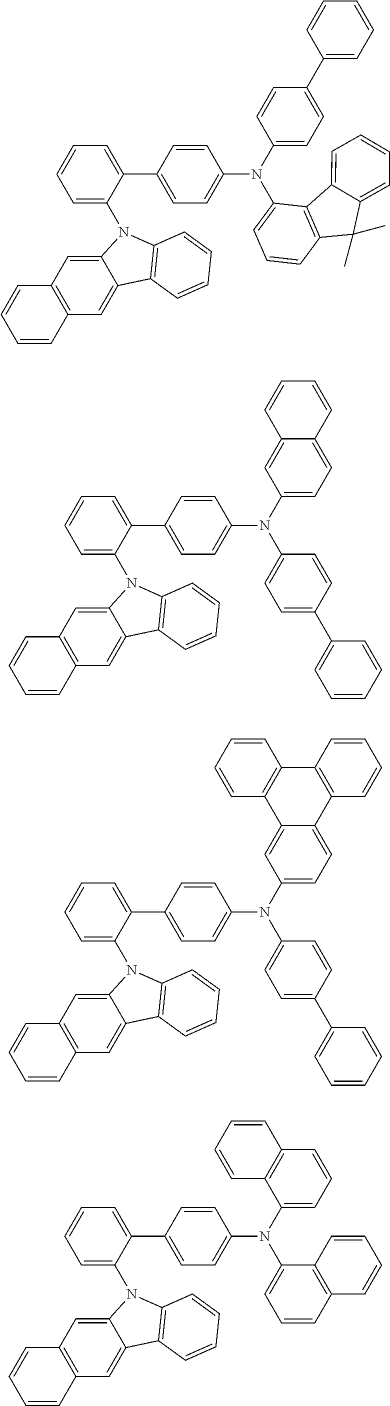 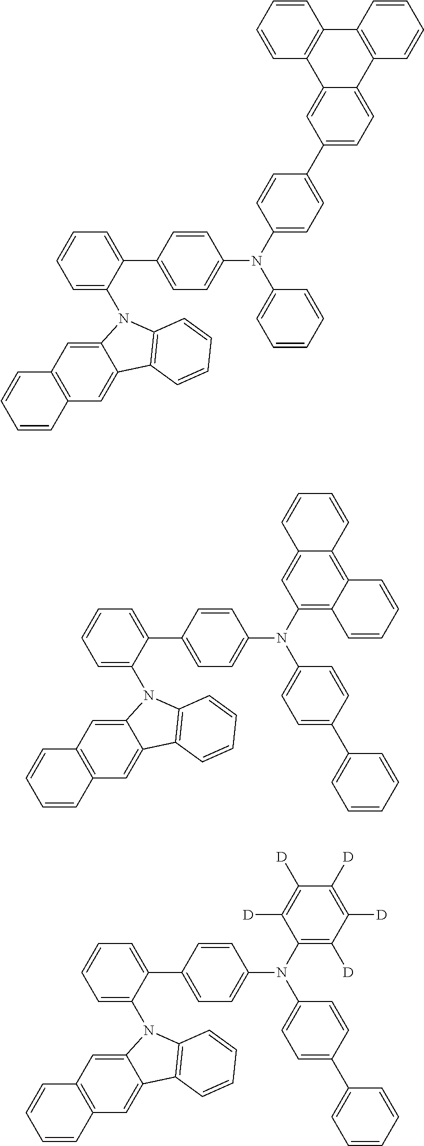 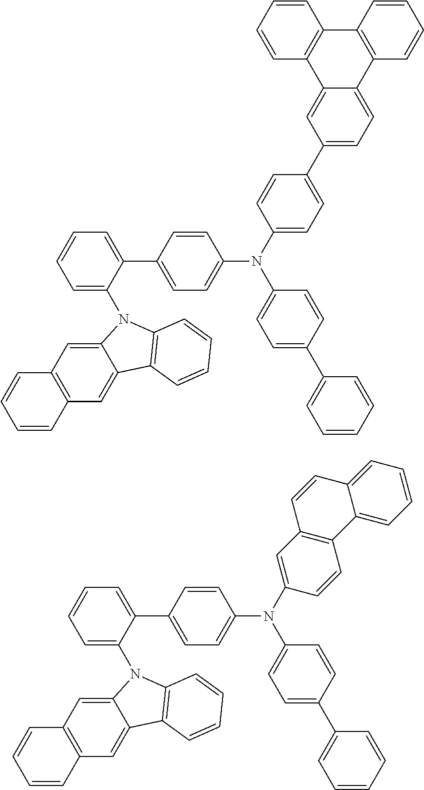 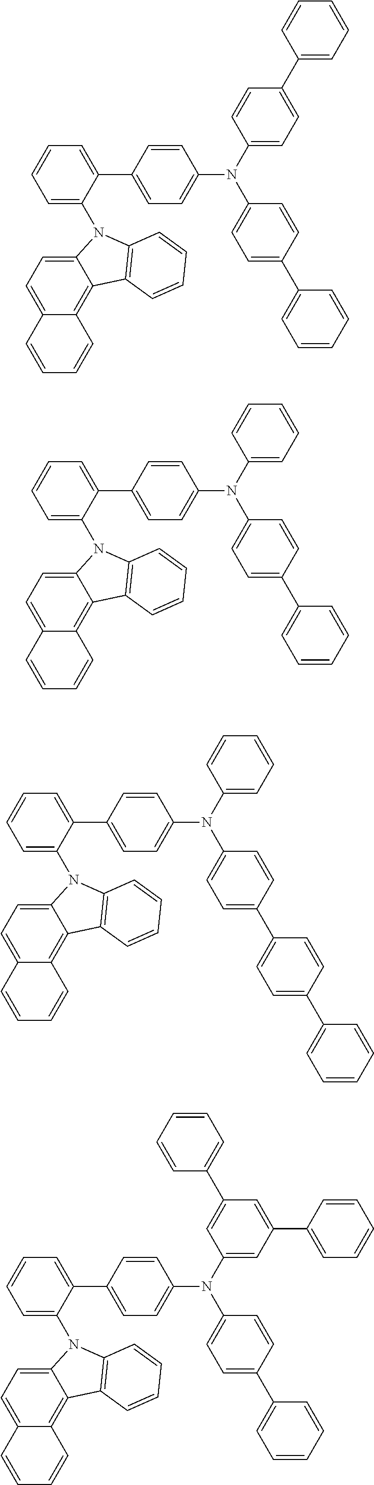 [SMILES: c1ccc(-c2ccc(N(c3ccc(-c4ccccc4)cc3)c3ccc(-c4ccccc4-n4c5ccccc5c5c6ccccc6ccc54)cc3)cc2)cc1 ; c1ccc(-c2ccc(N(c3ccccc3)c3ccc(-c4ccccc4-n4c5ccccc5c5c6ccccc6ccc54)cc3)cc2)cc1 ; c1ccc(-c2ccc(-c3ccc(N(c4ccccc4)c4ccc(-c5ccccc5-n5c6ccccc6c6c7ccccc7ccc65)cc4)cc3)cc2)cc1 ; c1ccc(-c2ccc(N(c3ccc(-c4ccccc4-n4c5ccccc5c5c6ccccc6ccc54)cc3)c3cc(-c4ccccc4)cc(-c4ccccc4)c3)cc2)cc1] 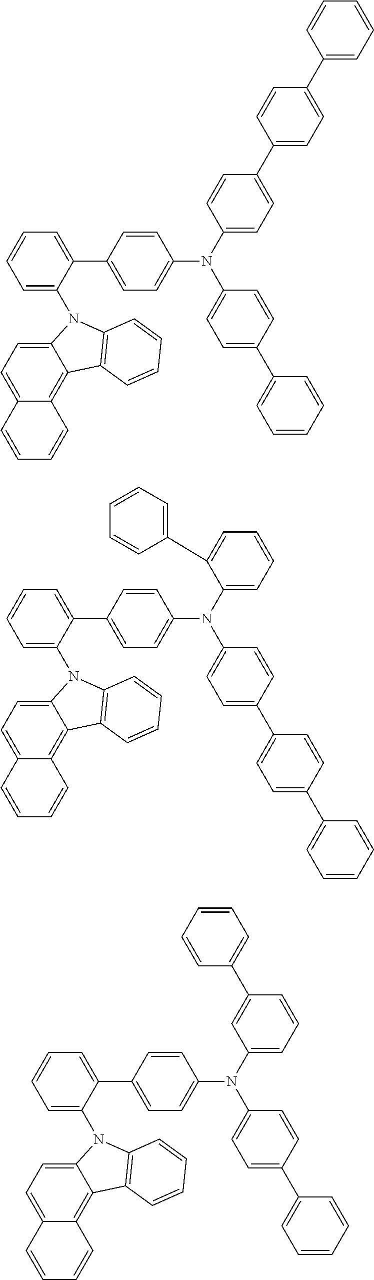 [SMILES: c1ccc(-c2ccc(-c3ccc(N(c4ccc(-c5ccccc5)cc4)c4ccc(-c5ccccc5-n5c6ccccc6c6c7ccccc7ccc65)cc4)cc3)cc2)cc1 ; c1ccc(-c2ccc(-c3ccc(N(c4ccc(-c5ccccc5-n5c6ccccc6c6c7ccccc7ccc65)cc4)c4ccccc4-c4ccccc4)cc3)cc2)cc1 ; c1ccc(-c2ccc(N(c3ccc(-c4ccccc4-n4c5ccccc5c5c6ccccc6ccc54)cc3)c3cccc(-c4ccccc4)c3)cc2)cc1] 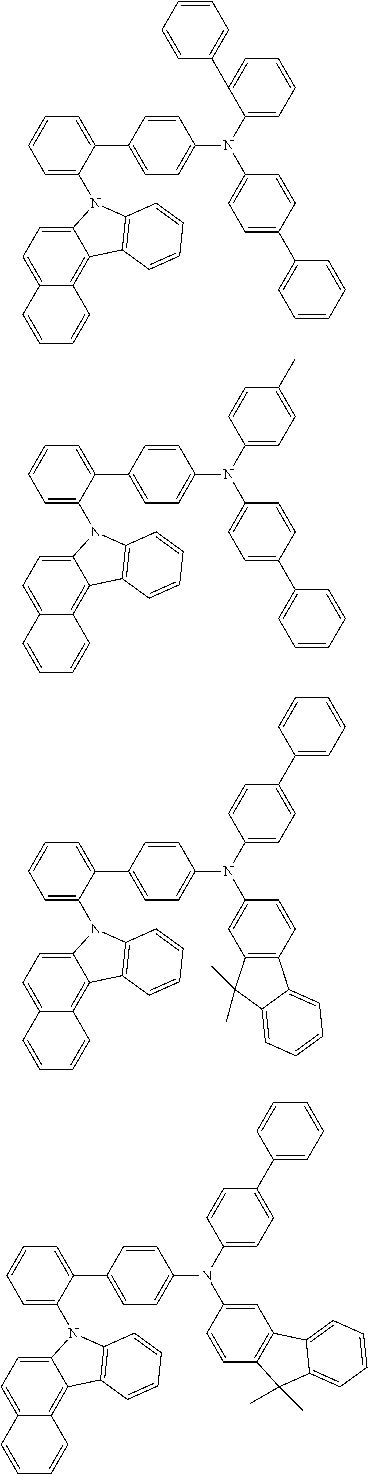 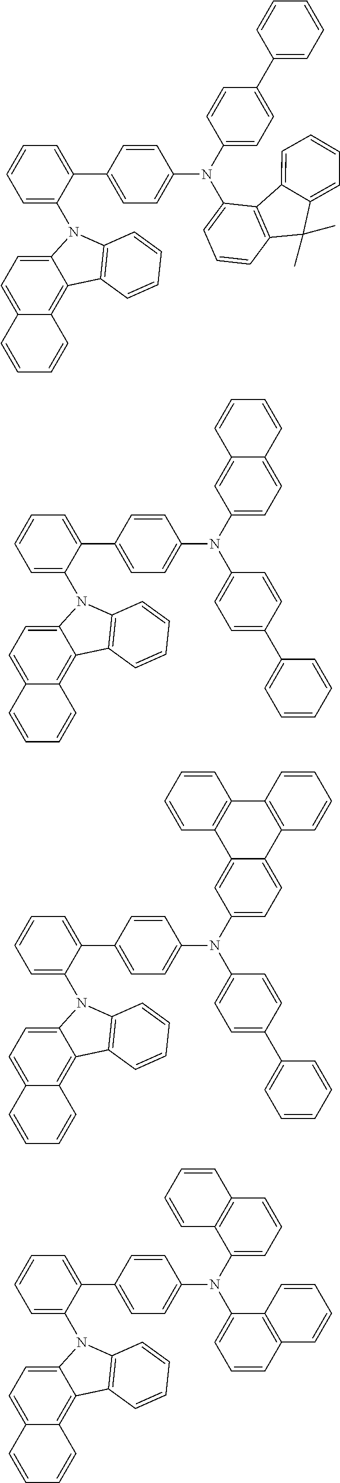 [SMILES: CC1(C)c2ccccc2-c2c(N(c3ccc(-c4ccccc4)cc3)c3ccc(-c4ccccc4-n4c5ccccc5c5c6ccccc6ccc54)cc3)cccc21 ; c1ccc(-c2ccc(N(c3ccc(-c4ccccc4-n4c5ccccc5c5c6ccccc6ccc54)cc3)c3ccc4ccccc4c3)cc2)cc1 ; c1ccc(-c2ccc(N(c3ccc(-c4ccccc4-n4c5ccccc5c5c6ccccc6ccc54)cc3)c3ccc4c5ccccc5c5ccccc5c4c3)cc2)cc1 ; c1ccc(-n2c3ccccc3c3c4ccccc4ccc32)c(-c2ccc(N(c3cccc4ccccc34)c3cccc4ccccc34)cc2)c1] 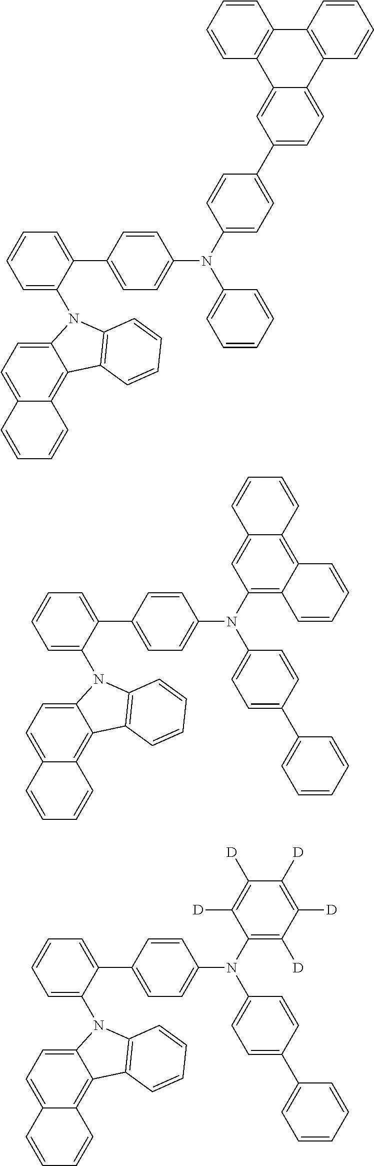 [SMILES: c1ccc(N(c2ccc(-c3ccc4c5ccccc5c5ccccc5c4c3)cc2)c2ccc(-c3ccccc3-n3c4ccccc4c4c5ccccc5ccc43)cc2)cc1 ; c1ccc(-c2ccc(N(c3ccc(-c4ccccc4-n4c5ccccc5c5c6ccccc6ccc54)cc3)c3cc4ccccc4c4ccccc34)cc2)cc1 ; [2H]c1c([2H])c([2H])c(N(c2ccc(-c3ccccc3)cc2)c2ccc(-c3ccccc3-n3c4ccccc4c4c5ccccc5ccc43)cc2)c([2H])c1[2H]] 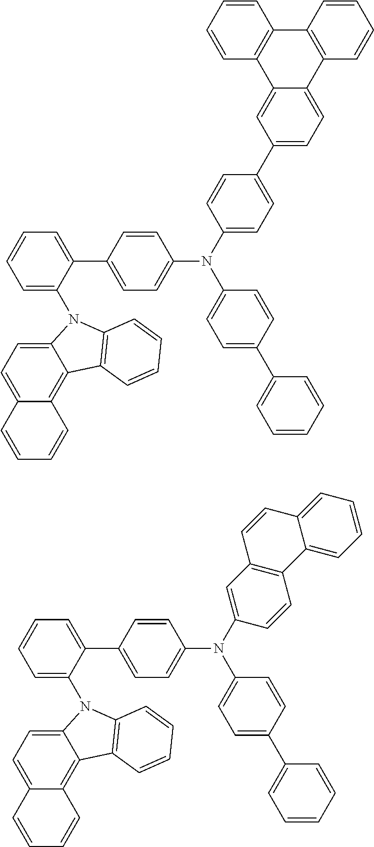 [SMILES: c1ccc(-c2ccc(N(c3ccc(-c4ccc5c6ccccc6c6ccccc6c5c4)cc3)c3ccc(-c4ccccc4-n4c5ccccc5c5c6ccccc6ccc54)cc3)cc2)cc1 ; c1ccc(-c2ccc(N(c3ccc(-c4ccccc4-n4c5ccccc5c5c6ccccc6ccc54)cc3)c3ccc4c(ccc5ccccc54)c3)cc2)cc1] 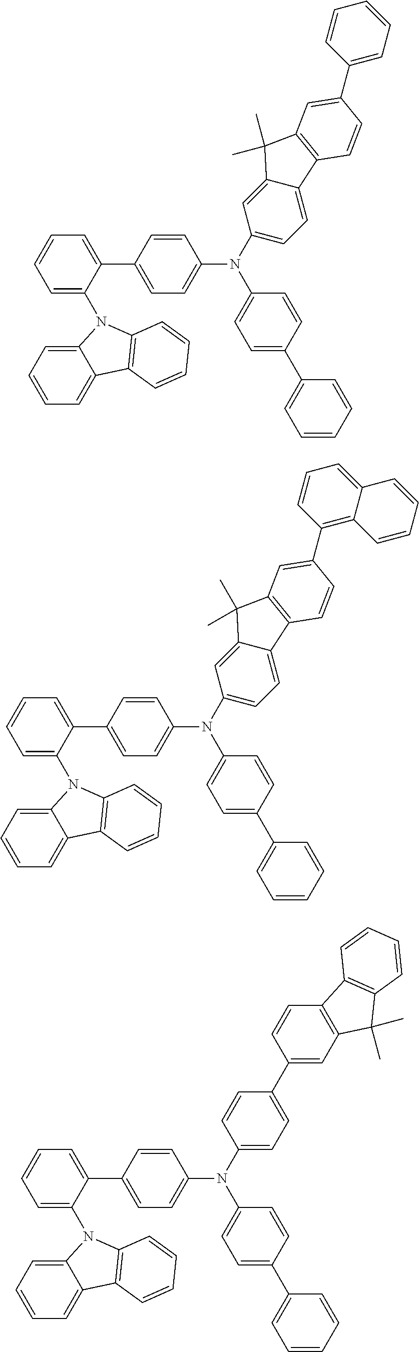 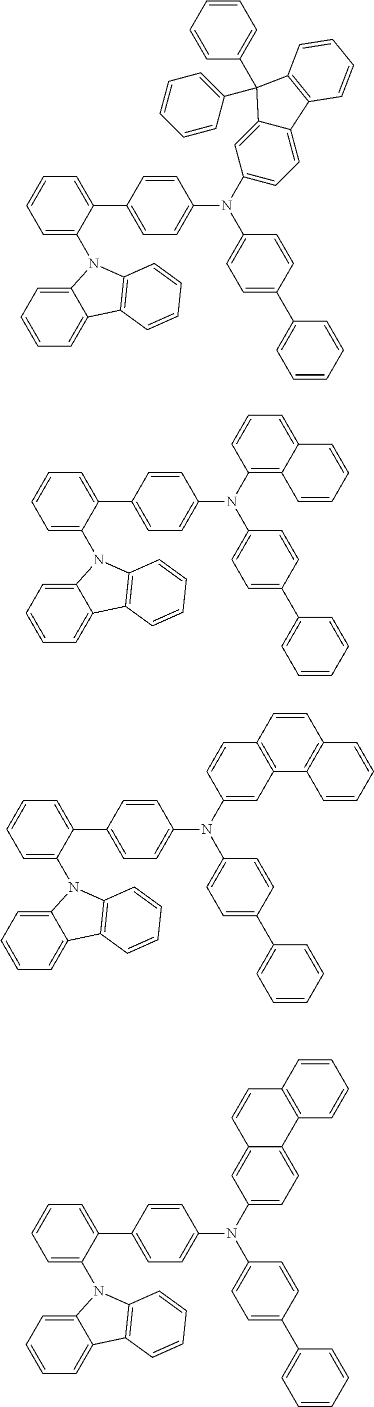 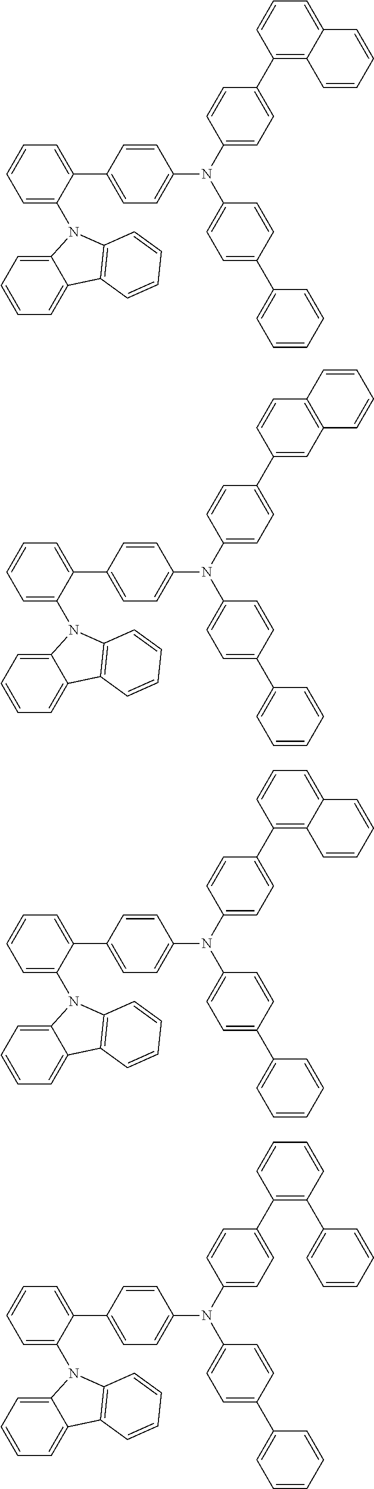 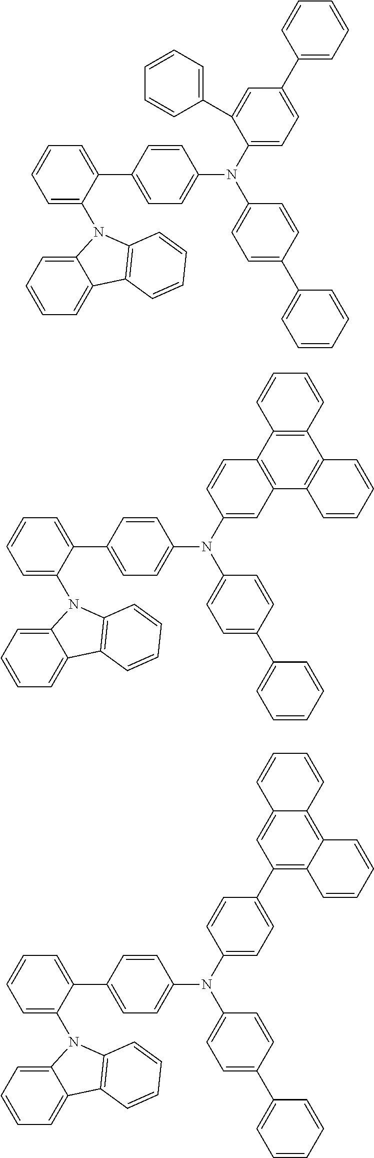 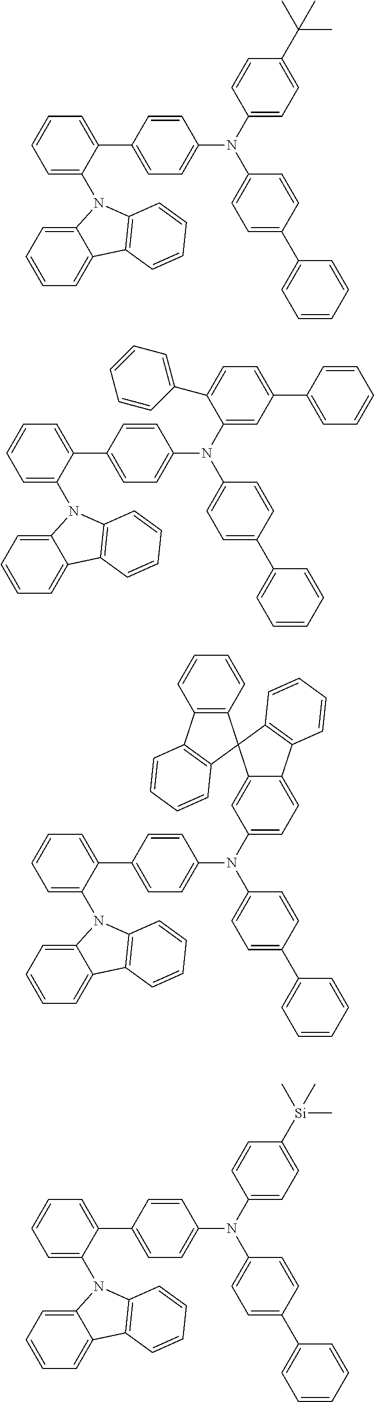 [SMILES: CC(C)(C)c1ccc(N(c2ccc(-c3ccccc3)cc2)c2ccc(-c3ccccc3-n3c4ccccc4c4ccccc43)cc2)cc1 ; c1ccc(-c2ccc(N(c3ccc(-c4ccccc4-n4c5ccccc5c5ccccc54)cc3)c3cc(-c4ccccc4)ccc3-c3ccccc3)cc2)cc1 ; c1ccc(-c2ccc(N(c3ccc(-c4ccccc4-n4c5ccccc5c5ccccc54)cc3)c3ccc4c(c3)C3(c5ccccc5-c5ccccc53)c3ccccc3-4)cc2)cc1 ; C[Si](C)(C)c1ccc(N(c2ccc(-c3ccccc3)cc2)c2ccc(-c3ccccc3-n3c4ccccc4c4ccccc43)cc2)cc1] [chemical structure]
